(19) United States
(12) Patent Application Publication
(10) Pub. No.: US 2019/0280220 A1
(43) Pub. Date: Sep. 12, 2019

(54) METAL COMPLEXES

(71) Applicant: Merck Patent GmbH, Darmstadt (DE)

(72) Inventors: Philipp Stoessel, Frankfurt am Main (DE); Christian Ehrenreich, Darmstadt (DE)

(73) Assignee: Merck Patent GmbH, Darmstadt (DE)

(21) Appl. No.: 16/345,033

(22) PCT Filed: Oct. 23, 2017
(86) PCT No.: PCT/EP2017/076937

§ 371 Date: Apr. 25, 2019

(30) Foreign Application Priority Data
Oct. 25, 2016 (EP) 16195512.5

(51) Int. Cl. H01L 51/00; C07F 15/00; C09K 11/06

(52) U.S. Cl. CPC H01L 51/0085; H01L 51/5016; C09K 11/06; C07F 15/0033

(57) ABSTRACT

The present invention relates to metal complexes and electronic devices, in particular organic electroluminescent devices containing said metal complexes. M(L)n(L′)m formula (1), formula (11)

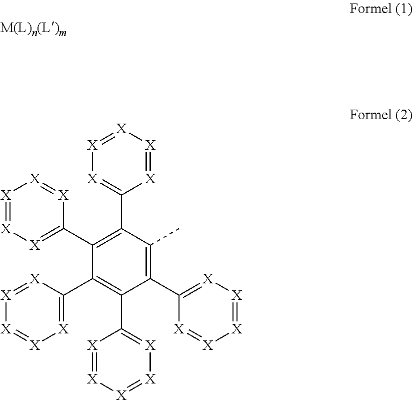

The present invention relates to metal complexes which are substituted by aromatic or heteroaromatic substituents and are suitable for use as emitters in organic electroluminescent devices.

According to the prior art, triplet emitters used in phosphorescent organic electroluminescent devices (OLEDs) are iridium or else platinum complexes in particular, especially ortho-metallated complexes having aromatic ligands, where the ligands bind to the metal via a negatively charged carbon atom and an uncharged nitrogen atom or via a negatively charged carbon atom and an uncharged carbene carbon atom. Examples of such complexes are tris(phenylpyridyl)iridium(III) and derivatives thereof, where the ligands used are, for example, 1- or 3-phenylisoquinolines, 2-phenylquinolines or phenylcarbenes. At the same time, the complexes mentioned are relatively difficult to process from solution.

Iridium complexes having ligands containing (pentaphenyl)phenyl structures are detailed in US 2010/0137461 A. However, these iridium complexes necessarily comprise monodentate ligands or ligands bonded to the iridium atom solely via two oxygen atoms or via one oxygen atom and one nitrogen atom.

It is therefore an object of the present invention to provide novel metal complexes suitable as emitters for use in OLEDs. It is a particular object to provide emitters which exhibit improved properties in relation to efficiency, operating voltage and/or lifetime. By oriented emission, a higher quantum efficiency can be obtained by improved outcoupling of light out of the component, such that the OLED has higher efficiency overall. As a consequence, the component can be driven with less current, which means a higher lifetime as a further advantage. A further object is that of providing metal complexes having improved processibility, especially from solution.

It has been found that, surprisingly, the abovementioned object is achieved by iridium complexes or platinum complexes containing one or more substituents composed of arylene or heteroarylene groups, which are of very good suitability for use in an organic electroluminescent device. The present invention therefore provides these complexes and organic electroluminescent devices comprising these complexes.

The invention thus provides a compound of the following formula (1):

M(L)ₙ(L′)ₘ formula (1)

where the symbols and indices used are as follows:
M is iridium or platinum;
L is the same or different at each instance and is a bidentate, preferably monoanionic ligand;
L′ is the same or different at each instance and is a ligand;
n is 1, 2 or 3, preferably 2 or 3, more preferably 3;
m is 0, 1, 2, 3 or 4, preferably 0, 1 or 2, more preferably 0 or 1, especially preferably 0;

at the same time, it is also possible for two or more ligands L to be joined to one another or for L to be joined to L′ by a single bond or a bivalent or trivalent bridge, thus forming a tridentate, tetradentate, pentadentate or hexadentate ligand system,

characterized in that the metal complex contains at least one substructure of the formula (2)

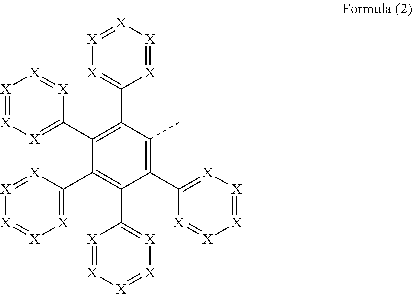

where the dotted bond represents the linkage of this group to another part of the metal complex of the formula (1) and in addition:
X is the same or different at each instance and is CR or N, with the proviso that not more than three symbols X per cycle are N;
R is the same or different at each instance and is H, D, F, Cl, Br, I, N(R¹)₂, CN, NO₂, OH, COOH, C(═O)N(R¹)₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy or thioalkoxy group having 1 to 20 carbon atoms or an alkenyl or alkynyl group having 2 to 20 carbon atoms or a branched or cyclic alkyl, alkoxy or thioalkoxy group having 3 to 20 carbon atoms, where the alkyl, alkoxy, thioalkoxy, alkenyl or alkynyl group may each be substituted by one or more R¹ radicals, where one or more nonadjacent CH₂ groups may be replaced by R¹C═CR¹, C≡C, Si(R¹)₂, C═O, NR¹, O, S or CONR¹, or an aromatic or heteroaromatic ring system which has 5 to 40 aromatic ring atoms and may be substituted in each case by one or more R¹ radicals, or an aryloxy or heteroaryloxy group which has 5 to 40 aromatic ring atoms and may be substituted by one or more R¹ radicals; at the same time, two R radicals together may also form a ring system;
R¹ is the same or different at each instance and is H, D, F, Cl, Br, I, N(R²)₂, CN, NO₂, Si(R²)₃, B(OR²)₂, C(═O)R², P(═O)(R²)₂, S(═O)R², S(═O)₂R², OSO₂R², a straight-chain alkyl, alkoxy or thioalkoxy group having 1 to 20 carbon atoms or an alkenyl or alkynyl group having 2 to 20 carbon atoms or a branched or cyclic alkyl, alkoxy or thioalkoxy group having 3 to 20 carbon atoms, where each alkyl, alkoxy, thioalkoxy, alkenyl or alkynyl group may be substituted by one or more R² radicals, where one or more nonadjacent CH₂ groups may be replaced by R²C═CR², C≡C, Si(R²)₂, C═O, NR², O, S or CONR², or an aromatic or heteroaromatic ring system which has 5 to 40 aromatic ring atoms and may be substituted in each case by one or more R² radicals, or an aryloxy or heteroaryloxy group which has 5 to 40 aromatic ring atoms and may be substituted by one or more R² radicals, or an aralkyl or heteroaralkyl group which has 5 to 40 aromatic ring atoms and may be substituted by one or more R² radicals, or a diarylamino group, diheteroarylamino group or arylheteroarylamino group which has 10 to 40 aromatic ring atoms and may be substituted by one or more R² radicals; at the same time, two or more R¹ radicals together may form a ring system;
R² is the same or different at each instance and is H, D, F or an aliphatic, aromatic and/or heteroaromatic organic radical, especially a hydrocarbyl radical, having 1 to 20 carbon atoms, in which one or more hydrogen atoms may also be replaced by F, at the same time, two or more R² substituents together may also form a mono- or polycyclic ring system;

where the substructure, as well as the linkage represented by a dotted bond, may have further bonds to parts of the metal complex of the formula (1);

with the proviso that, if M is Ir, the part of the metal complex that binds to Ir comprises not more than one monodentate ligand L′ and the bidentate ligands L of the metal complex each have at least one C—Ir linkage.

The wording that two or more radicals together may form a ring, in the context of the present description, shall be understood to mean, inter alia, that the two radicals are joined to one another by a chemical bond with formal elimination of two hydrogen atoms. This is illustrated by the following scheme:

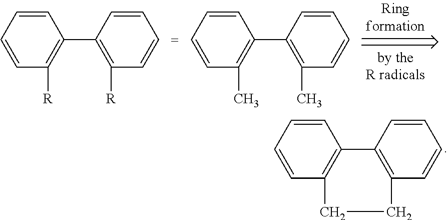

Ring formation of bicyclic, tricyclic and oligocyclic structures is likewise possible. In addition, however, the abovementioned wording shall also be understood to mean that, if one of the two radicals is hydrogen, the second radical binds to the position to which the hydrogen atom was bonded, forming a ring. This shall be illustrated by the following scheme:

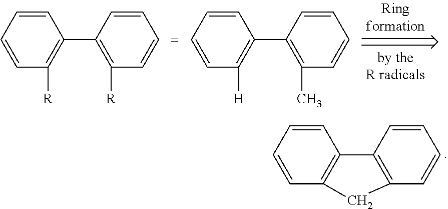

Entirely analogously, this shall also be understood to mean that, if both radicals are hydrogen atoms, in place of the two hydrogen atoms, a ring is formed via a single bond.

The formation of an aromatic ring system shall be illustrated by the following scheme:

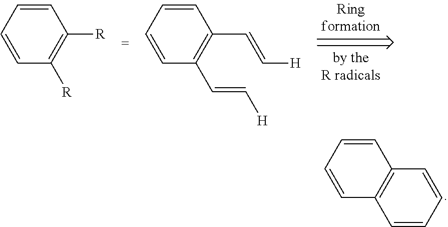

This kind of ring formation is possible in radicals bonded to carbon atoms directly bonded to one another, or in radicals bonded to further-removed carbon atoms. Preference is given to this kind of ring formation in radicals bonded to carbon atoms directly bonded to one another or to the same carbon atom.

An aryl group in the context of this invention contains 6 to 40 carbon atoms; a heteroaryl group in the context of this invention contains 2 to 40 carbon atoms and at least one heteroatom, with the proviso that the sum total of carbon atoms and heteroatoms is at least 5. The heteroatoms are preferably selected from N, O and/or S. An aryl group or heteroaryl group is understood here to mean either a simple aromatic cycle, i.e. benzene, or a simple heteroaromatic cycle, for example pyridine, pyrimidine, thiophene, etc., or a fused aryl or heteroaryl group, for example naphthalene, anthracene, phenanthrene, quinoline, isoquinoline, etc. In addition, in the context of the present invention, an aryl group shall be understood to mean a group in which two, three or more phenyl groups bonded directly to one another are bridged to one another via a CR₂ group, i.e., for example, a fluorene group, a spirobifluorene group or an indenofluorene group.

An aromatic ring system in the context of this invention contains 6 to 40 carbon atoms in the ring system. A heteroaromatic ring system in the context of this invention contains 1 to 40 carbon atoms and at least one heteroatom in the ring system, with the proviso that the sum total of carbon atoms and heteroatoms is at least 5. The heteroatoms are preferably selected from N, O and/or S. An aromatic or heteroaromatic ring system in the context of this invention shall be understood to mean a system which does not necessarily contain only aryl or heteroaryl groups, but in which it is also possible for a plurality of aryl or heteroaryl groups to be interrupted by a nonaromatic unit (preferably less than 10% of the atoms other than H), for example a carbon, nitrogen or oxygen atom or a carbonyl group. For example, systems such as triarylamine, diaryl ethers, stilbene, etc. shall thus also be regarded as aromatic ring systems in the context of this invention, and likewise systems in which two or more aryl groups are interrupted, for example, by a linear or cyclic alkyl group or by a silyl group. In addition, systems in which two or more aryl or heteroaryl groups are bonded directly to one another, for example biphenyl, terphenyl, quaterphenyl or bipyridine, shall likewise be regarded as an aromatic or heteroaromatic ring system.

A cyclic alkyl, alkoxy or thioalkoxy group in the context of this invention is understood to mean a monocyclic, bicyclic or polycyclic group.

In the context of the present invention, a C₁- to C₂₀-alkyl group in which individual hydrogen atoms or CH₂ groups may also be replaced by the abovementioned groups is understood to mean, for example, the methyl, ethyl, n-propyl, i-propyl, cyclopropyl, n-butyl, i-butyl, s-butyl, t-butyl, cyclobutyl, 2-methylbutyl, n-pentyl, s-pentyl, t-pentyl, 2-pentyl, neopentyl, cyclopentyl, n-hexyl, s-hexyl, t-hexyl, 2-hexyl, 3-hexyl, neohexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, adamantyl, trifluoromethyl, pentafluoroethyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)cyclohex-1-yl, 1-(n-butyl)cyclohex-1-yl, 1-(n-hexyl)cyclohex-1-yl, 1-(n-octyl)cyclohex-1-yl and 1-(n-decyl)cyclohex-1-yl radicals. An alkenyl group is understood to mean, for example, ethenyl, propenyl, butenyl, pentenyl, cyclopentenyl, hexenyl, cyclohexenyl, heptenyl, cycloheptenyl, octenyl, cyclooctenyl or cyclooctadienyl. An alkynyl group is understood to mean, for example, ethynyl, propynyl, butynyl, pentynyl, hexynyl, heptynyl or octynyl. A C₁- to C₄₀-alkoxy group is understood to mean, for example, methoxy, trifluoromethoxy, ethoxy, n-propoxy, i-propoxy, n-butoxy, i-butoxy, s-butoxy, t-butoxy or 2-methylbutoxy.

An aromatic or heteroaromatic ring system which has 5-40 aromatic ring atoms and may also be substituted in each case by the abovementioned radicals and which may be joined to the aromatic or heteroaromatic system via any desired positions is understood to mean, for example, groups derived from benzene, naphthalene, anthracene, benzanthracene, phenanthrene, benzophenanthrene, pyrene, chrysene, perylene, fluoranthene, benzofluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

In a preferred configuration, the substructure of the formula (2) may conform to at least one of the formulae (2-1), (2-2) and/or (2-3)

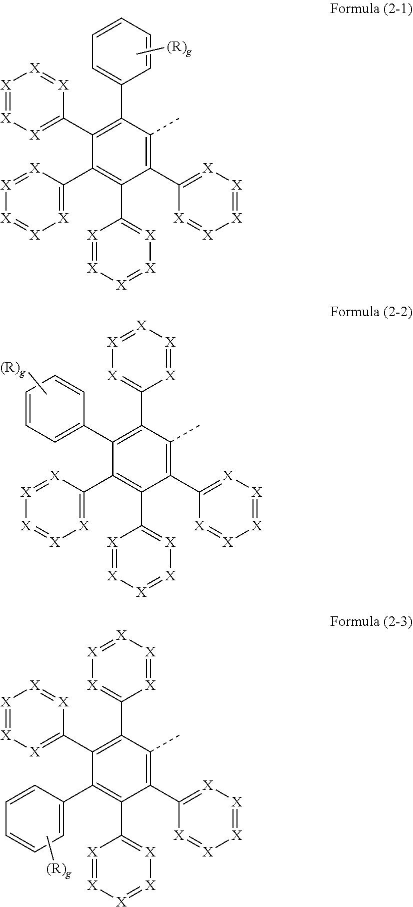

where the symbols R and X used have the definitions given above, especially for formula (2), and g is 0, 1, 2, 3, 4 or 5, preferably 0, 1, 2 or 3, where the substructure, as well as the linkage represented by a dotted bond, may have further bonds to parts of the metal complex of the formula (1).

Preferably, the metal complexes of the invention may comprise the substructures of the formula (2) that conform to at least one of the formulae (2-1a), (2-1b), (2-1c), (2-1d), (2-2a) and/or (2-2b)

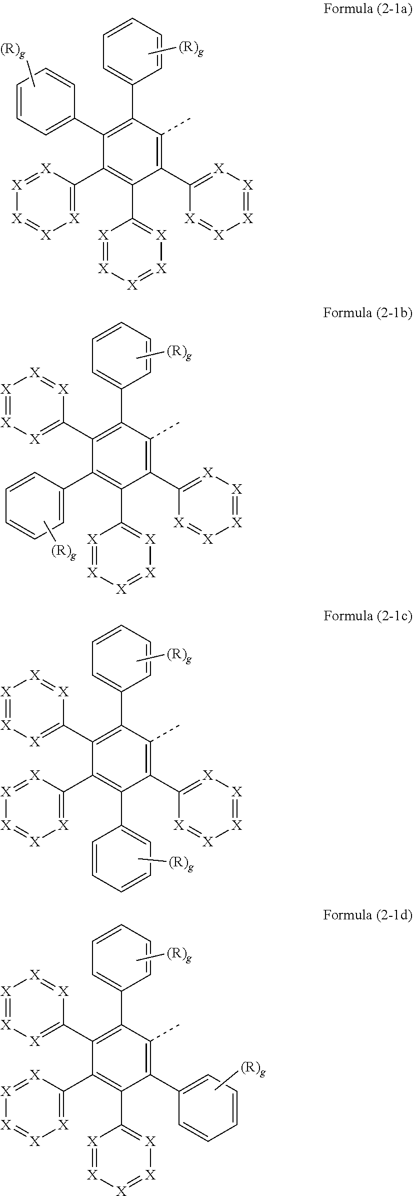

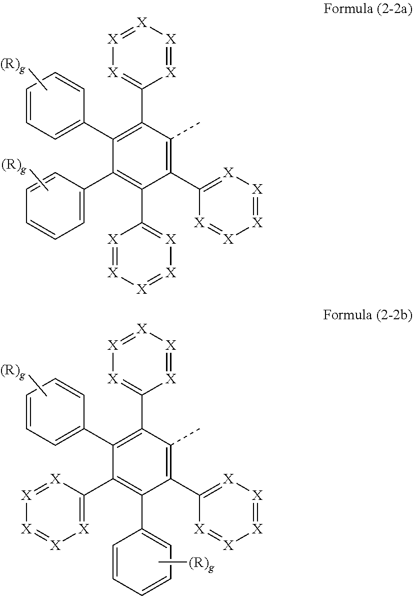

where the symbols R and X used have the definitions given above, especially for formula (2), and g is the same or different at each instance and is 0, 1, 2, 3, 4 or 5, preferably 0, 1, 2 or 3, where the substructure, as well as the linkage represented by a dotted bond, may have further bonds to parts of the metal complex of the formula (1).

It may further be the case that the above-detailed substructure of the formula (2) conforms to at least one of the formulae (2-1e), (2-1f), (2-1g), (2-1h), (2-1i) and/or (2-2c)

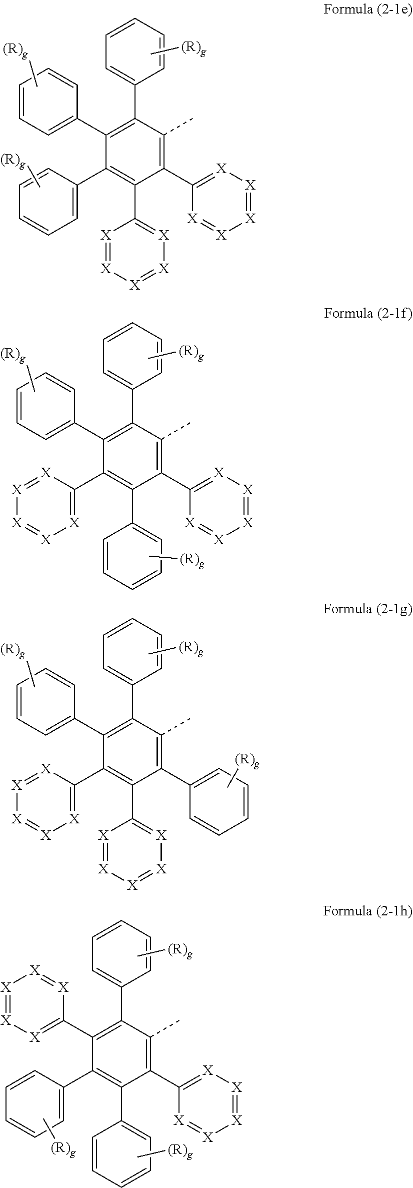

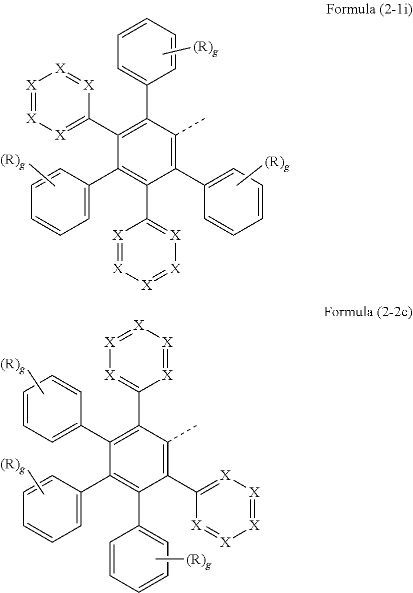

where the symbols R and X used have the definitions given above, especially for formula (2), and g is the same or different at each instance and is 01, 2, 3, 4 or 5, preferably 0, 1, 2 or 3, where the substructure, as well as the linkage represented by a dotted bond, may have further bonds to parts of the metal complex of the formula (1).

Preferably, not more than two X groups in the formulae (2), (2-1), (2-1a) to (2-1i), (2-2), (2-2a) to (2-2c), (2-3) per ring are N. More preferably, the substructure of the formula (2) or preferred embodiments thereof comprises not more than two nitrogen atoms, more preferably not more than one nitrogen atom and especially preferably no nitrogen atom. Furthermore, preference is given to compounds which are characterized in that, in formulae (2), (2-1), (2-1a) to (2-1i), (2-2), (2-2a) to (2-2c), (2-3), at least four X per ring and preferably all X are CR, where preferably at most 4, more preferably at most 3 and especially preferably at most 2 of the CR groups that X represents are not the CH group. More preferably, the substructure of the formulae (2), (2-1), (2-1a) to (2-1i), (2-2), (2-2a) to (2-2c), (2-3) comprises not more than two R radicals that are not H, more preferably not more than one and especially none.

In addition, it may be the case that the metal complex comprises at least one substructure of the formula (2-4)

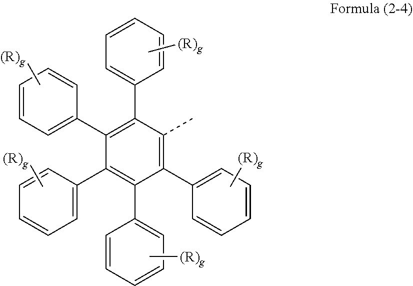

where the symbols R and X used have the definitions given above, especially for formula (2), and g is the same or different at each instance and is 0, 1, 2, 3, 4 or 5, preferably 0, 1, 2 or 3, where the substructure, as well as the linkage represented by a dotted bond, may have further bonds to parts of the metal complex of the formula (1).

It may preferably be the case that the sum total of the indices g in the structures of the formula (2), (2-1), (2-1a) to (2-1i), (2-2), (2-2a) to (2-2c), (2-3) and (2-4) in each case is at most 8, preferably at most 6, more preferably at most 4, especially preferably at most 2 and most preferably at most 1.

It may preferably be the case that the substructure of formula (2) or preferred embodiments thereof does not have any further bonds or linkages to parts of the metal complex, and so the substructures are bonded to the other parts of the metal complex only by the dotted line in the above-detailed formula (2) or preferred embodiments thereof.

In a preferred embodiment, the linkage, represented by a dotted bond in formula (2), (2-1), (2-1a) to (2-1i), (2-2), (2-2a) to (2-2c), (2-3), (2-4), of the substructure of formula (2), (2-1), (2-1a) to (2-1i), (2-2), (2-2a) to (2-2c), (2-3) and/or (2-4) is bonded to an aromatic or heteroaromatic ring system, preferably an aryl or heteroaryl radical having preferably 5 to 40 ring atoms. It is possible here for the aromatic or heteroaromatic ring system, preferably the aryl or heteroaryl radical having 5 to 40 ring atoms, preferably 5 to 24 ring atoms and especially preferably 6 to 12 ring atoms, to be substituted by one or more R radicals as defined above for formula (2); however, this radical is preferably unsubstituted. At the same time, the aromatic or heteroaromatic ring system or the aryl or heteroaryl radical is preferably part of a ligand L and coordinates directly to the metal M.

It may further be the case that the linkage, represented by a dotted bond in formula (2), (2-1), (2-1a) to (2-1i), (2-2), (2-2a) to (2-2c), (2-3) and (2-4), of the substructure of formula (2), (2-1), (2-1a) to (2-1i), (2-2), (2-2a) to (2-2c), (2-3) and/or (2-4) is bonded to an aryl or heteroaryl radical of the formula (Ar-1)

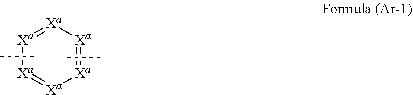

where one of the dotted bonds represents the linkage of this group to other parts of the metal complex of the formula (1) and the other of the dotted bonds represents the linkage of this group to one of the substructures of formula (2), (2-1), (2-1a) to (2-1i), (2-2), (2-2a) to (2-2c), (2-3) or (2-4) and the symbols X^{a} used are the same or different at each instance and are N, CR or C if X^{a} represents a bond to the substructure of the above-detailed formula (2) or preferred embodiments thereof or to another part of the metal complex of the formula (1), or two adjacent X^{a} groups together are O, S, NR, with the proviso that a 5-membered ring is formed, and R in each case independently has the definitions given above, especially for formula (2), where the substructure, as well as the linkage represented by a dotted bond, may have further bonds to parts of the metal complex of the formula (1).

Preferably, the aryl or heteroaryl radical of the formula (Ar-1) or preferred embodiments thereof comprises not more than two nitrogen atoms, more preferably not more than one nitrogen atom and especially preferably no nitrogen atom. Furthermore, preference is given to compounds which are characterized in that, in formula (Ar-1), at least four and preferably all X^{a} are CR or C, where preferably at most 4, more preferably at most 3 and especially preferably at most 2 of the CR groups that X^{a} represents are not the CH or C group. More preferably, the aryl or heteroaryl radical of the formula (Ar-1) or preferred embodiments thereof comprises not more than two R radicals that are not H, more preferably not more than one R radical and especially preferably no radical that is not H.

In a preferred configuration, the above-described aromatic or heteroaromatic ring system bonded to the substructure of formula (2), (2-1), (2-1a) to (2-1i), (2-2), (2-2a) to (2-2c), (2-3) and/or (2-4), especially the preferred embodiment thereof shown in formula (Ar-1), may be bonded directly to the metal atom M.

It may further be the case that the aryl or heteroaryl radical of the formula (Ar-1) is bonded to a further aryl or heteroaryl radical having 5 to 24 ring atoms which in turn interacts with the metal atom M.

Accordingly, the metal complexes of the invention preferably have substructures of the formulae (2-5) and/or (2-6)

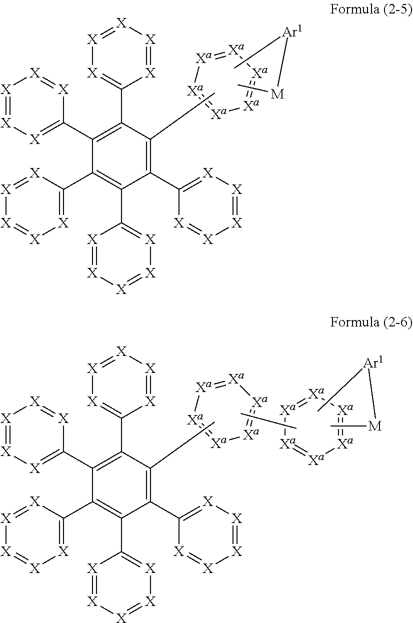

where the symbols R and X used have the definitions given above, especially for formula (2), the symbol M has the definition given above, especially for formula (1), the symbol X^{a} has the definition given above, especially for formula (Ar-1), and Ar¹ represents an aromatic or heteroaromatic ring system having 5 to 40 ring atoms which may be substituted by one or more R radicals as defined above for formula (2), where the substructure may have further bonds to parts of the metal complex of the formula (1). In a preferred embodiment, the substructure does not have any further bonds to parts of the metal complex of the formula (1).

The Ar¹ group in formulae (2-5) and/or (2-6) is an aromatic or heteroaromatic ring system having 5 to 40 ring atoms, preferably 5 to 24 ring atoms and especially preferably 6 to 12 ring atoms, which may be substituted by one or more R radicals as defined above for formula (2). Preferably, the Ar¹ group in the formulae (2-5) and/or (2-6) represents an aryl or heteroaryl radical having 5 to 40 ring atoms, preferably 5 to 24 ring atoms and especially preferably 6 to 12 ring atoms, such that the bonds shown in the formulae (2-5) and/or (2-6) are bonded directly to the further aromatic or heteroaromatic groups and the Ar¹ group forms through-conjugation with the aromatic or heteroaromatic group to which the Ar¹ group binds, as also shown by the formula (Ar-1). The Ar¹ radical may form a fused ring system together with the aromatic or heteroaromatic group to which the Ar¹ group binds, as also shown by the formula (Ar-1), such that the R groups of the respective ring systems may form an aliphatic, heteroaliphatic, aromatic or heteroaromatic ring system with the bond shown in formulae (2-5) and/or (2-6).

In a preferred embodiment of the invention, the group of the formula (Ar-1) coordinates directly to M, especially via a carbon atom, and the substructure of the formula (2) is bonded to (Ar-1) in the position para to the coordination to M. Preferably, the group of the formula (Ar-1) therefore has the structure of the following formula (Ar-1a):

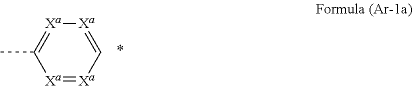

where * represents the position of coordination to M, the dotted bond represents the attachment of the substructure of the formula (2) and X^{a} has the definitions given above. Further preferably, in formulae (2-5) and (2-6), the Ar¹ group is bonded in the ortho position to the coordination to M.

In a preferred embodiment of the present invention, the Ar¹ group in formulae (2-5) and/or (2-6) is an aryl or heteroaryl group having 6 to 13 aromatic ring atoms, more preferably having 6 to 10 aromatic ring atoms, most preferably having 6 aromatic ring atoms, which coordinates to the metal via a carbon atom, which may be substituted by one or more R radicals.

In a preferred embodiment of the present invention, the Ar¹ group in formulae (2-5) and/or (2-6) is an aryl or heteroaryl group having 6 to 13 aromatic ring atoms, more preferably having 6 to 10 aromatic ring atoms, most preferably having 6 aromatic ring atoms, which coordinates to the metal via a nitrogen atom, where this group may be substituted by one or more R radicals.

Preferably, not more than two X or X^{a} groups in the formulae (2-5) and/or (2-6) per ring are N. More preferably, the substructure of the formulae (2-5) and/or (2-6) or preferred embodiments thereof comprises not more than three nitrogen atoms, more preferably not more than two nitrogen atoms and especially preferably exactly one nitrogen atom, where these substructures contain groups of the formulae X, X^{a} and Ar¹. Furthermore, preference is given to compounds which are characterized in that, in formulae (2-5) and (2-6), at least four X per ring and preferably all X are CR, where preferably at most 4, more preferably at most 3 and especially preferably at most 2 of the CR groups that X represents are not the CH group. In addition, preference is given to compounds comprising a substructure of the formula (2-5) or (2-6) or preferred embodiments thereof, in which at least two, preferably at least three, of the X^{a} groups are CR and not more than two, preferably exactly one or none of the X^{a} groups is N. When one X^{a} group is N, it is preferable when this nitrogen atom is coordinated directly to the metal M. More preferably, none of the X^{a} groups is N. More preferably, the substructure of the formulae (2-5) and/or (2-6) comprises at most eight, preferably at most six, more preferably at most four, especially preferably at most two, R radicals that are not H, more preferably at most one and especially preferably no R radical that is not H.

Preferably, one X^{a} group may be a nitrogen atom coordinated to the metal atom M. In addition, the Ar¹ radical may contain one nitrogen atom joined to the metal atom M. In this case, preferably all X^{a} groups may be a carbon atom or a CR group.

In a preferred embodiment, a substructure of the formulae (2-5) and/or (2-6) forms a bidentate ligand L of formula (1). Accordingly, the preferences detailed above and hereinafter for these bidentate ligands are also applicable to the substructures of the formulae (2-5) and/or (2-6).

The inventive metal complexes of the formula (1) may contain one, two, three or more of the substructures of the formula (2) further detailed above or preferred embodiments thereof. In a specific embodiment, an inventive metal complex of the formula (1) may comprise exactly one substructure of the formula (2). Preferably, metal complexes of the formula (1) may contain two, more preferably three or more, of the substructures of the formula (2) further detailed above or preferred embodiments thereof. Especially preferably, the inventive metal complexes of the formula (1) comprise one, two, three or six substructures of the formula (2) or preferred embodiments thereof.

There follows a description of the bidentate ligands that are identified by the symbol L in formula (1) and bonded to M. The coordinating atoms of the bidentate ligands here may be the same or different at each instance and may be selected from C, N, P, O, S and/or B, more preferably C, N and/or O and most preferably C and/or N. The bidentate ligands preferably have one carbon atom and one nitrogen atom or two carbon atoms or two nitrogen atoms or two oxygen atoms or one oxygen atom and one nitrogen atom as coordinating atoms. As described above, the bidentate ligands, when M=Ir, have at least one iridium-carbon bond. In this case, the coordinating atoms of each of the ligands may be the same, or they may be different. Preferably at least one of the bidentate ligands has, more preferably all the bidentate ligands have, one carbon atom and one nitrogen atom or two carbon atoms as coordinating atoms, especially one carbon atom and one nitrogen atom. More preferably at least two of the bidentate ligands and most preferably, when M=Ir, all three bidentate ligands have one carbon atom and one nitrogen atom or two carbon atoms as coordinating atoms, especially one carbon atom and one nitrogen atom. Particular preference is thus given to an iridium complex in which all three bidentate ligands are ortho-metallated, i.e. form a metallocycle with the iridium in which at least one iridium-carbon bond is present.

More preferably, the metal complex does not comprise any monodentate ligands, and all bidentate ligands, identically or differently at each instance, have at least one carbon atom as coordinating atom. It should be emphasized once again that the bidentate ligands may be joined to one another and may have further coordination sites, and so the term “bidentate ligand” refers to a ligand having at least two coordination sites. In the case that a bidentate ligand has exactly two coordination sites, this is stated explicitly. In this connection, it should also be noted that the index n in formula (1) may be 1 and the index m may simultaneously be 0, where, in this case, for example, the bidentate ligands L are joined to one another and form a hexadentate ligand system. In this case, the three ligands bonded to one another may also be regarded as sub-ligands.

The indices in the above-detailed formula (1) or the preferred embodiments of this formula are dependent on the type of metal and possible linkage of the ligands. For unbridged iridium complexes (M=Ir), n is more preferably 3 and m is 0. Since platinum in preferred complexes is only tetracoordinated, for unbridged platinum complexes (M=Pt), n is more preferably 2 and m=0. In the case of bridged complexes, the bidentate ligands can be regarded as sub-ligands, and so, when considered in this way, the details given above are applicable. Otherwise, according to the degree of bridging, n in particularly preferred embodiments as described above and hereinafter is 1 in each case, particular preference being given to formation of a metal complex containing iridium and a hexadentate tripodal ligand or a metal complex containing platinum and a tetradentate ligand.

Preferably, the metal complex of formula (1) comprises three bidentate ligands which may optionally also be joined. The three bidentate ligands may be the same or different. When the bidentate ligands are the same, they preferably also have the same substitution. When all three bidentate ligands chosen are the same, the result in the case of polypodal complexes is C₃-symmetric iridium complexes. It may also be advantageous to select the three bidentate ligands differently or to select two identical ligands and a different third ligand, so as to give rise to C₁-symmetric metal complexes, because this permits greater possible variation of the ligands, such that the desired properties of the complex, for example the HOMO and LUMO position or the emission color, can be varied more easily. Moreover, the solubility of the complexes can thus also be improved without having to attach long aliphatic or aromatic solubility-imparting groups.

In a preferred embodiment of the invention, either the three bidentate ligands are selected identically or two of the bidentate ligands are selected identically and the third bidentate ligand is different from the first two bidentate ligands.

It is further preferable when the metallocycle which is formed from the metal and the bidentate ligand is a five-membered ring, which is preferable particularly when the coordinating atoms are C and N, C and C, N and N, or N and O. When the coordinating atoms are O, a six-membered metallocyclic ring may also be preferred. This is shown schematically hereinafter:

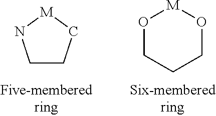

where N is a coordinating nitrogen atom, C is a coordinating carbon atom and O represents coordinating oxygen atoms, and the carbon atoms shown are atoms of the bidentate ligand.

In a preferred embodiment of the invention, at least one of the bidentate ligands, more preferably at least two of the bidentate ligands, most preferably, when M=Ir, all three bidentate ligands of the metal complex shown in formula (1), are the same or different at each instance and are selected from the structures of the following formulae (L-1), (L-2) and (L-3):

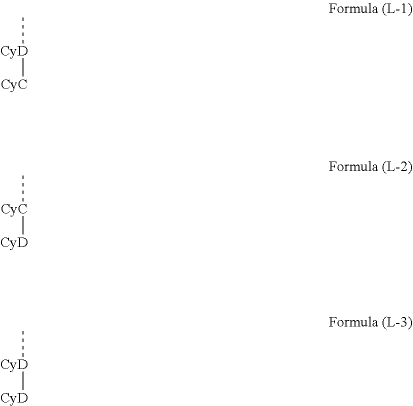

where the symbols used are as follows:
CyC is the same or different at each instance and is a substituted or unsubstituted aryl or heteroaryl group which has 5 to 14 aromatic ring atoms and coordinates in each case to the metal via a carbon atom and which is bonded to CyD via a covalent bond in each case;
CyD is the same or different at each instance and is a substituted or unsubstituted heteroaryl group which has 5 to 14 aromatic ring atoms and coordinates to the metal via a nitrogen atom or via a carbene carbon atom and which is bonded to CyC via a covalent bond;

at the same time, it is also possible for two or more ligands (L-1), (L-2) and/or (L-3) to be joined to one another via a single bond or a bivalent or trivalent bridge, thus forming a tridentate, tetradentate, pentadentate or hexadentate ligand system; where these optional bonds to a bridge are indicated by the dotted bond; at the same time, two or more of the optional substituents together may form a ring system; at the same time, a substituent may also additionally coordinate to M; in addition, the optional radicals are preferably selected from the abovementioned R radicals and/or the substructure of the formula (2).

At the same time, CyD in the ligands of the formulae (L-1) and (L-2) preferably coordinates via an uncharged nitrogen atom or via a carbene carbon atom. Further preferably, one of the two CyD groups in the ligand of the formula (L-3) coordinates via an uncharged nitrogen atom and the other of the two CyD groups via an anionic nitrogen atom. Further preferably, CyC in the ligands of the formulae (L-1) and (L-2) coordinates via anionic carbon atoms.

Further preferably, the substructure of the formula (2) binds to one of the CyC and CyD groups, preferably to CyC. CyC here preferably conforms to the above-adduced structure of the formula (Ar-1) when one X^{a} group in this structure is C which coordinates to M, or CyD conforms to the above-adduced structure of the formula (Ar-1) when one X^{a} group in this structure is N which coordinates to M.

When two or more of the substituents, especially two or more R radicals, together form a ring system, it is possible for a ring system to be formed from substituents bonded to directly adjacent carbon atoms. In addition, it is also possible that the substituents on CyC and CyD in the formulae (L-1) and (L-2) or the substituents on the two CyD groups in formula (L-3) together form a ring, as a result of which CyC and CyD or the two CyD groups or the two CyC groups may also together form a single fused aryl or heteroaryl group as bidentate ligand.

In a preferred embodiment of the present invention, CyC is an aryl or heteroaryl group having 6 to 13 aromatic ring atoms, more preferably having 6 to 10 aromatic ring atoms, most preferably having 6 aromatic ring atoms, which coordinates to the metal via a carbon atom, which may be substituted by one or more R radicals and which is bonded to CyD via a covalent bond. More preferably, CyC is a group of the above-adduced formula (Ar-1).

Preferred embodiments of the CyC group are the structures of the following formulae (CyC-1) to (CyC-20):

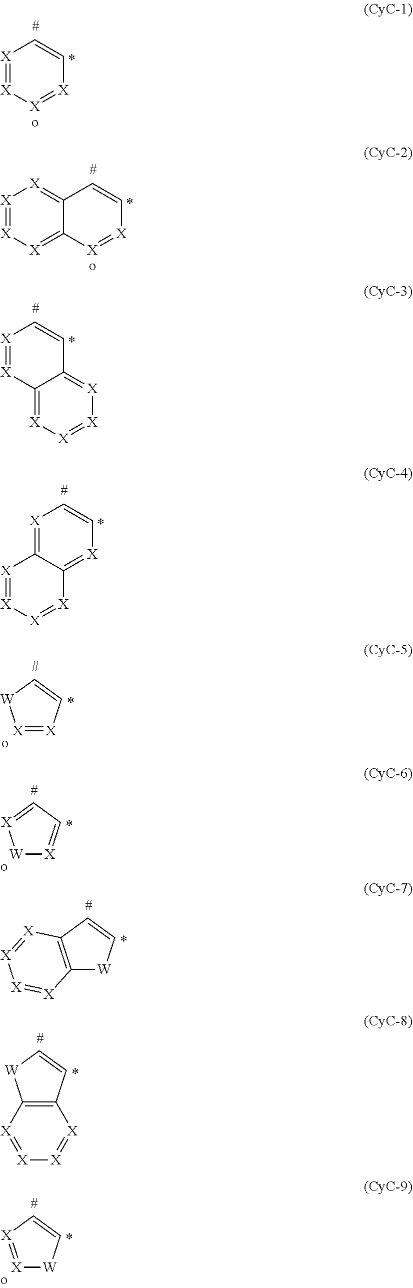

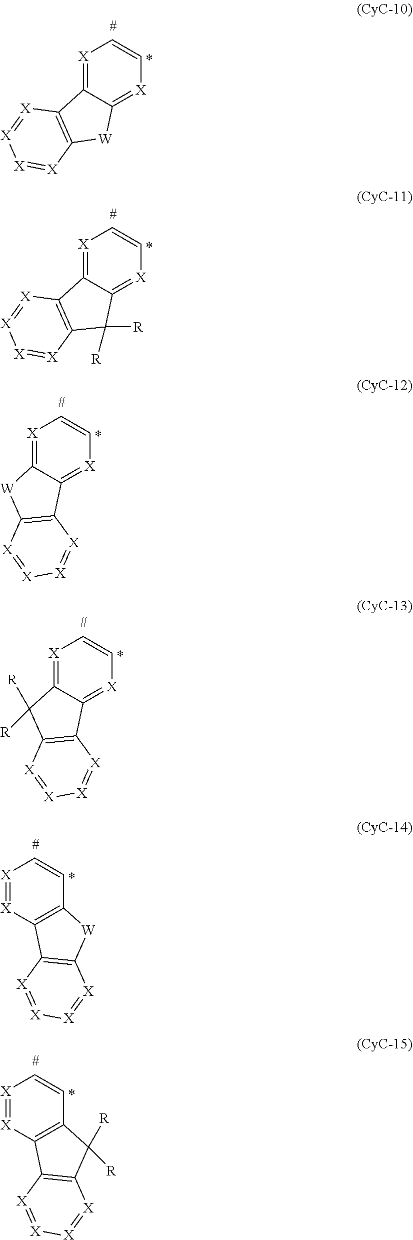

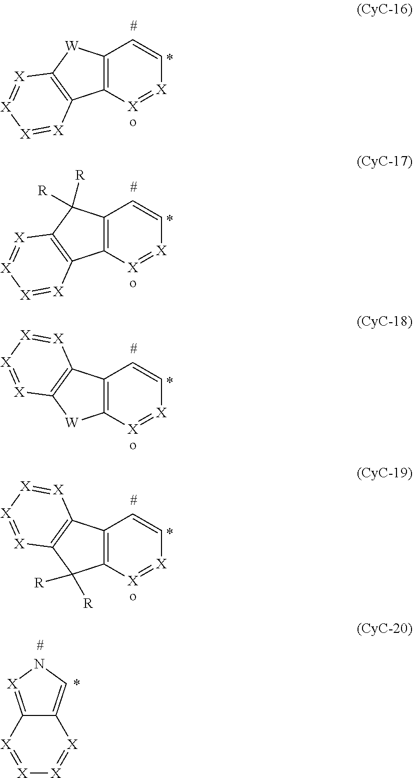

where CyC binds in each case to the position in CyD indicated by # and coordinates to the metal at the position indicated by *, R has the definitions given above and the further symbols used are as follows:
X is the same or different at each instance and is CR or N, where preferably not more than two X symbols per cycle are N;
W is NR, O or S;

where the ligands may optionally be bonded by a bridge via the CyC group, where the bond to the bridge may preferably be via the position marked “o”, where the position marked “o” represents a carbon atom if it constitutes a bridgehead site. When the CyC group is bonded to a bridge, the bond is preferably via the position marked “o” in the formulae depicted above, and so the symbol X marked “o” in that case is preferably C. The above-depicted structures which do not contain any symbol X marked “o” are preferably not bonded directly to a bridge, since such a bond to the bridge is not advantageous for steric reasons.

Preferably, a total of not more than two symbols X in CyC are N, more preferably not more than one symbol X in CyC is N, and especially preferably all symbols X are CR, with the proviso that, when CyC is bonded to a bridge, one symbol X is C and the bridge is bonded to this carbon atom.

Particularly preferred CyC groups are the groups of the following formulae (CyC-1a) to (CyC-20a):

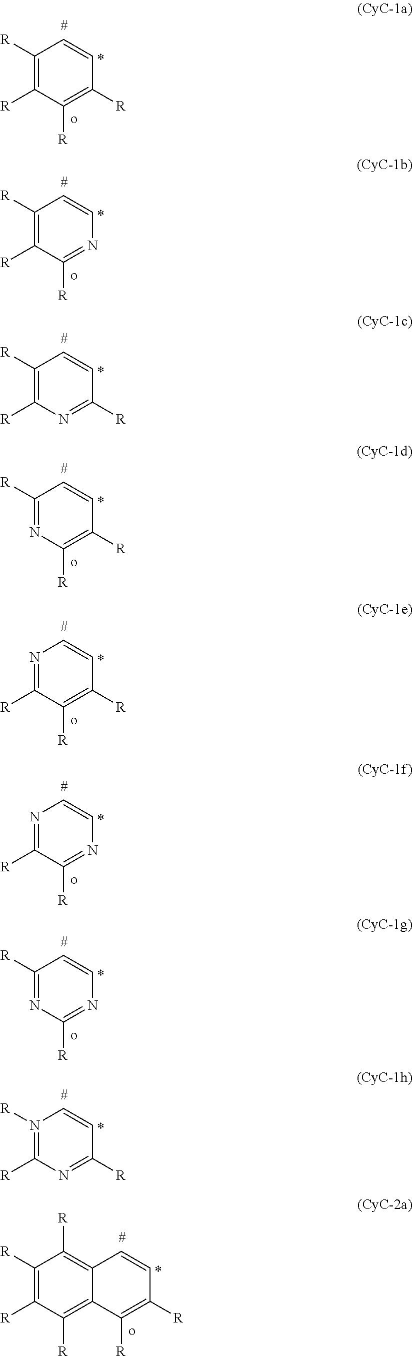

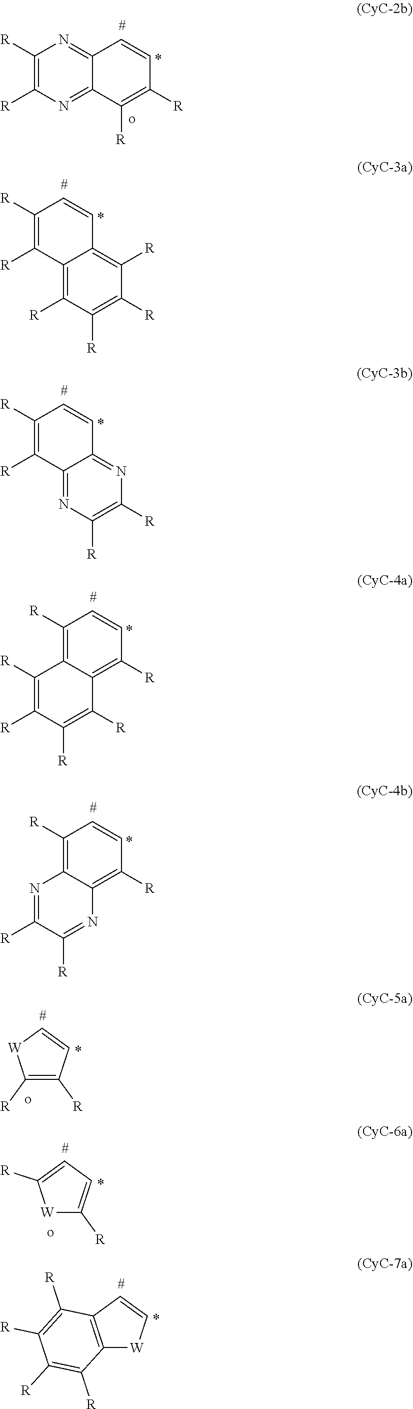

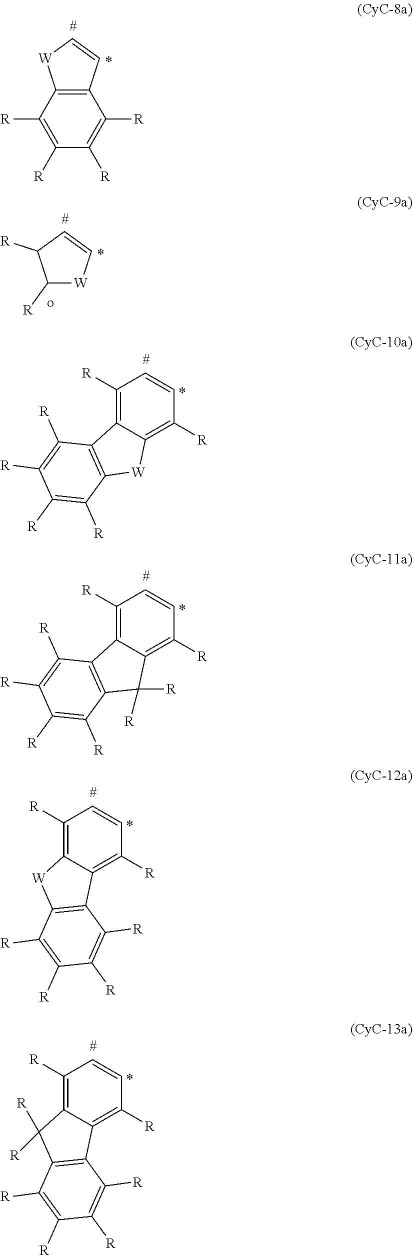

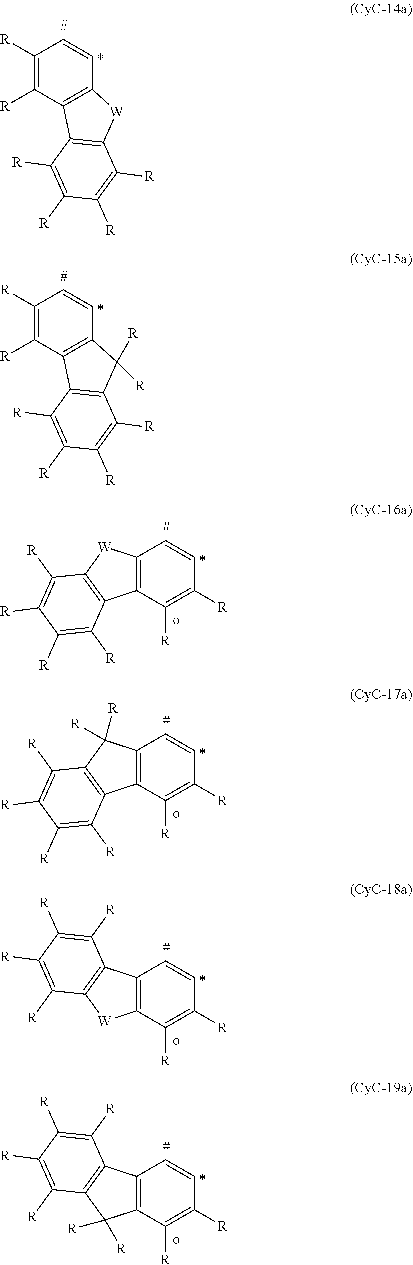

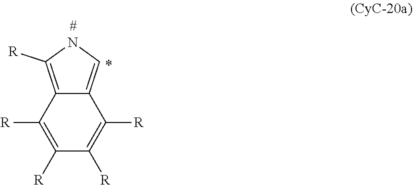

where the symbols have the definitions given above and, when the bridge is bonded to CyC, one R radical is absent and the bridge is bonded to the corresponding carbon atom. When a CyC group is bonded to a bridge, the bond is preferably via the position marked “o” in the formulae depicted above, and so the R radical in this position in that case is preferably absent. The above-depicted structures which do not contain any carbon atom marked “o” are preferably not bonded directly to a bridge.

Preferred groups among the (CyC-1) to (CyC-19) groups are the (CyC-1), (CyC-3), (CyC-8), (CyC-10), (CyC-12), (CyC-13) and (CyC-16) groups, and particular preference is given to the (CyC-1a), (CyC-3a), (CyC-8a), (CyC-10a), (CyC-12a), (CyC-13a) and (CyC-16a) groups.

It may further be the case that CyC comprises a substructure of the formula (2) or the preferred embodiment of this substructure or is formed by suitable substitution by R radicals, where the X groups in formula (2) in this case are CR¹. More preferably, one R radical in the above-detailed embodiments of the CyC group represents a substructure of the formula (2), such that the bonding site shown by a dotted bond in formula (2) is bonded directly to the aromatic or heteroaromatic ring system shown in the CyC group.

In a further preferred embodiment of the invention, CyD is a heteroaryl group having 5 to 13 aromatic ring atoms, more preferably having 6 to 10 aromatic ring atoms, which coordinates to the metal via an uncharged nitrogen atom or via a carbene carbon atom and which may be substituted by one or more R radicals and which is bonded via a covalent bond to CyC.

Preferred embodiments of the CyD group are the structures of the following formulae (CyD-1) to (CyD-14):

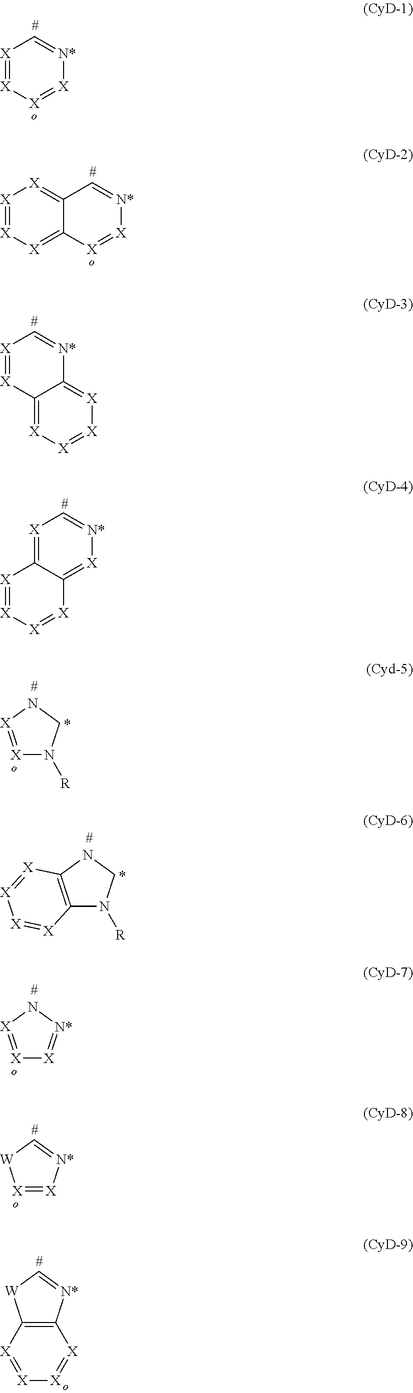

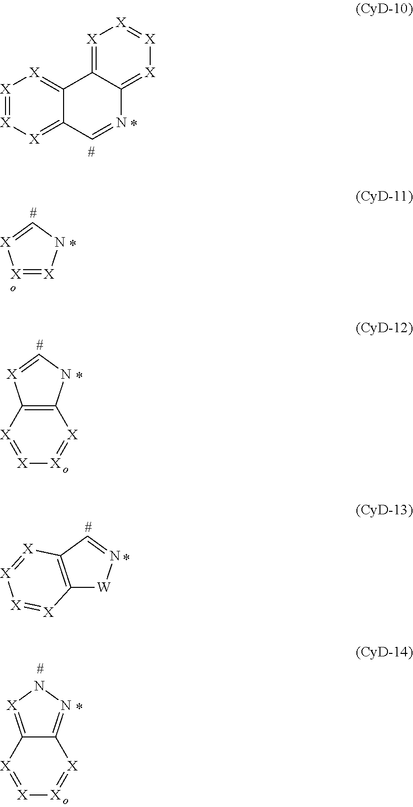

where the CyD group binds to CyC in each case at the position identified by # and coordinates to the metal at the position identified by *, where X, W and R have the definitions given above and where the ligands may optionally be bonded by a bridge via the CyD group, where the bond to the bridge is preferably via the position marked “o”, where the position marked “o” represents a carbon atom if it constitutes a bridgehead site. When the CyD group is bonded to a bridge, the bond is preferably via the position marked “o” in the formulae depicted above, and so the symbol X marked “o” in that case is preferably C. The above-depicted structures which do not contain any symbol X marked “o” are preferably not bonded directly to a bridge, since such a bond to the bridge is not advantageous for steric reasons.

In this case, the (CyD-1) to (CyD-4), (CyD-7) to (CyD-10), (CyD-13) and (CyD-14) groups coordinate to the metal via an uncharged nitrogen atom, the (CyD-5) and (CyD-6) groups via a carbene carbon atom and the (CyD-11) and (CyD-12) groups via an anionic nitrogen atom.

Preferably, a total of not more than two symbols X in CyD are N, more preferably not more than one symbol X in CyD is N, and especially preferably all symbols X are CR, with the proviso that, when CyD is bonded to a bridge, one symbol X is C and the bridge is bonded to this carbon atom.

Particularly preferred CyD groups are the groups of the following formulae (CyD-1a) to (CyD-14b):

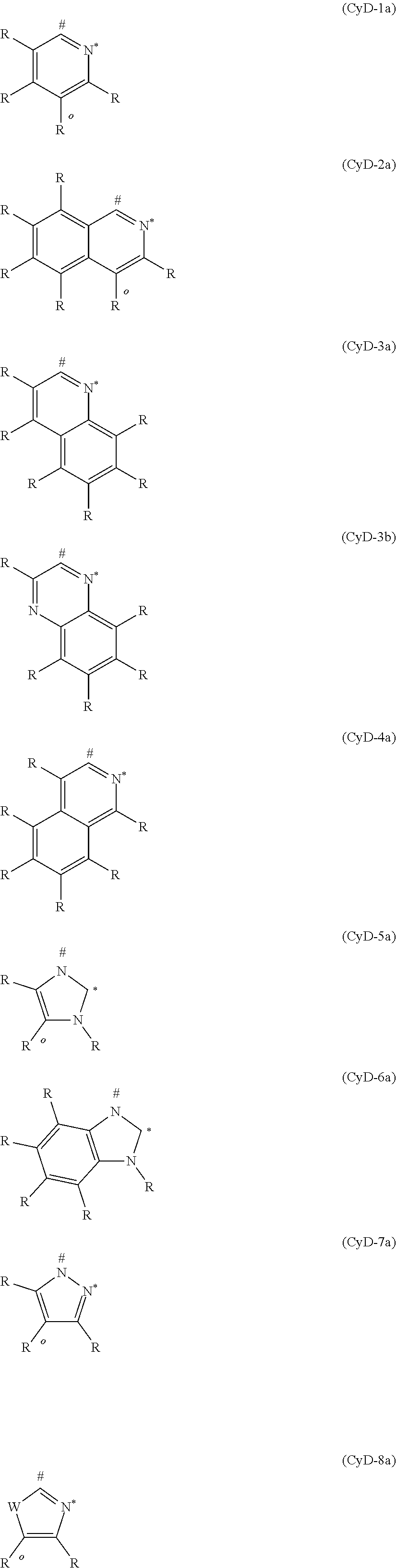

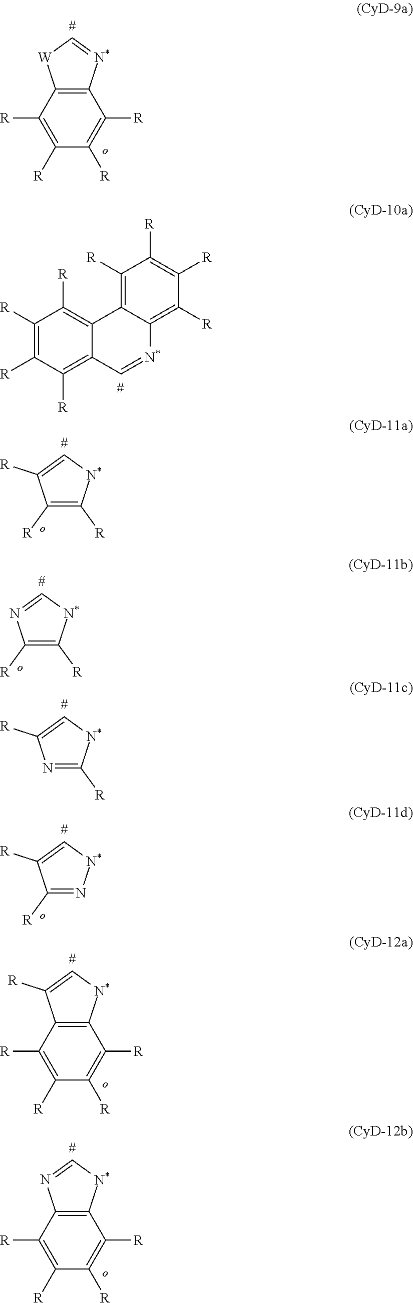

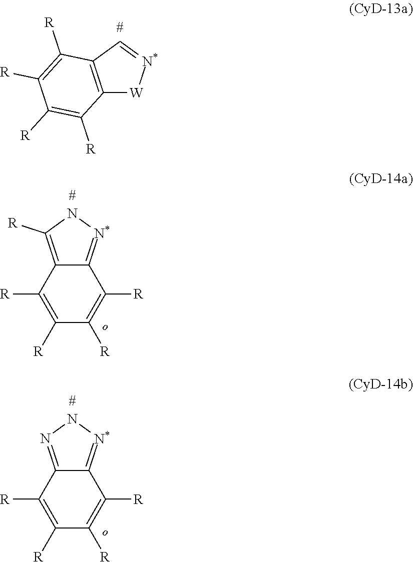

where the symbols used have the definitions given above and, when the bridge is bonded to CyD, one R radical is absent and the bridge is bonded to the corresponding carbon atom. When the CyD group is bonded to a bridge, the bond is preferably via the position marked “o” in the formulae depicted above, and so the R radical in this position in that case is preferably absent. The above-depicted structures which do not contain any carbon atom marked “o” are preferably not bonded directly to a bridge.

Preferred groups among the (CyD-1) to (CyD-10) groups are the (CyD-1), (CyD-2), (CyD-3), (CyD-4), (CyD-5) and (CyD-6) groups, especially (CyD-1), (CyD-2) and (CyD-3), and particular preference is given to the (CyD-1a), (CyD-2a), (CyD-3a), (CyD-4a), (CyD-5a) and (CyD-6a) groups, especially (CyD-1a), (CyD-2a) and (CyD-3a).

In a preferred embodiment of the present invention, CyC is an aryl or heteroaryl group having 6 to 13 aromatic ring atoms, and at the same time CyD is a heteroaryl group having 5 to 13 aromatic ring atoms. More preferably, CyC is an aryl or heteroaryl group having 6 to 10 aromatic ring atoms, and at the same time CyD is a heteroaryl group having 5 to 10 aromatic ring atoms. Most preferably, CyC is an aryl or heteroaryl group having 6 aromatic ring atoms, and CyD is a heteroaryl group having 6 to 10 aromatic ring atoms. At the same time, CyC and CyD may be substituted by one or more R radicals.

It may further be the case that CyD comprises a substructure of the formula (2) or the preferred embodiment of this substructure or is formed by suitable substitution by R radicals, where the X groups in formula (2) in this case are CR¹. More preferably, one R radical in the above-detailed embodiments of the CyD group represents a substructure of the formula (2), such that the bonding site shown by a dotted bond in formula (2) is bonded directly to the aromatic or heteroaromatic ring system shown in the CyD group. Especially preferably, the substructure of the formula (2) or the preferred embodiment of this substructure is bonded to a CyC group or is formed by an appropriate substitution, and CyD does not have a substructure of the formula (2).

The abovementioned preferred groups (CyC-1) to (CyC-20) and (CyD-1) to (CyD-14) may be combined with one another as desired in the ligands of the formulae (L-1) and (L-2). In this case, at least one of the CyC or CyD groups may have a suitable attachment site to a bridge, where suitable attachment sites in the abovementioned formula are identified by “o”. It is especially preferable when the CyC and CyD groups mentioned as particularly preferred above, i.e. the groups of the formulae (CyC-1a) to (CyC-20a) and the groups of the formulae (CyD1-a) to (CyD-14b), are combined with one another. Combinations in which neither CyC nor CyD has such a suitable attachment site for a bridge are therefore not preferred.

It is very particularly preferable when one of the (CyC-1), (CyC-3), (CyC-8), (CyC-10), (CyC-12), (CyC-13) and (CyC-16) groups and especially the (CyC-1a), (CyC-3a), (CyC-8a), (CyC-10a), (CyC-12a), (CyC-13a) and (CyC-16a) groups is combined with one of the (CyD-1), (CyD-2) and (CyD-3) groups and especially with one of the (CyD-1a), (CyD-2a) and (CyD-3a) groups.

Preferred ligands (L-1) are the structures of the following formulae (L-1-1) and (L-1-2), and preferred ligands (L-2) are the structures of the following formulae (L-2-1) to (L-2-4):

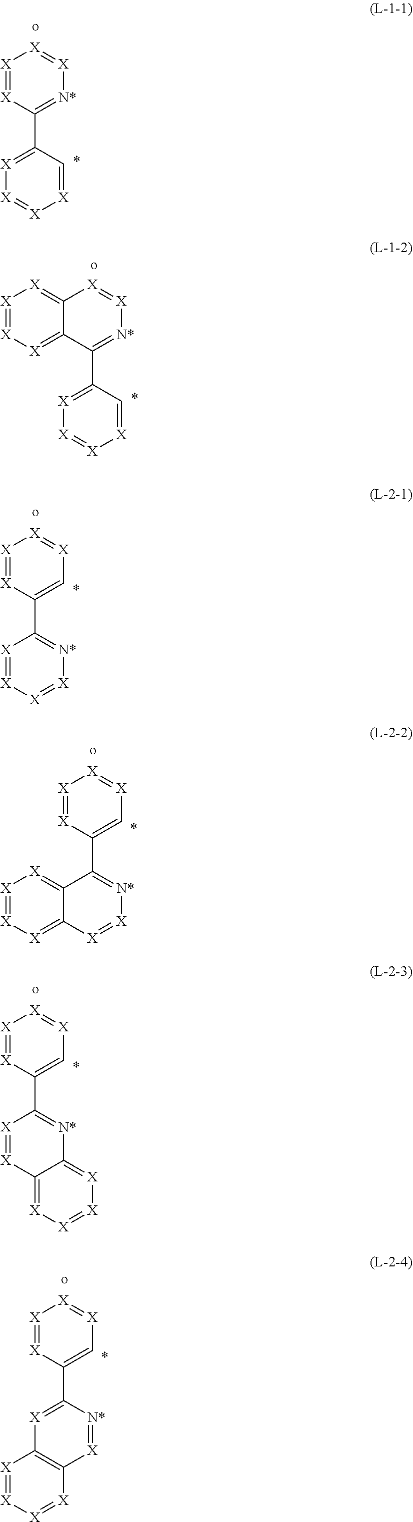

where the symbols used have the definitions given above and the ligands may optionally be bonded by a bridge, where the bond to the bridge may preferably be via the position marked “o”, where the position marked “o” represents a carbon atom if it constitutes a bridgehead site.

Particularly preferred ligands (L-1) are the structures of the following formulae (L-1-1a) and (L-1-2b), and particularly preferred ligands (L-2) are the structures of the following formulae (L-2-1a) to (L-2-4a):

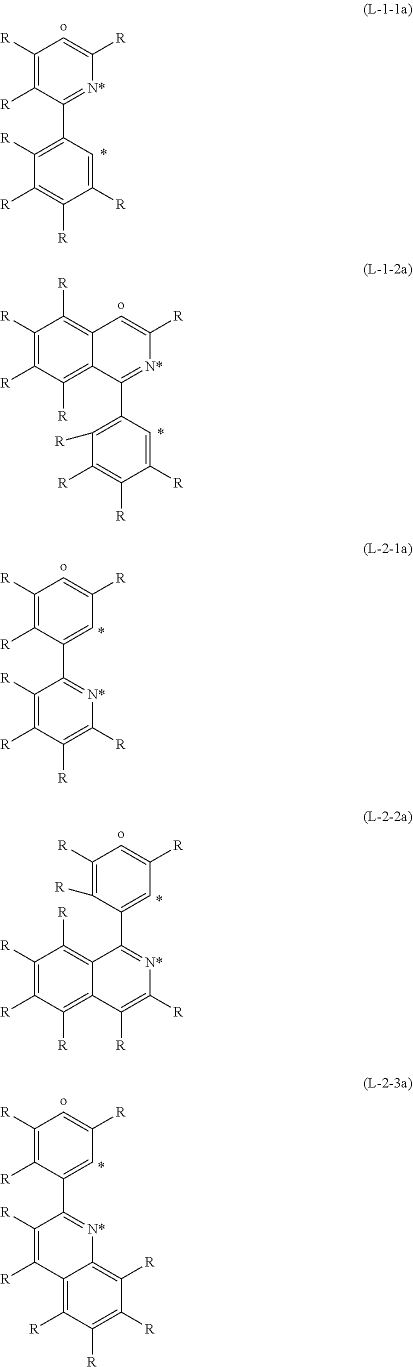

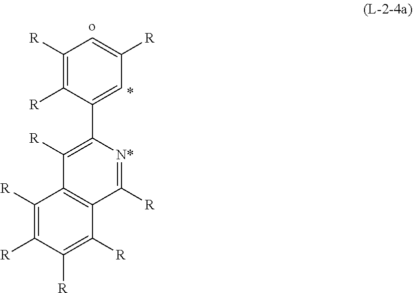

where the symbols used have the definitions given above and the ligands may optionally be bonded by a bridge, where the bond to the bridge may preferably be via the position marked “o”, where the position marked “o” represents a carbon atom if it constitutes a bridgehead site. If the ligands are unbridged, the position marked “o” may also be substituted by an R radical.

It is likewise possible for the abovementioned preferred CyD groups in the ligands of the formula (L-3) to be combined with one another as desired, it being preferable to combine an uncharged CyD group, i.e. a (CyD-1) to (CyD-10), (CyD-13) or (CyD-14) group, with an anionic CyD group, i.e. a (CyD-11) or (CyD-12) group, where the ligands may optionally be bonded by a bridge, where the bond to the bridge may preferably be via the position marked “o”, where suitable attachment sites in the abovementioned formula are identified by “o”.

When two R radicals, one of them bonded to CyC and the other to CyD in the formulae (L-1) and (L-2) or one of them bonded to one CyD group and the other to the other CyD group in formula (L-3), form an aromatic ring system with one another, this may result in bridged ligands and, for example, also in ligands which constitute a single larger heteroaryl group overall, for example benzo[h]quinoline, etc. The ring formation between the substituents on CyC and CyD in the formulae (L-1) and (L-2) or between the substituents on the two CyD groups in formula (L-3) is preferably via a group according to one of the following formulae (RB-1) to (RB-10):

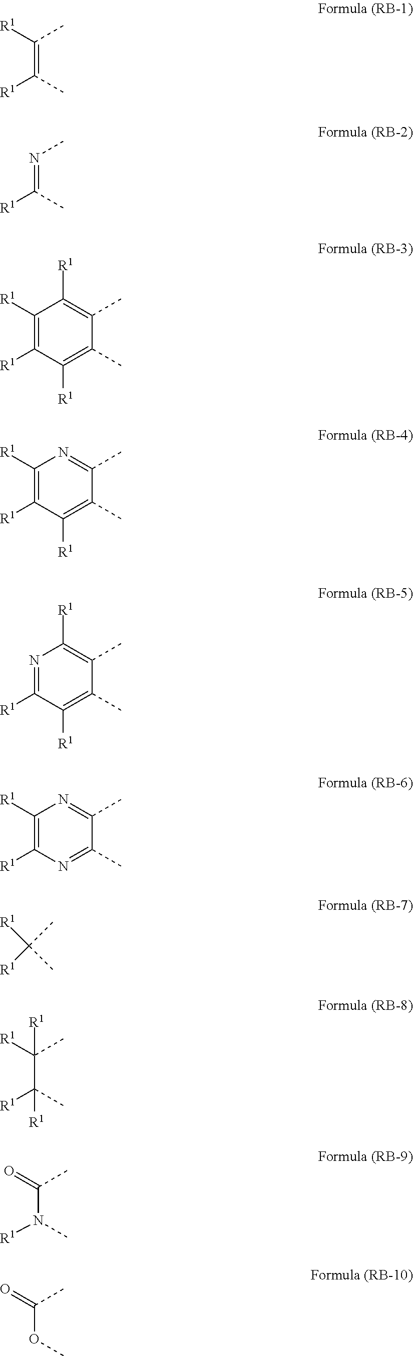

where R¹ has the definitions given above and the dotted bonds signify the bonds to CyC or CyD. At the same time, the unsymmetric groups among those mentioned above may be incorporated in each of the two options; for example, in the group of the formula (RB-10), the oxygen atom may bind to the CyC group and the carbonyl group to the CyD group, or the oxygen atom may bind to the CyD group and the carbonyl group to the CyC group.

At the same time, the group of the formula (RB-7) is preferred particularly when this results in ring formation to give a six-membered ring, as shown below, for example, by the formulae (L-23) and (L-24).

Preferred ligands which arise through ring formation between two R radicals in the different cycles are the structures of the formulae (L-5) to (L-32) shown below:

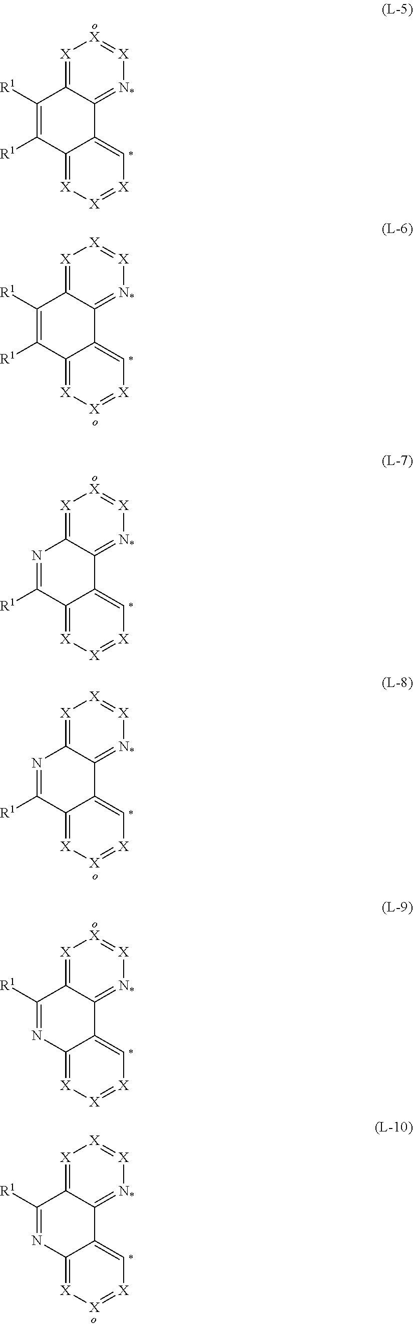

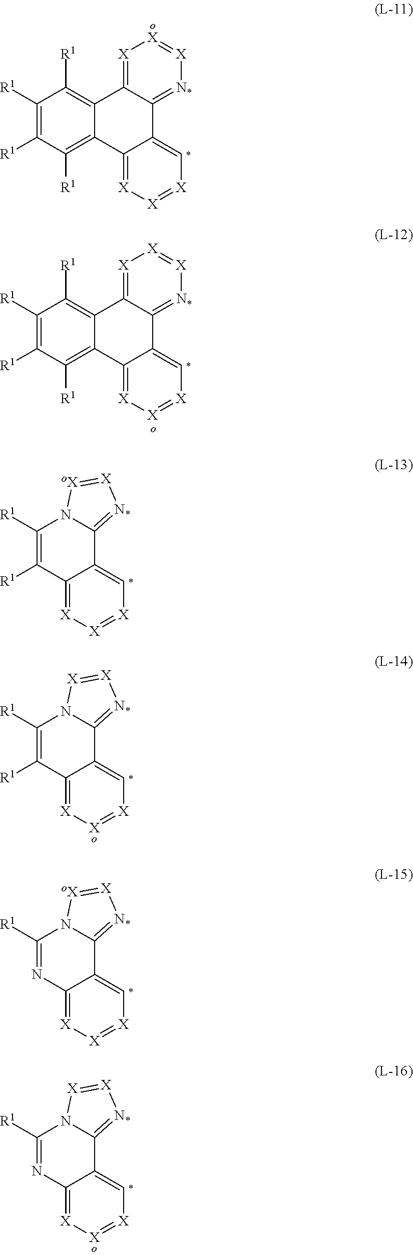

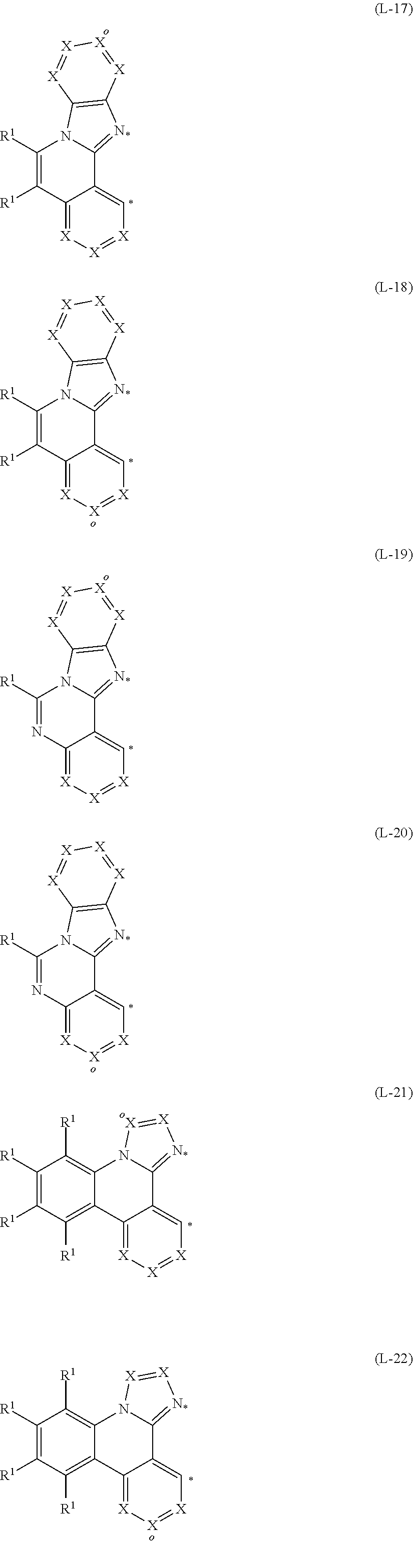

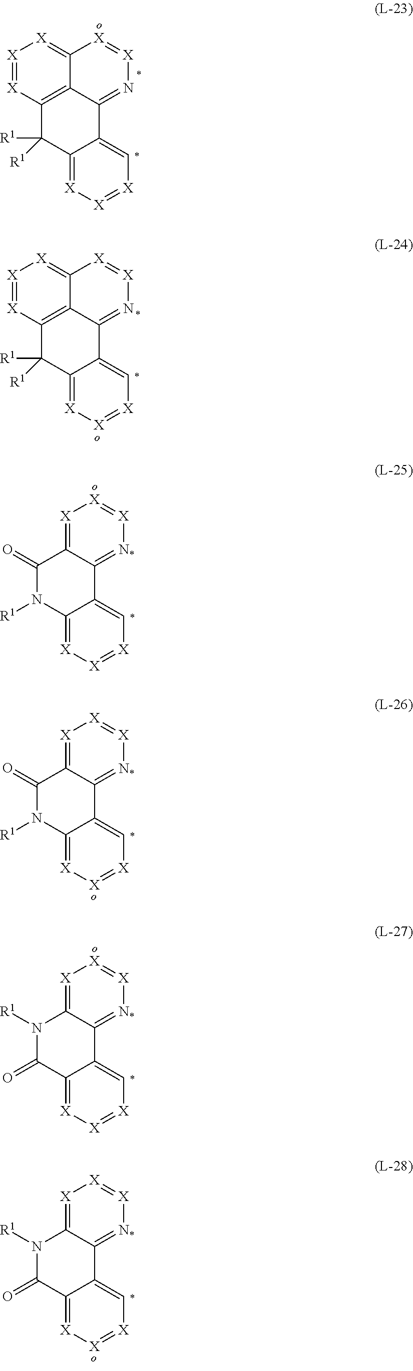

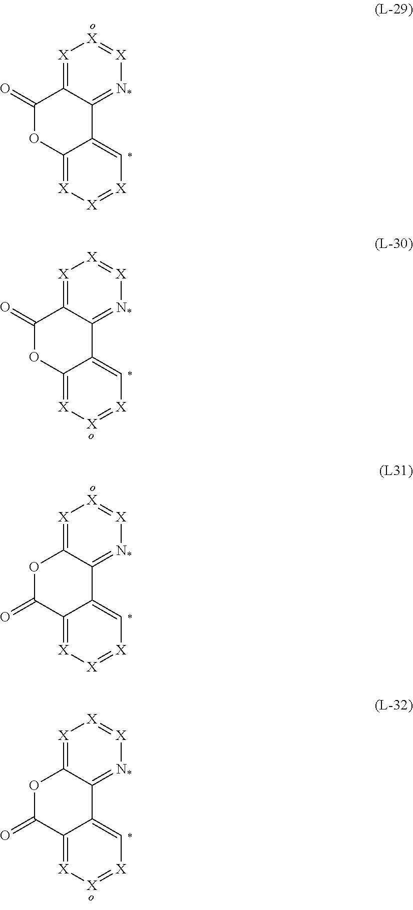

where the symbols used have the definitions given above, where the ligands may optionally be bonded by a bridge, where the bond to the bridge may preferably be via the position marked “o”, where the position marked “o” represents a carbon atom if it constitutes a bridgehead site.

In a preferred embodiment of the ligands of the formulae (L-5) to (L-32), overall, one symbol X is N and the other symbols X are CR, or all symbols X are CR, with the proviso that, when these ligands are bonded via a bridge, one symbol X is C and the bridge is bonded to this carbon atom.

In a further embodiment of the invention, it is preferable if, in the groups (CyC-1) to (CyC-20) or (CyD-1) to (CyD-14) or in the ligands (L-5) to (L-3), one of the atoms X is N when an R group bonded as a substituent adjacent to this nitrogen atom is not hydrogen or deuterium. This applies analogously to the preferred structures (CyC-1a) to (CyC-20a) or (CyD-1a) to (CyD-14b) in which a substituent bonded adjacent to a non-coordinating nitrogen atom is preferably an R group which is not hydrogen or deuterium. This substituent R is preferably a group selected from CF₃, OCF₃, alkyl or alkoxy groups having 1 to 10 carbon atoms, especially branched or cyclic alkyl or alkoxy groups having 3 to 10 carbon atoms, a dialkylamino group having 2 to 10 carbon atoms, aromatic or heteroaromatic ring systems or aralkyl or heteroaralkyl groups. These groups are sterically demanding groups. Further preferably, this R radical may also form a cycle with an adjacent R radical.

A further suitable bidentate ligand is the ligand of the following formula (L-33) or (L-34)

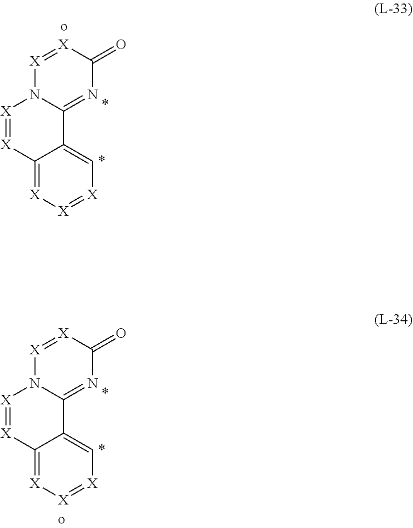

where R has the definitions given above, * represents the position of coordination to the metal, where the ligands may optionally be bonded by a bridge, where the bond to the bridge may preferably be via the position marked “o”, and the further symbols used are as follows:
X is the same or different at each instance and is CR or N, with the proviso that not more than one X symbol per cycle is N, where X is C if the ligand at this position is bonded to a bridge.

When two R radicals bonded to adjacent carbon atoms in the ligands (L-33) and (L-34) form an aromatic cycle with one another, this cycle together with the two adjacent carbon atoms is preferably a structure of the following formula (BR-11):

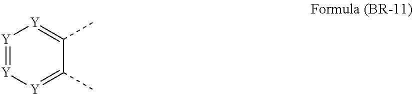

where the dotted bonds symbolize the linkage of this group within the ligand and Y is the same or different at each instance and is CR¹ or N and preferably not more than one symbol Y is N.

In a preferred embodiment of the ligand (L-33) or (L-34), not more than one group of the formula (50) is present. The ligands are thus preferably ligands of the following formulae (L-35) to (L-40):

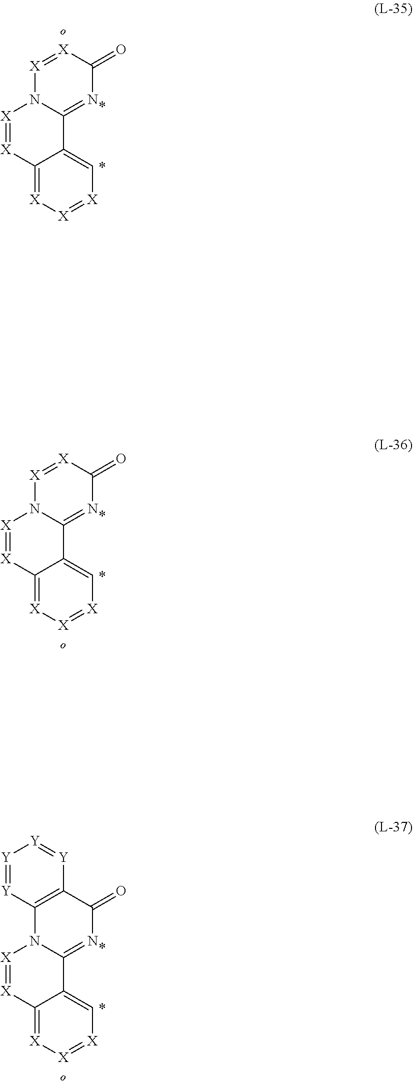

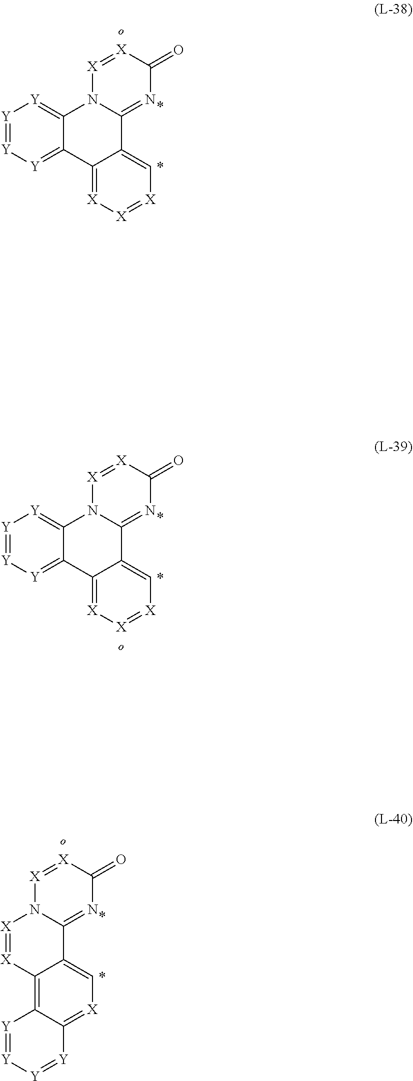

where X is the same or different at each instance and is CR or N, but the R radicals do not form an aromatic or heteroaromatic ring system with one another and the further symbols have the definitions given above, where the ligands may optionally be bonded by a bridge, where the bond to the bridge may preferably be via the position marked “o”, where the position marked “o” represents a carbon atom if this constitutes a bridgehead site.

In a preferred embodiment of the invention, in the ligand of the formulae (L-33) to (L-40), a total of 0, 1 or 2 of the symbols X and, if present, Y are N. More preferably, a total of 0 or 1 of the symbols X and, if present, Y are N.

In a preferred embodiment of the invention, the X group in the ortho position to the coordination to the metal is CR. In this radical, R bonded in the ortho position to the coordination to the metal is preferably selected from the group consisting of H, D, F and methyl.

In a further embodiment of the invention, it is preferable, if one of the atoms X or, if present, Y is N, when a substituent bonded adjacent to this nitrogen atom is an R group which is not hydrogen or deuterium. This substituent R is preferably a group selected from CF₃, OCF₃, alkyl or alkoxy groups having 1 to 10 carbon atoms, especially branched or cyclic alkyl or alkoxy groups having 3 to 10 carbon atoms, a dialkylamino group having 2 to 10 carbon atoms, aromatic or heteroaromatic ring systems or aralkyl or heteroaralkyl groups. These groups are sterically demanding groups. Further preferably, this R radical may also form a cycle with an adjacent R radical.

Further suitable bidentate ligands are the structures of the following formulae (L-41) to (L-45), where preferably not more than one of the bidentate ligands is one of these structures,

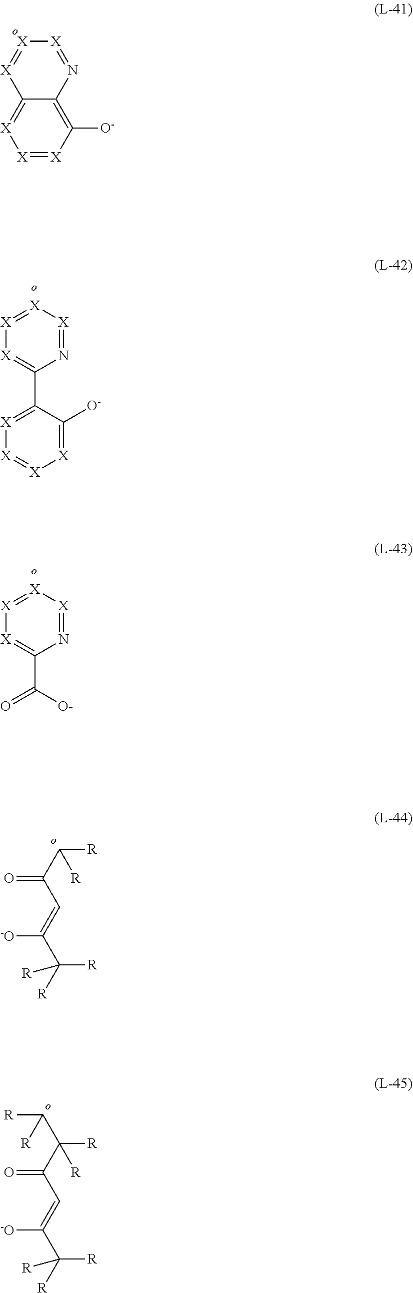

where the ligands (L-41) to (L-43) each coordinate to the metal via the nitrogen atom shown explicitly and the negatively charged oxygen atom and the ligands (L-44) and (L-45) via the two oxygen atoms, X has the definitions given above, where the ligands may optionally be bonded by a bridge, where the bond to the bridge may preferably be via the position marked by “o”, where X is C if the ligand is bonded to a bridge at this position, or, in formula (L-44) or (L-45), the carbon atom may have a substituent R if the ligand is not bonded to a bridge at this position.

The above-recited preferred embodiments of X are also preferred for the ligands of the formulae (L-41) to (L-43).

Preferred ligands of the formulae (L-41) to (L-43) are therefore the ligands of the following formulae (L-41a) to (L-43a):

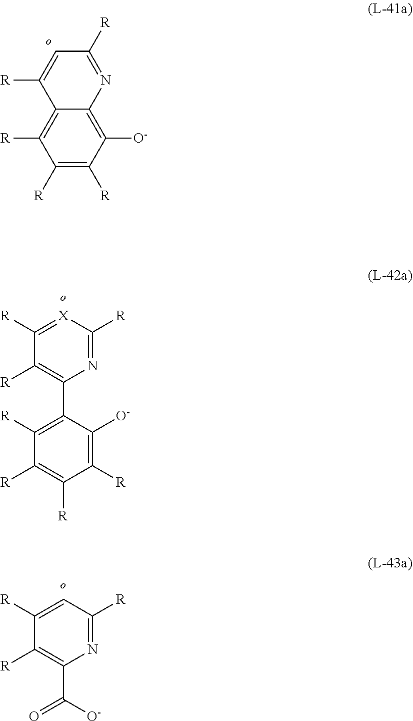

where the symbols used have the definitions given above and one R group is absent, where the ligands may optionally be bonded by a bridge, where the bond to the bridge may preferably be via the position marked “o” or, in formula (L-41a), (L-42a) or (L-43a), the carbon atom may have a substituent R if the ligand at this position is not bonded to a bridge.

More preferably, in these formulae, R is hydrogen, where the ligands may optionally be bonded by a bridge, where the bond to the bridge may preferably be via the position marked “o”, and so the structures are those of the following formulae (L-41b) to (L-43b):

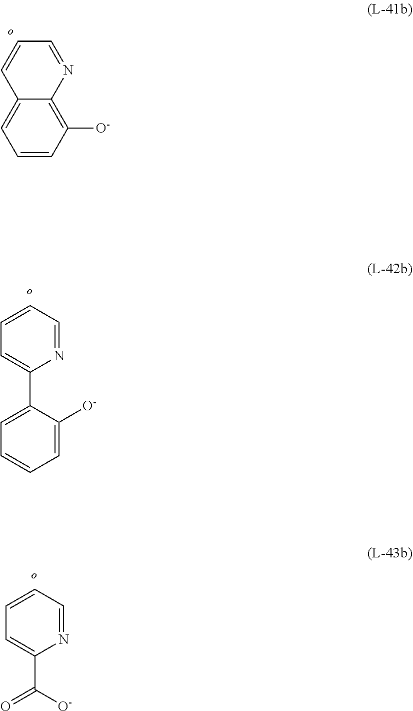 [SMILES: [O-]c1cccc2cccnc12 ; [O-]c1ccccc1-c1ccccn1 ; O=C([O-])c1ccccn1]

where the symbols used have the definitions given above.

Further preferred bidentate ligands are the structures of the following formula (L-46):

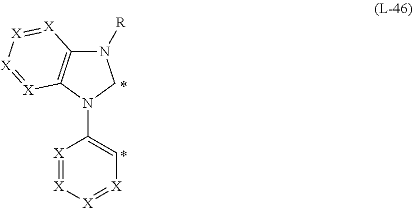

where X and R have the definitions given above, * represents the position of coordination to the metal, where the ligands may optionally be bonded by a bridge. In this case, the R group bonded to N is preferably not H, but is an alkyl, heteroalkyl, aryl or heteroaryl group as detailed above for R. Preferably, not more than two X per ring are N; more preferably, all X are CR, where the ligands may be bonded via an R radical.

Preferred ligands of the formula (L-46) are therefore the ligands of the following formulae (L-46a):

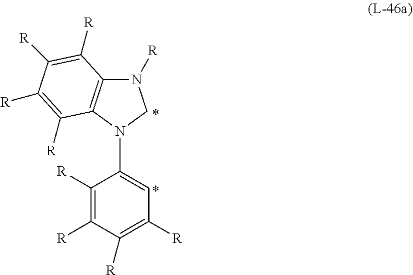

where the symbols used have the definitions given above.

In a preferred embodiment, the metal complexes conform to the general formula

M(L)ₙ(L′)ₘ Formula (1a)

where the symbol M and the ligands L and/or L′ have the definitions given in claim 1 and at least some of the ligands are joined via a bridge, so as to form a tridentate, tetradentate, pentadentate or hexadentate ligand system, and preferably to form a metal complex containing iridium and a hexadentate tripodal ligand, with the proviso that the metal complex contains at least one substructure of the formula (2)

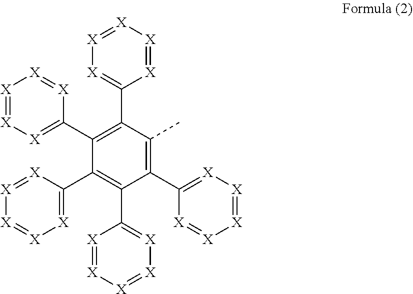

where the symbols have the definitions given above, especially for formula (1) and (2), where the preferences mentioned above are applicable thereto as well. In this case, the ligands L and L′ may be regarded as three bidentate sub-ligands that coordinate to a metal. Preferably, the bridge may be an aryl or heteroaryl group which has 5 to 36 aromatic ring atoms and may be substituted by one or more R radicals.

In the case of Pt, in a structure of formula (1a), preferably a tetradentate ligand system is formed.

There follows a description of preferred iridium and platinum complexes. As described above, these are organometallic complexes. An organometallic complex in the context of the present invention is a complex having at least one metal-carbon bond to the ligand.

In a preferred embodiment of the invention, the iridium or platinum complex is uncharged, i.e. electrically neutral. Therefore, the iridium complex preferably contains either three bidentate monoanionic ligands or one tripodal hexadentate trianionic ligand, and the platinum complex contains either two bidentate monoanionic ligands or one tetradentate dianionic ligand.

The bond of the ligand to the iridium or the platinum may either be a coordinate bond or a covalent bond, or the covalent fraction of the bond may vary according to the ligand. When it is said in the present application that the ligand or ligand coordinates or binds to iridium or the platinum, this refers in the context of the present application to any kind of bond of the ligand to the iridium or the platinum, irrespective of the covalent component of the bond.

In a further preferred embodiment of the invention, M is platinum, and so an organometallic platinum complex comprises a substructure of the formula (2). When M is platinum, this complex preferably comprises two bidentate ligands that may be joined to one another. In this case, these ligands are the same or different and are preferably selected from the above-depicted ligands of the formulae (L-1), (L-2) and (L-3), where the abovementioned preferences are applicable thereto as well.

When M is platinum and the platinum complex comprises a tetradentate ligand, this can be shown schematically by the following formula (Lig′):

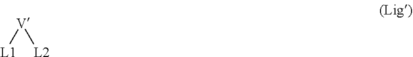

where V′ is selected from CR₂, NR, O, S and BR, preferably CR₂ and NR, where R has the definitions given above, and L1 and L2 are the same or different at each instance and are each bidentate ligands, preferably monoanionic bidentate ligands. Since the ligand has two bidentate ligands, the overall result is a tetradentate ligand, i.e. a ligand which coordinates or binds to the platinum via four coordination sites.

The platinum complex formed with this ligand of the formula (Lig′) can thus be represented schematically by the following formula:

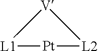

where the symbols used have the definitions given above.

In a preferred embodiment of the invention, M is iridium. It may be the case here that the metal is Ir(III) and the metal complex has three bidentate ligands, where two of the bidentate ligands coordinate to the iridium via one carbon atom and one nitrogen atom in each case or via two carbon atoms, and the third of the bidentate ligands coordinates to the iridium via one carbon atom and one nitrogen atom or via two carbon atoms or via two nitrogen atoms, where preferably the third of the bidentate ligands coordinates to the iridium via one carbon atom and one nitrogen atom or via two carbon atoms.

Particular preference is given to an iridium complex having a tripodal hexadentate ligand as described hereinafter. This tripodal hexadentate ligand contains three bidentate sub-ligands which may be the same or different and coordinate to an iridium atom, where the three bidentate sub-ligands are joined via a bridge of the following formula (3) or formula (4):

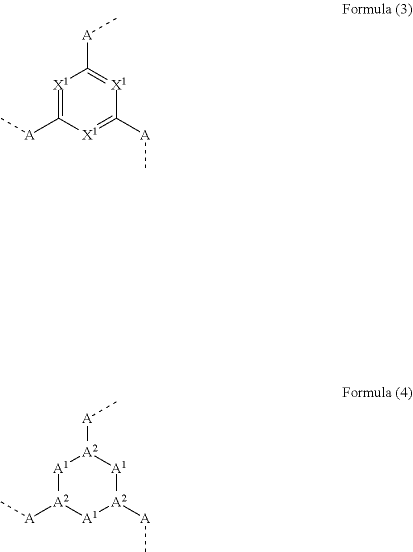

where the dotted bond constitutes the bond of the bidentate ligands to this structure, R, R¹ and R² have the definitions given above and in addition:
X¹ is the same or different at each instance and is CR or N;
A¹ is the same or different at each instance and is C(R)₂ or O;
A² is the same or different at each instance and is CR, P(═O), B or SiR, with the proviso that, when A²=P(═O), B or SiR, the symbol A¹ is O and the symbol A bonded to this A² is not —C(═O)—NR′— or —C(═O)—O—;
A is the same or different at each instance and is —CR═CR—, —C(═O)—NR′—, —C(═O)—O— or a group of the following formula (5):

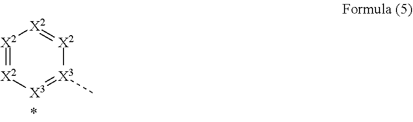

where the dotted bond represents the position of the bond of the bidentate ligands to this structure and * represents the position of the linkage of the unit of the formula (5) to the central cyclic group;
X² is the same or different at each instance and is CR or N or two adjacent X² groups together are NR, O or S, thus forming a five-membered ring, and the remaining X² are the same or different at each instance and are CR or N; or two adjacent X² groups together are CR or N when one of the X³ groups in the cycle is N, thus forming a five-membered ring; with the proviso that not more than two adjacent X² groups are N;
X³ is C at each instance or one X³ group is N and the other X³ group in the same cycle is C; with the proviso that two adjacent X² groups together are CR or N when one of the X³ groups in the cycle is N;
R′ is the same or different at each instance and is H, D, a straight-chain alkyl group having 1 to 20 carbon atoms or a branched or cyclic alkyl group having 3 to 20 carbon atoms, where the alkyl group in each case may be substituted by one or more R¹ radicals and where one or more nonadjacent CH₂ groups may be replaced by Si(R¹)₂, or an aromatic or heteroaromatic ring system which has 5 to 40 aromatic ring atoms and may be substituted in each case by one or more R¹ radicals;

at the same time, the three bidentate sub-ligands, apart from by the bridge of the formula (3) or (4), may also be closed by a further bridge to form a cryptate.

When two R or R¹ or R² radicals together form a ring system, it may be mono- or polycyclic, and aliphatic, heteroaliphatic, aromatic or heteroaromatic. In this case, the radicals which together form a ring system may be adjacent, meaning that these radicals are bonded to the same carbon atom or to carbon atoms directly bonded to one another, or they may be further removed from one another.

The structure of the hexadentate tripodal ligands can be shown in schematic form by the following formula (Lig):

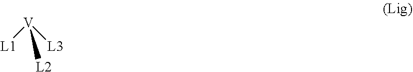

where V represents the bridge of formula (3) or (4) and L1, L2 and L3 are the same or different at each instance and are each bidentate sub-ligands, preferably monoanionic bidentate sub-ligands. “Bidentate” means that the particular ligand in the complex M coordinates or binds to the iridium via two coordination sites. “Tripodal” means that the ligand has three sub-ligands bonded to the bridge V or the bridge of the formula (3) or (4). Since the ligand has three bidentate sub-ligands, the overall result is a hexadentate ligand, i.e. a ligand which coordinates or binds to the iridium via six coordination sites. The expression “bidentate sub-ligand” in the context of this application means that this unit would be a bidentate ligand if the bridge of the formula (3) or (4) were not present. However, as a result of the formal abstraction of a hydrogen atom in this bidentate ligand and the attachment to the bridge of the formula (3) or (4), it is not a separate ligand but a portion of the hexadentate ligand which thus arises, and so the term “sub-ligand” is used therefor.

The iridium complex formed with this ligand of the formula (Lig) can thus be represented schematically by the following formula:

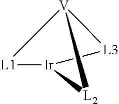

where V represents the bridge of formula (3) or (4) and L1, L2 and L3 are the same or different at each instance and are each bidentate sub-ligands.

Preferred embodiments of the bridge of the formula (3) or (4) are detailed hereinafter. Suitable embodiments of the group of the formula (3) are the structures of the following formulae (6) to (9), and suitable embodiments of the group of the formula (4) are the structures of the following formulae (10) to (14):

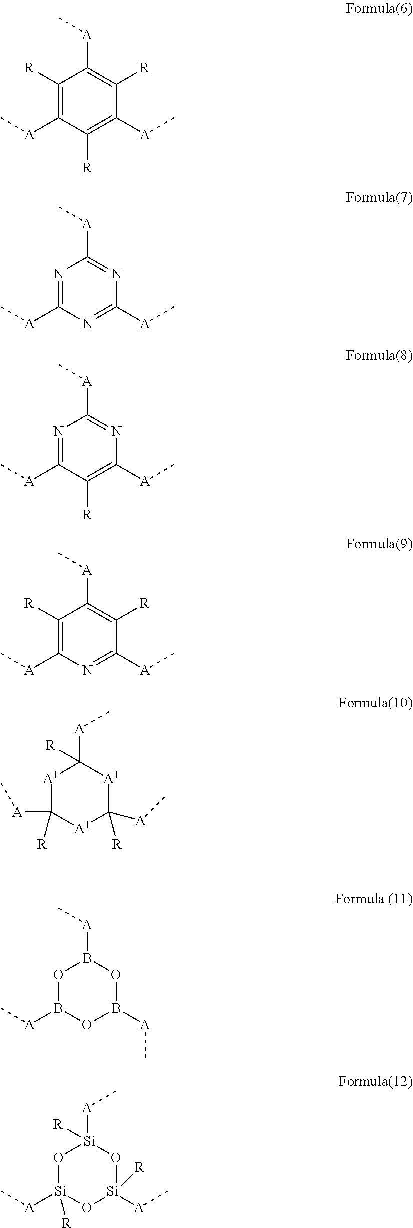

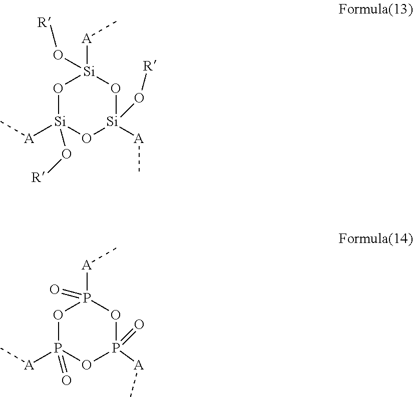

where the symbols have the definitions given above.

The following is applicable in respect of preferred R radicals on the trivalent central benzene ring of the formula (6), on the pyrimidine ring of the formula (8), on the pyridine ring of the formula (9) and on the central (hetero)aliphatic ring of the formulae (10) to (14):
R is the same or different at each instance and is H, D, F, CN, a straight-chain alkyl or alkoxy group having 1 to 10 carbon atoms or an alkenyl group having 2 to 10 carbon atoms or a branched or cyclic alkyl or alkoxy group having 3 to 10 carbon atoms, each of which may be substituted by one or more R¹ radicals, or an aromatic or heteroaromatic ring system which has 5 to 24 aromatic ring atoms and may be substituted in each case by one or more R¹ radicals;
R¹ is the same or different at each instance and is H, D, F, CN, a straight-chain alkyl or alkoxy group having 1 to 10 carbon atoms or an alkenyl group having 2 to 10 carbon atoms or a branched or cyclic alkyl or alkoxy group having 3 to 10 carbon atoms, each of which may be substituted by one or more R² radicals, or an aromatic or heteroaromatic ring system which has 5 to 24 aromatic ring atoms and may be substituted in each case by one or more R² radicals; at the same time, two or more adjacent R¹ radicals together may form a ring system;
R² is the same or different at each instance and is H, D, F or an aliphatic, aromatic and/or heteroaromatic organic radical having 1 to 20 carbon atoms, in which one or more hydrogen atoms may also be replaced by F.

The following is applicable in respect of particularly preferred R radicals on the trivalent central benzene ring of the formula (6), on the pyrimidine ring of the formula (8), on the pyridine ring of the formula (9) and on the central (hetero)aliphatic ring of the formulae (10) to (14):
R is the same or different at each instance and is H, D, F, CN, a straight-chain alkyl group having 1 to 4 carbon atoms or a branched or cyclic alkyl group having 3 to 6 carbon atoms, each of which may be substituted by one or more R¹ radicals, or an aromatic or heteroaromatic ring system which has 6 to 12 aromatic ring atoms and may be substituted in each case by one or more R¹ radicals;
R¹ is the same or different at each instance and is H, D, F, CN, a straight-chain alkyl group having 1 to 4 carbon atoms or a branched or cyclic alkyl group having 3 to 6 carbon atoms, each of which may be substituted by one or more R² radicals, or an aromatic or heteroaromatic ring system which has 6 to 12 aromatic ring atoms and may be substituted in each case by one or more R² radicals; at the same time, two or more adjacent R¹ radicals together may form a ring system;
R² is the same or different at each instance and is H, D, F or an aliphatic or aromatic hydrocarbyl radical having 1 to 12 carbon atoms.

In a preferred embodiment of the invention, all X¹ groups in the group of the formula (3) are CR, and so the central trivalent cycle of the formula (3) is a benzene. More preferably, all X¹ groups are CH. In a further preferred embodiment of the invention, all X¹ groups are a nitrogen atom, and so the central trivalent cycle of the formula (3) is a triazine. Preferred embodiments of the formula (3) are thus the structures of the formulae (6) and (7). More preferably, the structure of the formula (6) is a structure of the following formula (6′):

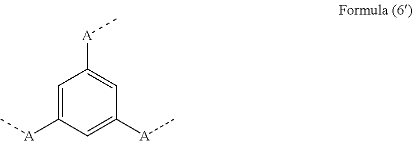

where the symbols have the definitions given above.

In a further preferred embodiment of the invention, all A² groups in the group of the formula (4) are CR. More preferably, all A² groups are CH. Preferred embodiments of the formula (4) are thus the structures of the formula (10). More preferably, the structure of the formula (10) is a structure of the following formula (10′) or (10″):

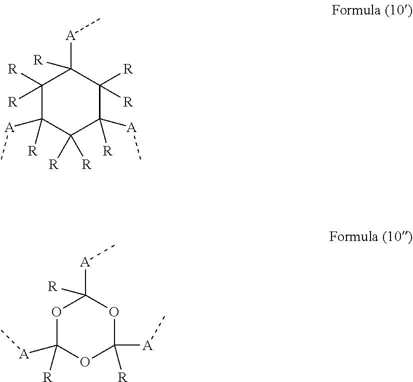

where the symbols have the definitions given above and R is preferably H.

Preferred embodiments of the group of the formula (5) are described hereinafter. The group of the formula (5) may represent a heteroaromatic five-membered ring or an aromatic or heteroaromatic six-membered ring. In a preferred embodiment of the invention, the group of the formula (5) contains not more than two heteroatoms in the aromatic or heteroaromatic unit, more preferably not more than one heteroatom. This does not mean that any substituents bonded to this group cannot also contain heteroatoms. In addition, this definition does not mean that formation of rings by substituents cannot give rise to fused aromatic or heteroaromatic structures, for example naphthalene, benzimidazole, etc.

When both X³ groups in formula (5) are carbon atoms, preferred embodiments of the group of the formula (5) are the structures of the following formulae (15) to (31), and, when one X³ group is a carbon atom and the other X³ group in the same cycle is a nitrogen atom, preferred embodiments of the group of the formula (5) are the structures of the following formulae (32) to (39):

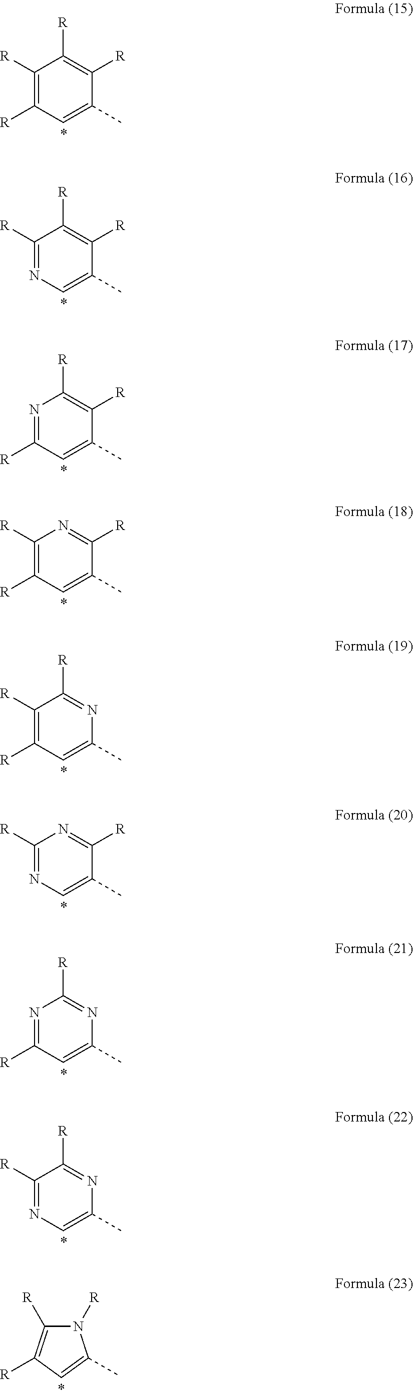

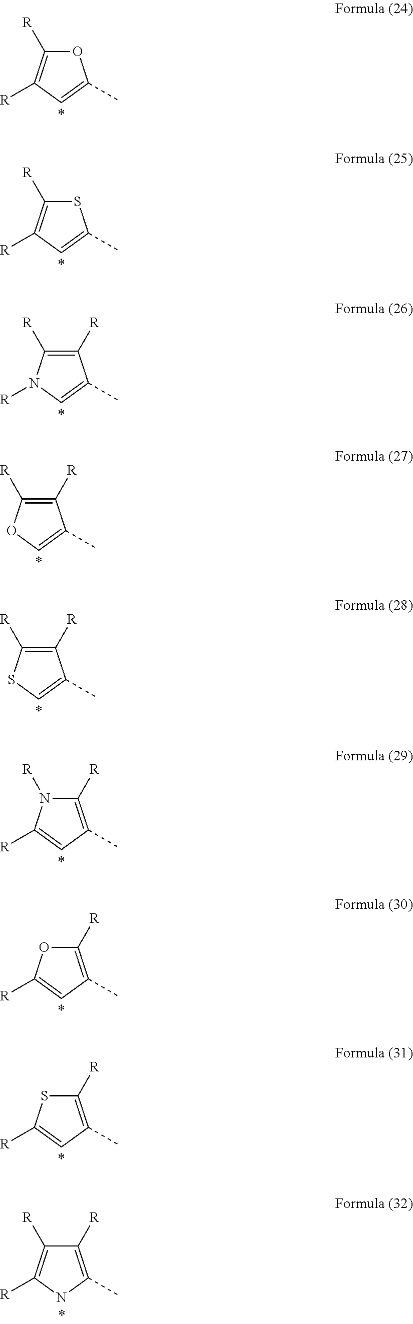

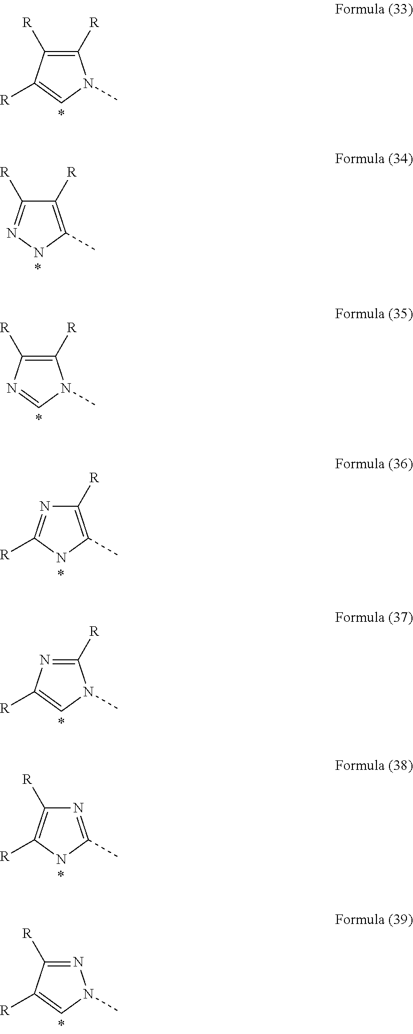

where the symbols have the definitions given above.

Particular preference is given to the six-membered aromatic rings and heteroaromatic rings of the formulae (15) to (19) depicted above. Very particular preference is given to ortho-phenylene, i.e. a group of the abovementioned formula (15).

At the same time, it is also possible for adjacent R substituents together to form a ring system, such that it is possible to form fused structures, including fused aryl and heteroaryl groups, for example naphthalene, quinoline, benzimidazole, carbazole, dibenzofuran or dibenzothiophene. Such ring formation is shown schematically below in groups of the abovementioned formula (15), which leads to groups of the following formulae (15a) to (15j):

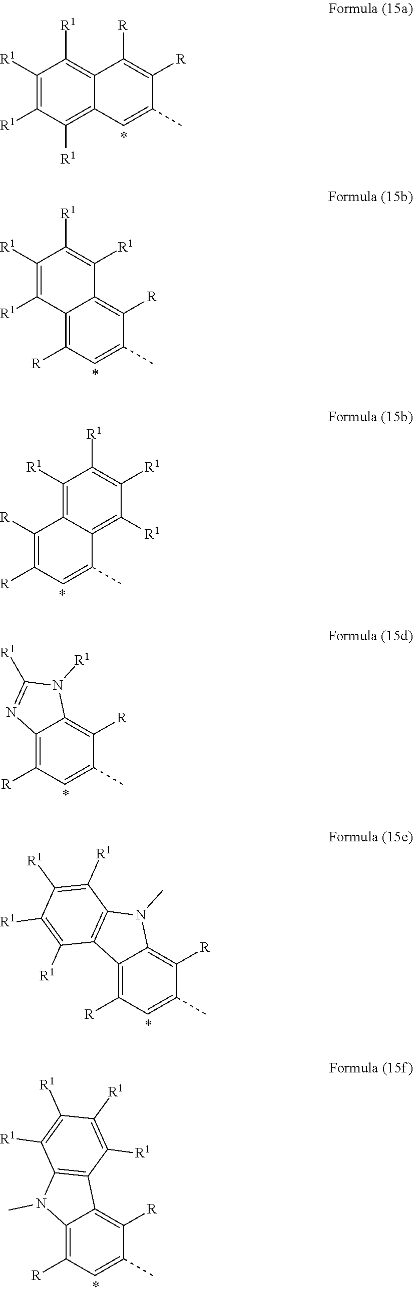

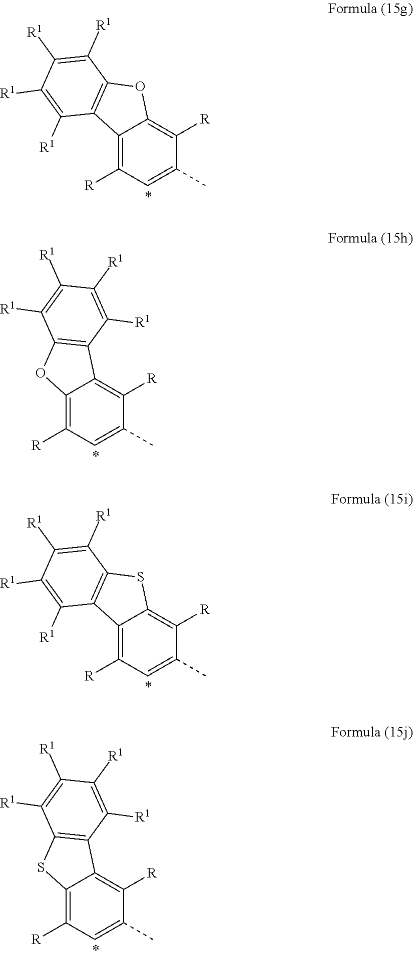

where the symbols have the definitions given above.

In general, the groups fused on may be fused onto any position in the unit of formula (5), as shown by the fused-on benzo group in the formulae (15a) to (15c). The groups as fused onto the unit of the formula (5) in the formulae (15d) to (15j) may therefore also be fused onto other positions in the unit of the formula (5).

The group of the formula (3) can more preferably be represented by the following formulae (3a) to (3m), and the group of the formula (4) can more preferably be represented by the following formulae (4a) to (4m):

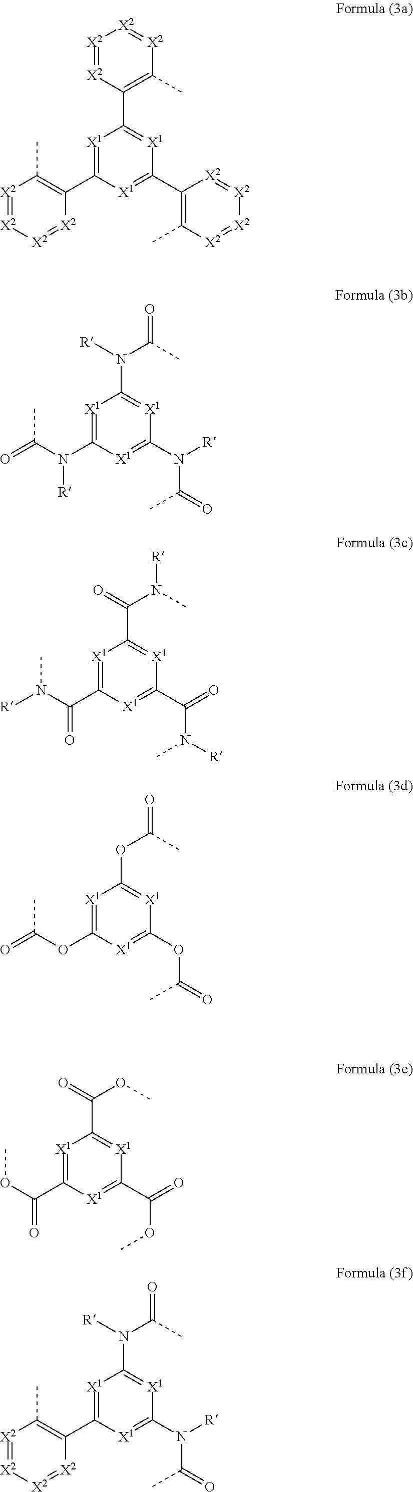

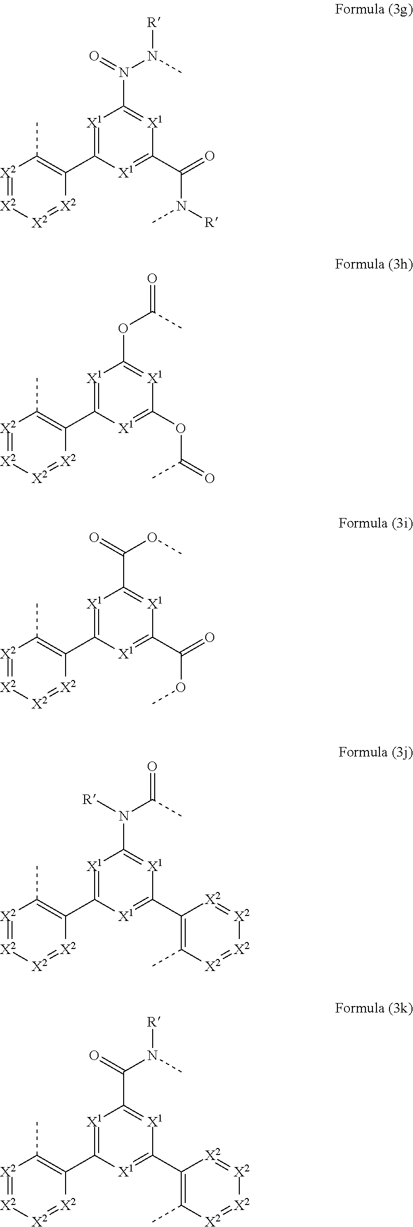

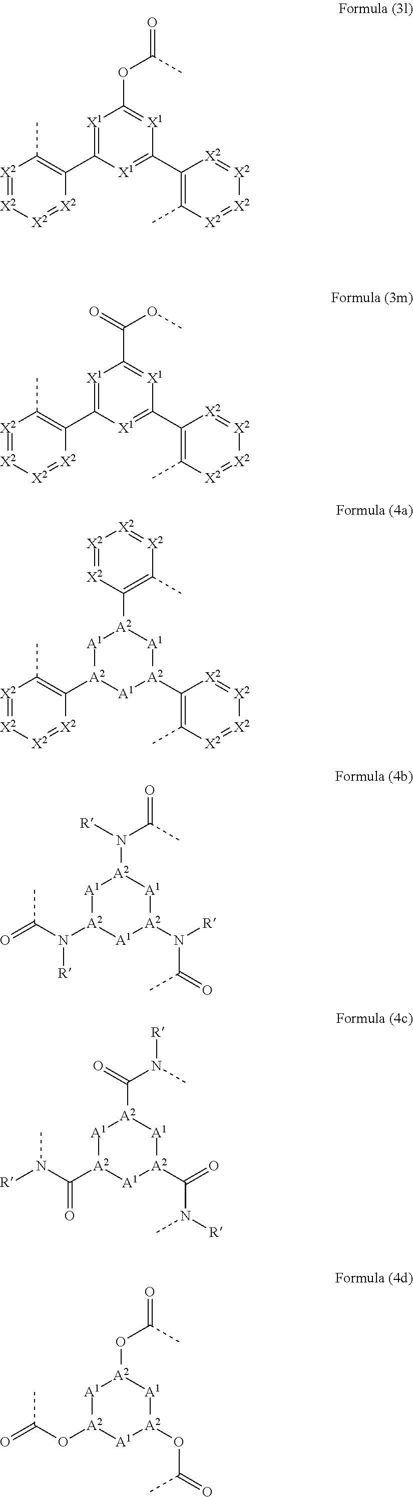

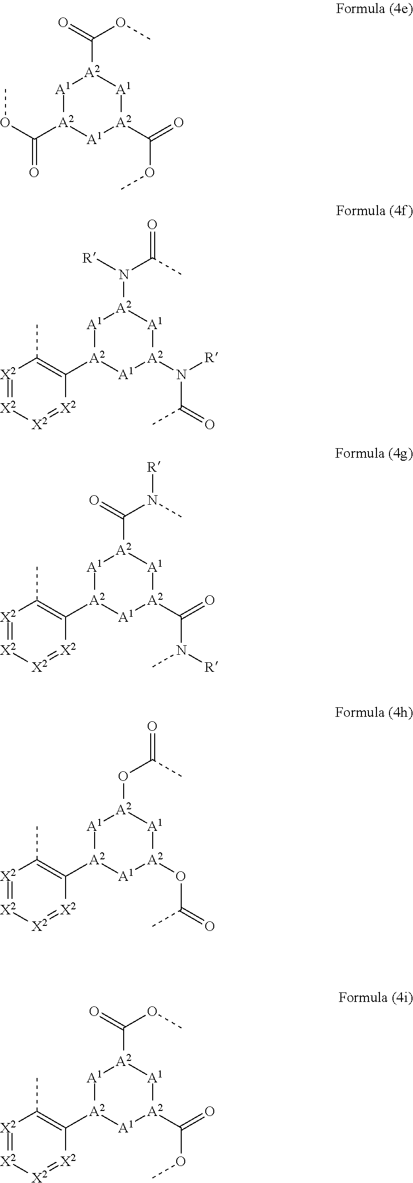

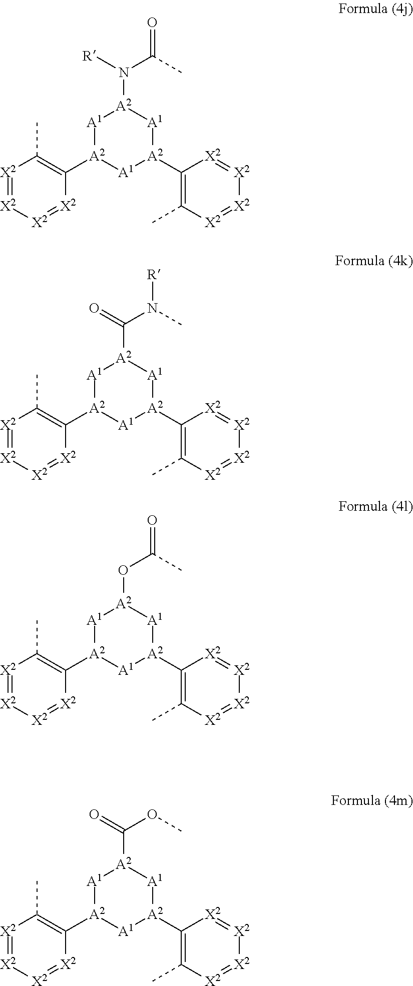

where the symbols have the definitions given above. Preferably, X² is the same or different at each instance and is CR.

In a preferred embodiment of the invention, the group of the formulae (3a) to (3m) is selected from the groups of the formulae (6a′) to (6m′), and the group of the formulae (4a) to (4m) from the groups of the formulae (10a′) to (10m′):

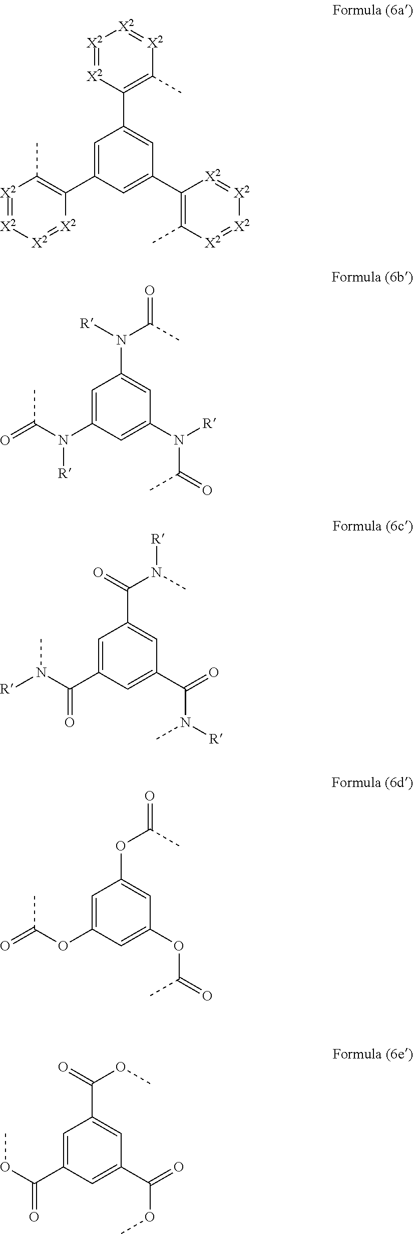

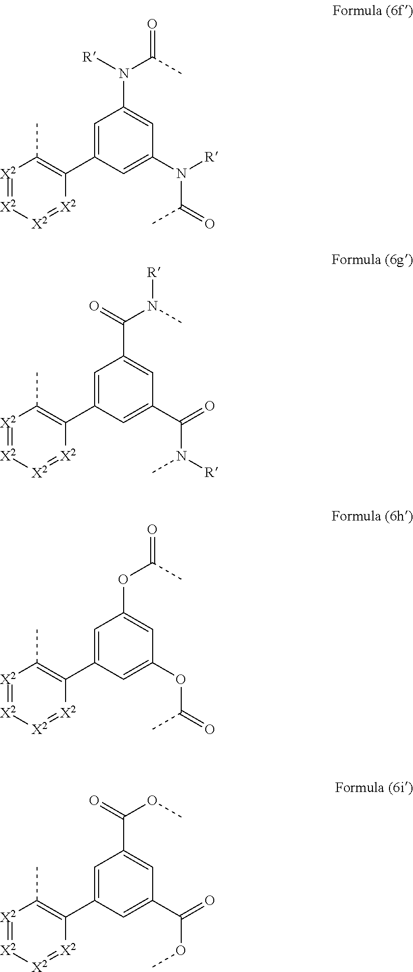

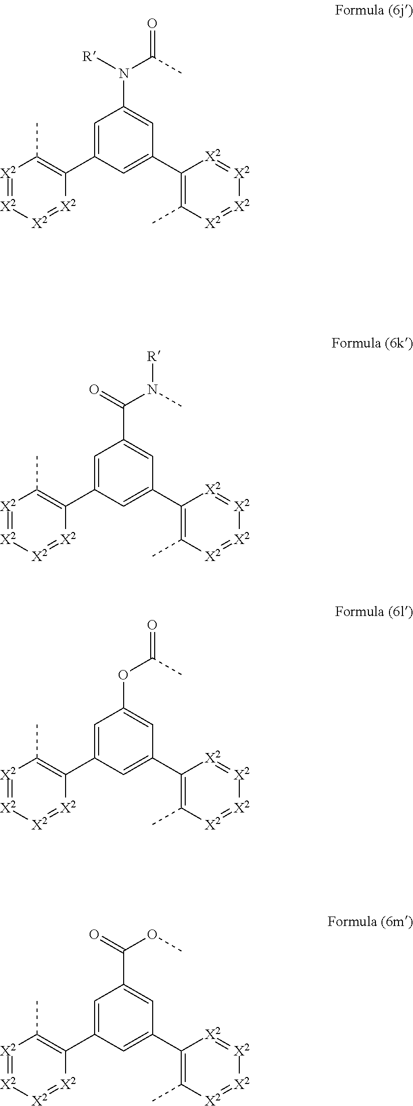

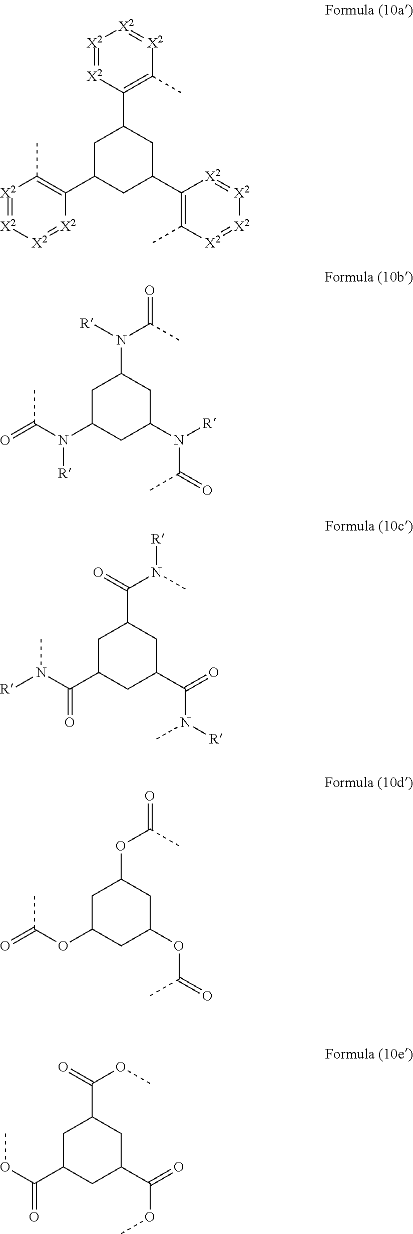

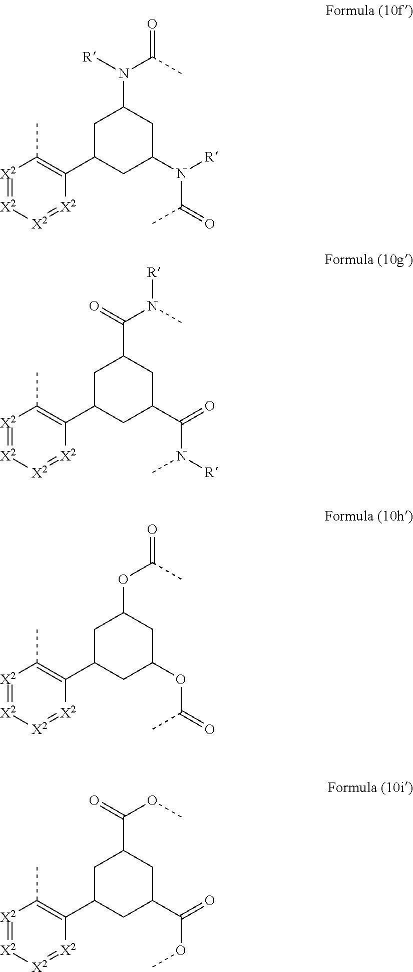

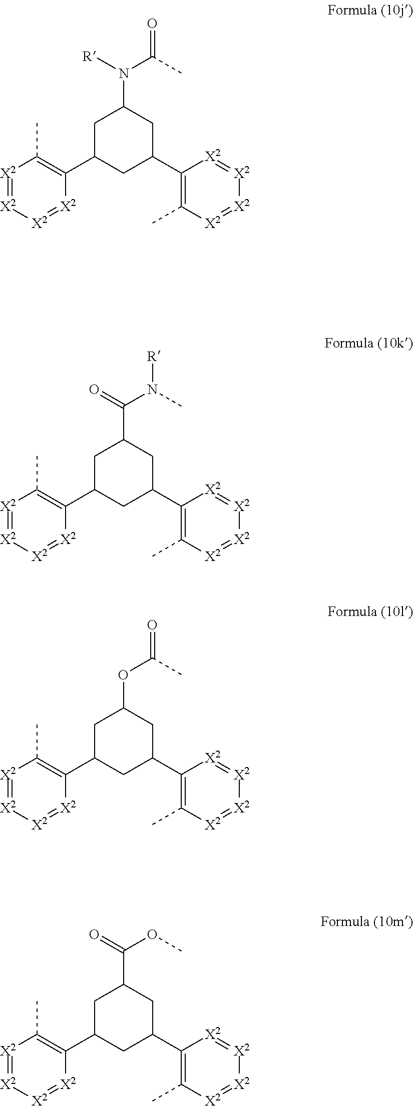

where the symbols have the definitions given above. Preferably, X² is the same or different at each instance and is CR.

A particularly preferred embodiment of the group of the formula (3) is the group of the following formula (6a″):

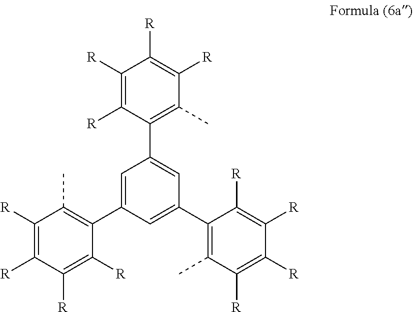

where the symbols have the definitions given above.

More preferably, the R groups in the abovementioned formulae are the same or different and are H, D or an alkyl group having 1 to 4 carbon atoms. Most preferably, R═H. Very particular preference is thus given to the structure of the following formula (6a′″):

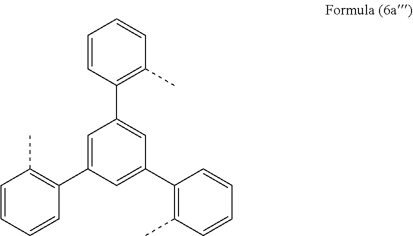

where the symbols have the definitions given above.

There follows a description of preferred substituents as may be present on the above-described sub-ligands and ligands, but also on the bivalent arylene or heteroarylene group in the structure of the formula (5).

In a preferred embodiment of the invention, the metal complex of the invention contains two R substituents or two R¹ substituents which are bonded to adjacent carbon atoms and together form an aliphatic ring according to one of the formulae described hereinafter. In this case, the two R substituents which form this aliphatic ring may be present on the bridge of the formulae (3) or (4) or the preferred embodiments and/or on one or more of the bidentate ligands. The aliphatic ring which is formed by the ring formation by two R substituents together or by two R¹ substituents together is preferably described by one of the following formulae (40) to (46):

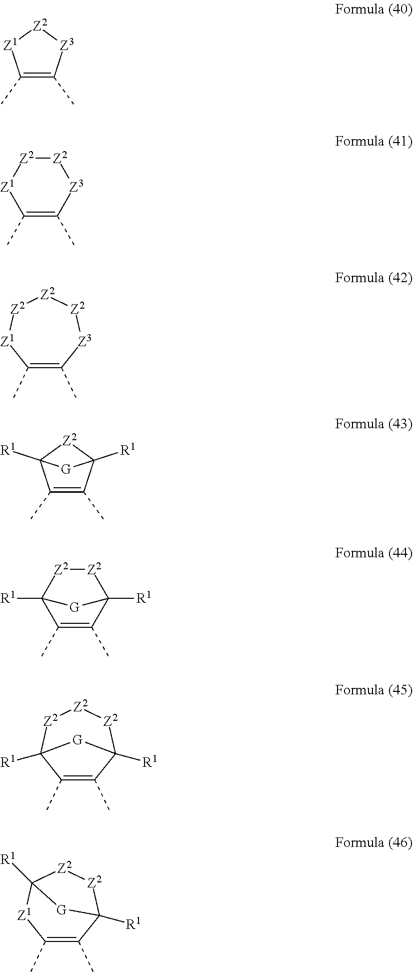

where R¹ and R² have the definitions given above, the dotted bonds signify the linkage of the two carbon atoms in the ligand and, in addition:
Z¹, Z³ is the same or different at each instance and is C(R³)₂, O, S, NR³ or C(═O);
Z² is C(R¹)₂, O, S, NR³ or C(═O);
G is an alkylene group which has 1, 2 or 3 carbon atoms and may be substituted by one or more R² radicals, —CR²═CR²— or an ortho-bonded arylene or heteroarylene group which has 5 to 14 aromatic ring atoms and may be substituted by one or more R² radicals;
R³ is the same or different at each instance and is H, F, a straight-chain alkyl or alkoxy group having 1 to 10 carbon atoms, a branched or cyclic alkyl or alkoxy group having 3 to 10 carbon atoms, where the alkyl or alkoxy group may be substituted in each case by one or more R² radicals, where one or more nonadjacent CH₂ groups may be replaced by R²C═CR², C≡C, Si(R²)₂, C═O, NR², O, S or CONR², or an aromatic or heteroaromatic ring system which has 5 to 24 aromatic ring atoms and may be substituted in each case by one or more R² radicals, or an aryloxy or heteroaryloxy group which has 5 to 24 aromatic ring atoms and may be substituted by one or more R² radicals; at the same time, two R³ radicals bonded to the same carbon atom together may form an aliphatic or aromatic ring system and thus form a spiro system; in addition, R³ with an adjacent R or R¹ radical may form an aliphatic ring system;

with the proviso that no two heteroatoms in these groups are bonded directly to one another and no two C═O groups are bonded directly to one another.

In a preferred embodiment of the invention, R³ is not H.

In the above-depicted structures of the formulae (40) to (46) and the further embodiments of these structures specified as preferred, a double bond is depicted in a formal sense between the two carbon atoms. This is a simplification of the chemical structure when these two carbon atoms are incorporated into an aromatic or heteroaromatic system and hence the bond between these two carbon atoms is formally between the bonding level of a single bond and that of a double bond. The drawing of the formal double bond should thus not be interpreted so as to limit the structure; instead, it will be apparent to the person skilled in the art that this is an aromatic bond.

When adjacent radicals in the structures of the invention form an aliphatic ring system, it is preferable when the latter does not have any acidic benzylic protons. Benzylic protons are understood to mean protons which bind to a carbon atom bonded directly to the ligand. This can be achieved by virtue of the carbon atoms in the aliphatic ring system which bind directly to an aryl or heteroaryl group being fully substituted and not containing any bonded hydrogen atoms. Thus, the absence of acidic benzylic protons in the formulae (40) to (42) is achieved by virtue of Z¹ and Z³, when they are C(R³)₂, being defined such that R³ is not hydrogen. This can additionally also be achieved by virtue of the carbon atoms in the aliphatic ring system which bind directly to an aryl or heteroaryl group being the bridgeheads in a bi- or polycyclic structure. The protons bonded to bridgehead carbon atoms, because of the spatial structure of the bi- or polycycle, are significantly less acidic than benzylic protons on carbon atoms which are not bonded within a bi- or polycyclic structure, and are regarded as non-acidic protons in the context of the present invention. Thus, the absence of acidic benzylic protons in formulae (43) to (46) is achieved by virtue of this being a bicyclic structure, as a result of which R¹, when it is H, is much less acidic than benzylic protons since the corresponding anion of the bicyclic structure is not mesomerically stabilized. Even when R¹ in formulae (43) to (46) is H, this is therefore a non-acidic proton in the context of the present application.

In a preferred embodiment of the structure of the formulae (40) to (46), not more than one of the Z¹, Z² and Z³ groups is a heteroatom, especially O or NR³, and the other groups are C(R³)₂ or C(R¹)₂, or Z¹ and Z³ are the same or different at each instance and are O or NR³ and Z² is C(R¹)₂. In a particularly preferred embodiment of the invention, Z¹ and Z³ are the same or different at each instance and are C(R³)₂, and Z² is C(R¹)₂ and more preferably C(R³)₂ or CH₂.

Preferred embodiments of the formula (40) are thus the structures of the formulae (40-A), (40-B), (40-C) and (40-D), and a particularly preferred embodiment of the formula (40-A) is the structures of the formulae (40-E) and (40-F):

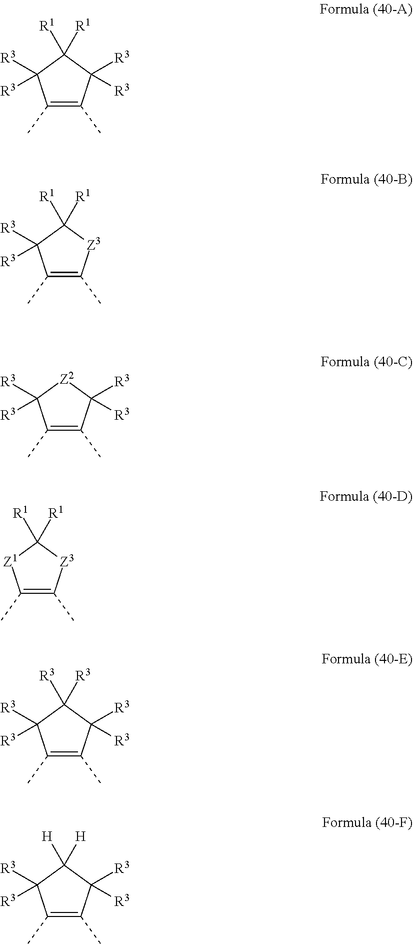

where R¹ and R³ have the definitions given above and Z¹, Z² and Z³ are the same or different at each instance and are O or NR³.

Preferred embodiments of the formula (41) are the structures of the following formulae (41-A) to (41-F):

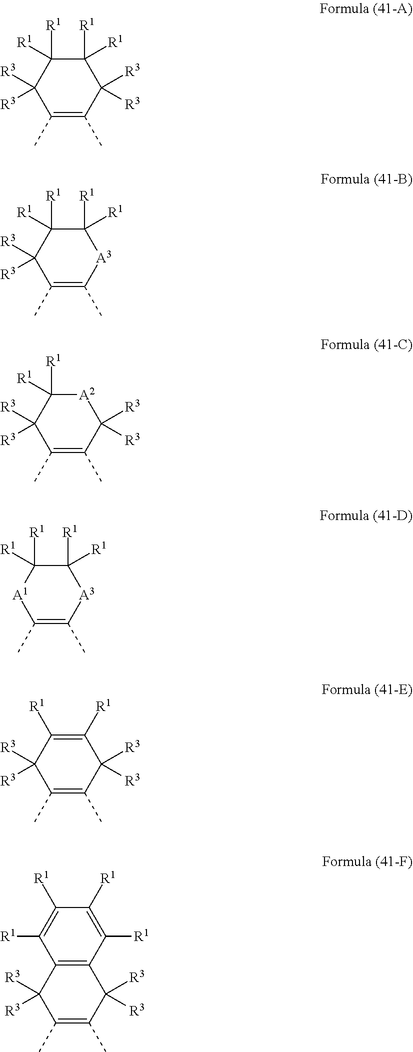

where R¹ and R³ have the definitions given above and Z¹, Z² and Z³ are the same or different at each instance and are O or NR³.

Preferred embodiments of the formula (42) are the structures of the following formulae (42-A) to (42-E):

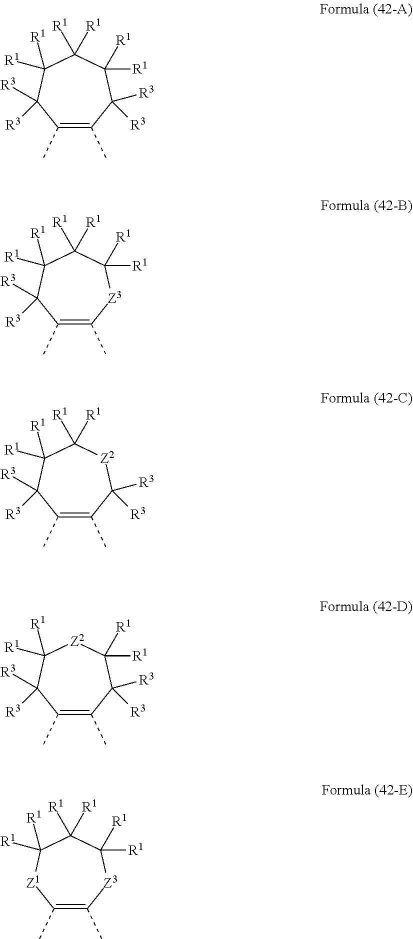

where R¹ and R³ have the definitions given above and Z¹, Z² and Z³ are the same or different at each instance and are O or NR³.

In a preferred embodiment of the structure of formula (43), the R¹ radicals bonded to the bridgehead are H, D, F or CH₃. Further preferably, Z² is C(R¹)₂ or O, and more preferably C(R³)₂. Preferred embodiments of the formula (54) are thus structures of the formulae (43-A) and (43-B), and a particularly preferred embodiment of the formula (43-A) is a structure of the formula (43-C):

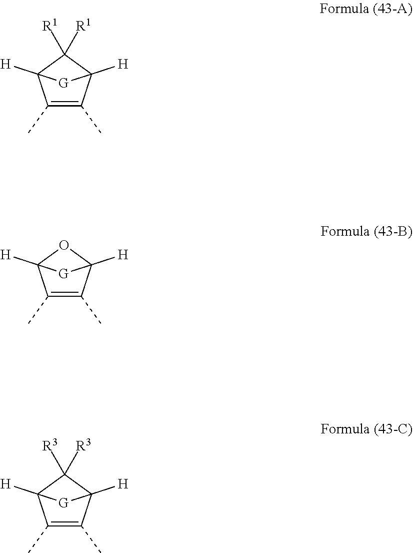

where the symbols used have the definitions given above.

In a preferred embodiment of the structure of formulae (44), (45) and (46), the R¹ radicals bonded to the bridgehead are H, D, F or CH₃. Further preferably, Z² is C(R¹)₂. Preferred embodiments of the formulae (44), (45) and (46) are thus the structures of the formulae (44-A), (45-A) and (46-A):

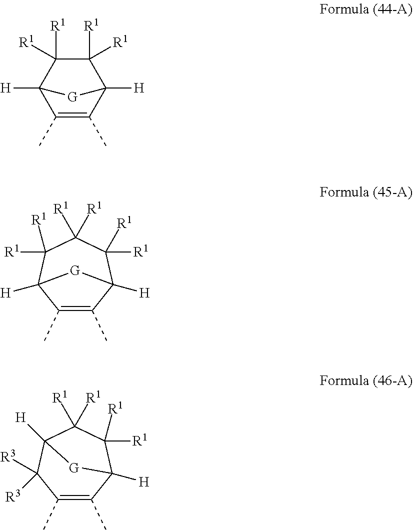

where the symbols used have the definitions given above.

Further preferably, the G group in the formulae (43), (43-A), (43-B), (43-C), (44), (44-A), (45), (45-A), (46) and (46-A) is a 1,2-ethylene group which may be substituted by one or more R² radicals, where R² is preferably the same or different at each instance and is H or an alkyl group having 1 to 4 carbon atoms, or an ortho-arylene group which has 6 to 10 carbon atoms and may be substituted by one or more R² radicals, but is preferably unsubstituted, especially an ortho-phenylene group which may be substituted by one or more R² radicals, but is preferably unsubstituted.

In a further preferred embodiment of the invention, R³ in the groups of the formulae (40) to (46) and in the preferred embodiments is the same or different at each instance and is F, a straight-chain alkyl group having 1 to 10 carbon atoms or a branched or cyclic alkyl group having 3 to 20 carbon atoms, where one or more nonadjacent CH₂ groups in each case may be replaced by R²C═CR² and one or more hydrogen atoms may be replaced by D or F, or an aromatic or heteroaromatic ring system which has 5 to 14 aromatic ring atoms and may be substituted in each case by one or more R² radicals; at the same time, two R³ radicals bonded to the same carbon atom may together form an aliphatic or aromatic ring system and thus form a spiro system; in addition, R³ may form an aliphatic ring system with an adjacent R or R¹ radical.

In a particularly preferred embodiment of the invention, R³ in the groups of the formulae (40) to (46) and in the preferred embodiments is the same or different at each instance and is F, a straight-chain alkyl group having 1 to 3 carbon atoms, especially methyl, or an aromatic or heteroaromatic ring system which has 5 to 12 aromatic ring atoms and may be substituted in each case by one or more R² radicals, but is preferably unsubstituted; at the same time, two R³ radicals bonded to the same carbon atom may together form an aliphatic or aromatic ring system and thus form a spiro system; in addition, R³ may form an aliphatic ring system with an adjacent R or R¹ radical.

Examples of particularly suitable groups of the formula (40) are the groups depicted below:

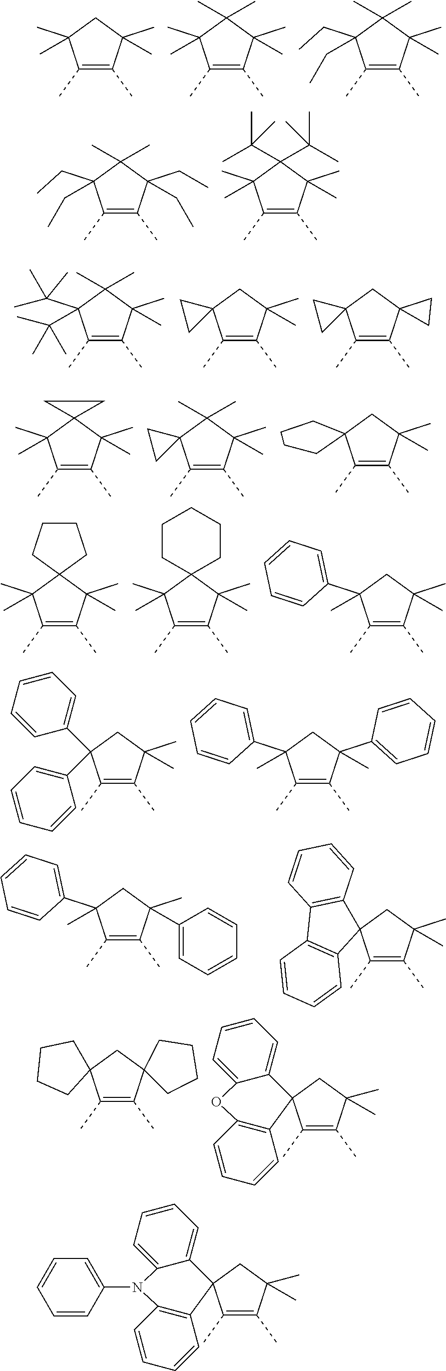

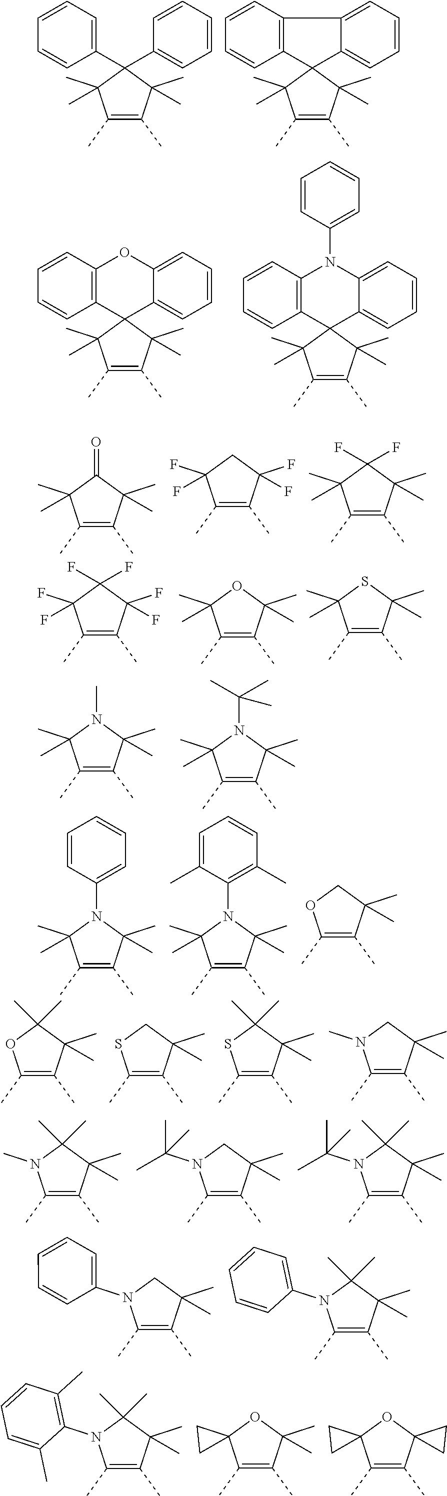

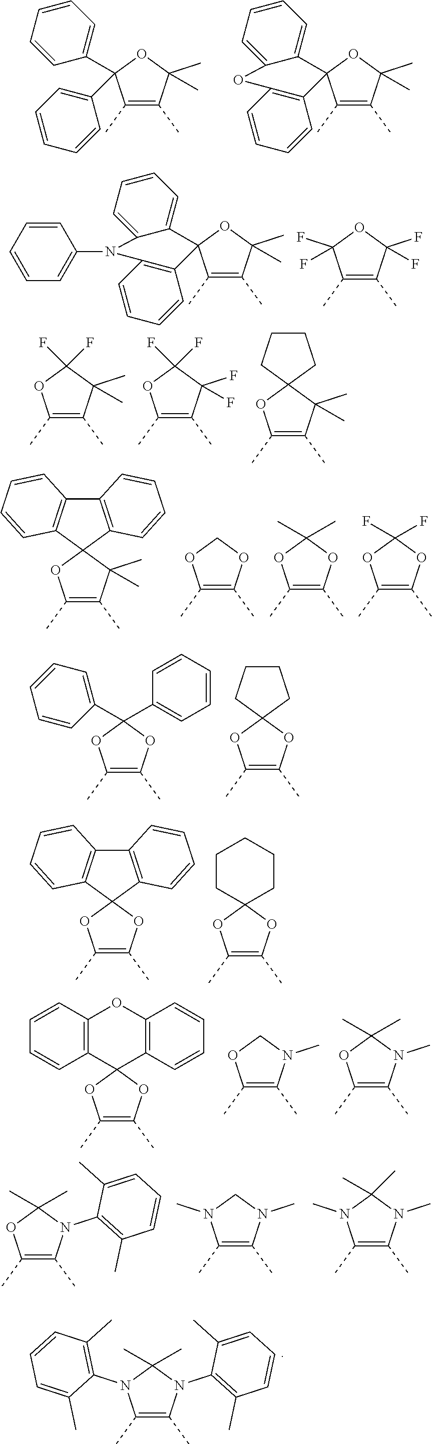

Examples of particularly suitable groups of the formula (41) are the groups depicted below:

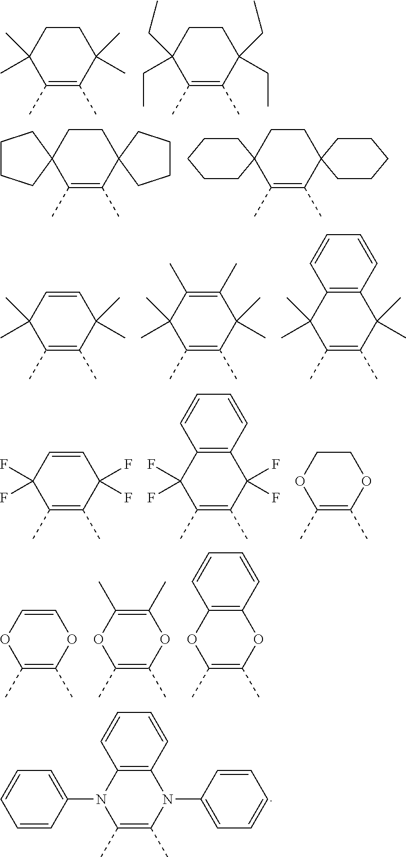

Examples of particularly suitable groups of the formulae (42), (45) and (46) are the groups depicted below:

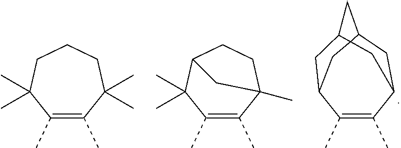

Examples of particularly suitable groups of the formula (43) are the groups depicted below:

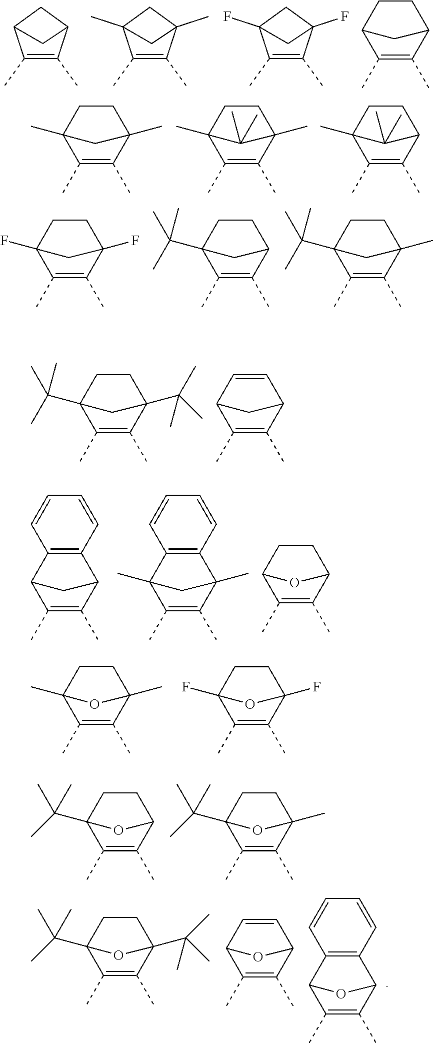

Examples of particularly suitable groups of the formula (44) are the groups depicted below:

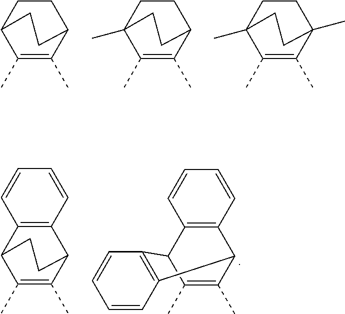

When R radicals are bonded within the substructures of the formulae (2), (2-1), (2-1a) to (2-1i), (2-2), (2-2a) to (2-2c), (2-3), (2-4), (2-5) and/or (2-6) or within the aryl or heteroaryl radicals of the formula (Ar-1) or within the bidentate sub-ligands or ligands or within the bivalent arylene or heteroarylene groups of the formula (5) bonded within the formulae (3) or (4) or the preferred embodiments, these R radicals are the same or different at each instance and are preferably selected from the group consisting of H, D, F, Br, I, N(R¹)₂, CN, Si(R¹)₃, B(OR¹)₂, C(═O)R¹, a straight-chain alkyl group having 1 to 10 carbon atoms or an alkenyl group having 2 to 10 carbon atoms or a branched or cyclic alkyl group having 3 to 10 carbon atoms, where the alkyl or alkenyl group may be substituted in each case by one or more R¹ radicals, or an aromatic or heteroaromatic ring system which has 5 to 30 aromatic ring atoms and may be substituted in each case by one or more R¹ radicals; at the same time, two adjacent R radicals together or R together with R¹ may also form a ring system. More preferably, these R radicals are the same or different at each instance and are selected from the group consisting of H, D, F, N(R¹)₂, a straight-chain alkyl group having 1 to 6 carbon atoms or a branched or cyclic alkyl group having 3 to 10 carbon atoms, where one or more hydrogen atoms may be replaced by D or F, or an aromatic or heteroaromatic ring system which has 5 to 24 aromatic ring atoms and may be substituted in each case by one or more R¹ radicals; at the same time, two adjacent R radicals together or R together with R¹ may also form a mono- or polycyclic ring system.

Preferred R¹ radicals bonded to R are the same or different at each instance and are H, D, F, N(R²)₂, ON, a straight-chain alkyl group having 1 to 10 carbon atoms or an alkenyl group having 2 to 10 carbon atoms or a branched or cyclic alkyl group having 3 to 10 carbon atoms, where the alkyl group may be substituted in each case by one or more R² radicals, or an aromatic or heteroaromatic ring system which has 5 to 24 aromatic ring atoms and may be substituted in each case by one or more R² radicals; at the same time, two or more adjacent R¹ radicals together may form a mono- or polycyclic aliphatic ring system. Particularly preferred R¹ radicals bonded to R are the same or different at each instance and are H, F, CN, a straight-chain alkyl group having 1 to 5 carbon atoms or a branched or cyclic alkyl group having 3 to 5 carbon atoms, each of which may be substituted by one or more R² radicals, or an aromatic or heteroaromatic ring system which has 5 to 13 aromatic ring atoms and may be substituted in each case by one or more R² radicals; at the same time, two or more adjacent R¹ radicals together may form a mono- or polycyclic aliphatic ring system.

Preferred R² radicals are the same or different at each instance and are H, F or an aliphatic hydrocarbyl radical having 1 to 5 carbon atoms or an aromatic hydrocarbyl radical having 6 to 12 carbon atoms; at the same time, two or more R² substituents together may also form a mono- or polycyclic aliphatic ring system.

Preferred embodiments of the compounds of the invention may be chiral structures. According to the exact structure of the complexes and ligands, the formation of diastereomers and of several pairs of enantiomers is possible.

In that case, the complexes of the invention may include both the mixtures of the different diastereomers or the corresponding racemates and the individual isolated diastereomers or enantiomers.

If mononuclear chiral complex synthesis units are used to form polynuclear complexes of the invention, these are typically used in the form of a racemate of the Δ and Λ isomers. In the polynuclear chiral compounds of the invention, this leads to diastereomer mixtures, for example for dinuclear compounds to Δ,Δ/Λ,Λ and (meso)Δ,Λ forms. Unless stated otherwise, these are converted or used further as a diastereomer mixture. In addition, it is possible to separate these by chromatographic methods or by fractional crystallization.

If the enantiomerically pure Δ or Λ isomers of mononuclear complex synthesis units are used to form polynuclear complexes of the invention, it is possible, for example, to selectively prepare Δ,Δ or Λ,Λ or (meso)Δ,Λ forms for dinuclear complexes. The same also applies to trinuclear and higher polynuclear complexes of the invention.

The Δ or Λ isomers of mononuclear chiral complex synthesis units needed for the purpose can be obtained as follows. If C₃- or C₃ᵥ-symmetric ligands are used in the synthesis of the mononuclear complex synthesis units, what is typically obtained is a racemic mixture of the C₃-symmetric complexes, i.e. of the A enantiomer and the A enantiomer. These may be separated by standard methods (chromatography on chiral materials/columns or optical resolution by crystallization). This is shown in the scheme below using the example of a C₃-symmetric ligand that leads to tripodal metal complexes bearing three phenylpyridine sub-ligands, and is also applicable in analogous form to all other C₃- or C₃ᵥ-symmetric ligands for synthesis of tripodal complexes and also in an analogous manner to the complexes of the IrL₃ type where L is a bidentate ligand.

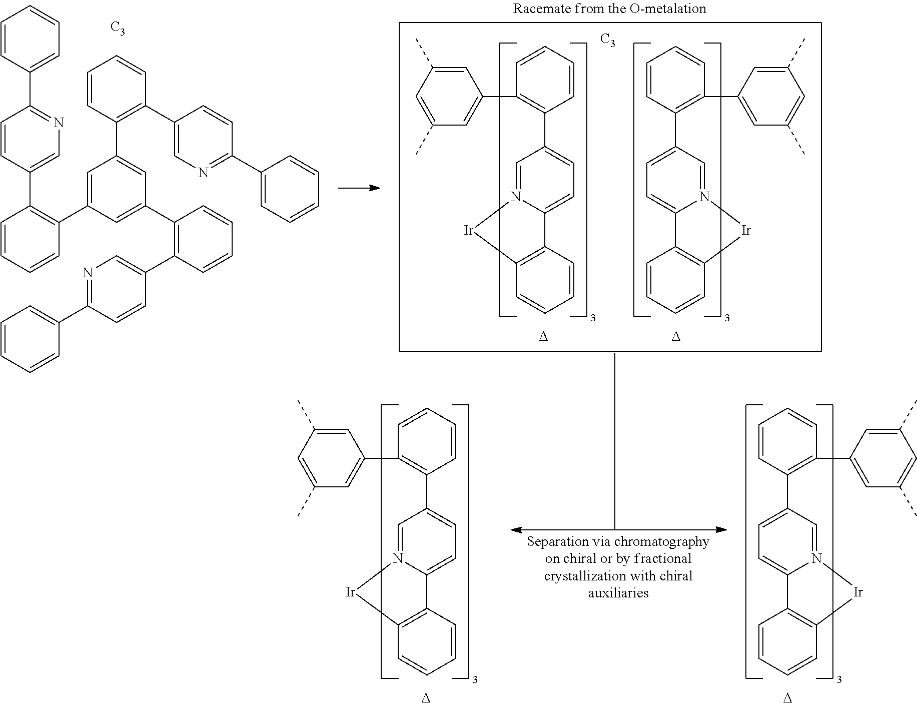

Optical resolution via fractional crystallization of diastereomeric salt pairs can be effected by customary methods. One option for this purpose is to oxidize the uncharged Ir(III) complexes (for example with peroxides or H₂O₂ or by electrochemical means), add the salt of an enantiomerically pure monoanionic base (chiral base) to the cationic Ir(IV) complexes thus produced, separate the diastereomeric salts thus produced by fractional crystallization, and then reduce them with the aid of a reducing agent (e.g. zinc, hydrazine hydrate, ascorbic acid, etc.) to give the enantiomerically pure uncharged complex, as shown schematically below:

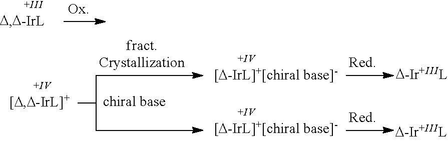

In addition, an enantiomerically pure or enantiomerically enriching synthesis is possible by complexation in a chiral medium (e.g. R- or S-1,1-binaphthol).

Analogous processes can also be conducted with complexes of Cₛ-symmetric ligands.

If C₁-symmetric ligands are used in the complexation, what is typically obtained is a diastereomer mixture of the complexes which can be separated by standard methods (chromatography, crystallization).

Enantiomerically pure C₃-symmetric complexes can also be synthesized selectively, as shown in the scheme which follows. For this purpose, an enantiomerically pure C₃-symmetric ligand is prepared and complexed, the diastereomer mixture obtained is separated and then the chiral group is detached.

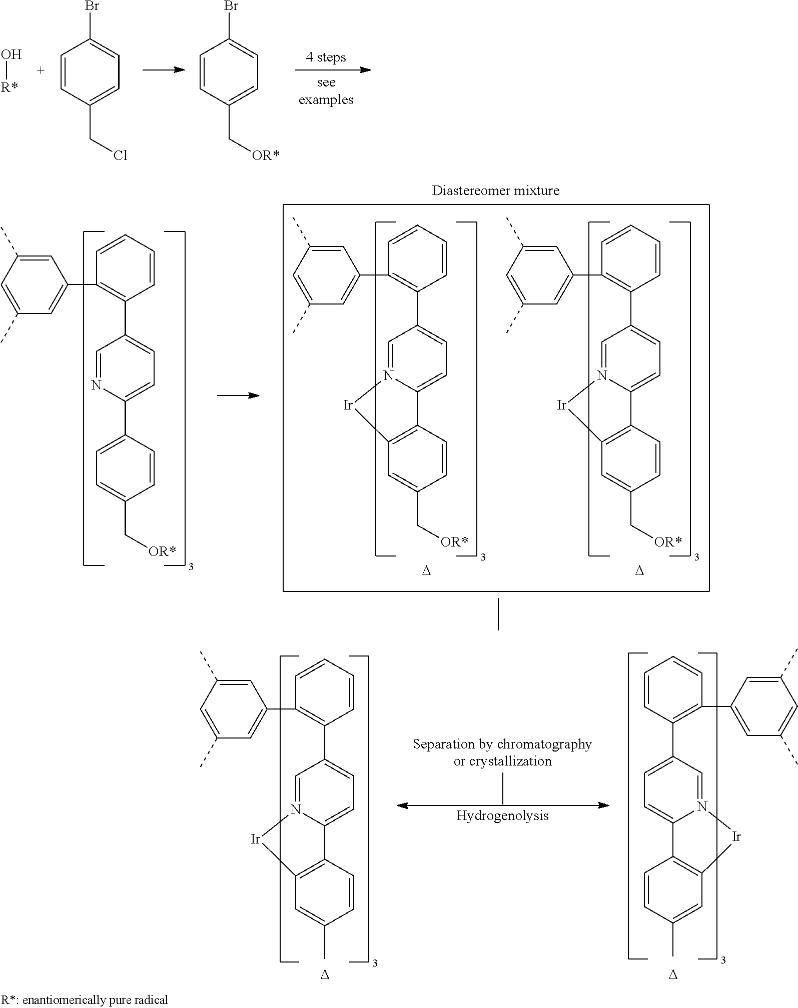

The Δ or Λ isomers of mononuclear complex synthesis units thus obtained can finally be functionalized, for example halogenated or borylated, and then joined by coupling reactions, for example Suzuki coupling, to give polynuclear complexes of the invention.

The abovementioned preferred embodiments can be combined with one another as desired. In a particularly preferred embodiment of the invention, the abovementioned preferred embodiments apply simultaneously.

The metal complexes of the invention can be prepared by various processes. However, it may be preferable to use a metal complex as reactant, which is reacted with an aromatic or heteroaromatic compound to form a substructure of formula (2).

Therefore, the present invention further provides a process for preparing the metal complexes of the invention, in which a metal complex is reacted with an aromatic or heteroaromatic compound. Preferably, a cyclopentadienone derivative can be reacted with an alkyne derivative, which can be effected in a Diels-Alder reaction. The Diels-Alder product then reacts with elimination of CO to give a complex of the invention. More particularly, the alkyne derivative to be converted in a Diels-Alder reaction may be a metal complex.

The complexes to be used can be prepared by two routes. Firstly, the ligand comprising an alkyne function, for example, is prepared and then coordinated to the metal or metal fragments. In general, for this purpose, an iridium salt or platinum salt is reacted with the corresponding free ligand.

In addition, corresponding alkyne derivatives of metal complexes can be obtained by reacting metal complexes containing corresponding reactive groups with aromatic or heteroaromatic alkyne compounds. Coupling reactions suitable for this purpose, for example Suzuki coupling, are common knowledge, and the reaction known as the Sonogashira reaction has been found to be particularly useful for this purpose. The reaction conditions for a Suzuki coupling or a Sonogashira reaction are widely known in the technical field, and the examples give valuable pointers in this connection.

The reactive metal complexes for use as reactant for a Suzuki coupling or a Sonogashira reaction can be obtained, for example, by known halogenations, preferably brominations, from known metal complexes.

Iridium complexes suitable as reactants can be obtained by reaction of the corresponding free ligands with metal alkoxides of the formula (47), with metal ketoketonates of the formula (48), with metal halides of the formula (49) or with metal carboxylates of the formula (50)

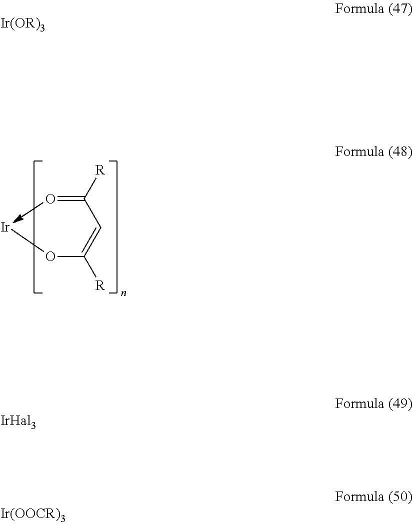

where R has the definitions given above, Hal=F, Cl, Br or I and the iridium reactants may also take the form of the corresponding hydrates. R here is preferably an alkyl group having 1 to 4 carbon atoms.

It is likewise possible to use iridium compounds bearing both alkoxide and/or halide and/or hydroxyl and ketoketonate radicals. These compounds may also be charged. Corresponding iridium compounds of particular suitability as reactants are disclosed in WO 2004/085449. Particularly suitable are [IrCl₂(acac)₂]-, for example Na[IrCl₂(acac)₂], metal complexes with acetylacetonate derivatives as ligand, for example Ir(acac)₃ or tris(2,2,6,6-tetramethylheptane-3,5-dionato)iridium, and IrCl₃.xH₂O where x is typically a number from 2 to 4.

The synthesis of the complexes for use in accordance with the invention is preferably conducted as described in WO 2002/060910 and in WO 2004/085449. In this case, the synthesis can, for example, also be activated by thermal or photochemical means and/or by microwave radiation. In addition, the synthesis can also be conducted in an autoclave at elevated pressure and/or elevated temperature.

The reactions can be conducted without addition of solvents or melting aids in a melt of the corresponding ligands to be o-metallated. It is optionally possible to add solvents or melting aids. Suitable solvents are protic or aprotic solvents such as aliphatic and/or aromatic alcohols (methanol, ethanol, isopropanol, t-butanol, etc.), oligo- and polyalcohols (ethylene glycol, propane-1,2-diol, glycerol, etc.), alcohol ethers (ethoxyethanol, diethylene glycol, triethylene glycol, polyethylene glycol, etc.), ethers (di- and triethylene glycol dimethyl ether, diphenyl ether, etc.), aromatic, heteroaromatic and/or aliphatic hydrocarbons (toluene, xylene, mesitylene, chlorobenzene, pyridine, lutidine, quinoline, isoquinoline, tridecane, hexadecane, etc.), amides (DMF, DMAC, etc.), lactams (NMP), sulfoxides (DMSO) or sulfones (dimethyl sulfone, sulfolane, etc.). Suitable melting aids are compounds that are in solid form at room temperature but melt when the reaction mixture is heated and dissolve the reactants, so as to form a homogeneous melt. Particularly suitable are biphenyl, m-terphenyl, triphenyls, R- or S-binaphthol or else the corresponding racemate, 1,2-, 1,3- or 1,4-bisphenoxybenzene, triphenylphosphine oxide, 18-crown-6, phenol, 1-naphthol, hydroquinone, etc. Particular preference is given here to the use of hydroquinone.

Elucidations relating to the preparation methods can be found in the examples.

It is possible by these processes, if necessary followed by purification, for example recrystallization or sublimation, to obtain the inventive compounds of formula (1) in high purity, preferably more than 99% (determined by means of ¹H NMR and/or HPLC).

The metal complexes of the invention may also be rendered soluble by suitable substitution, for example by comparatively long alkyl groups (about 4 to 20 carbon atoms), especially branched alkyl groups, or optionally substituted aryl groups, for example xylyl, mesityl or branched terphenyl or quaterphenyl groups. Another particular method that leads to a distinct improvement in the solubility of the metal complexes is the use of fused-on aliphatic groups, as shown, for example, by the formulae (44) to (50) disclosed above. Such compounds are then soluble in sufficient concentration at room temperature in standard organic solvents, for example toluene or xylene, to be able to process the complexes from solution. These soluble compounds are of particularly good suitability for processing from solution, for example by printing methods.

The compounds of the invention can also be mixed with a polymer or incorporated covalently into a polymer. This is especially possible with compounds substituted by reactive leaving groups such as bromine, iodine, chlorine, boronic acid or boronic ester, or by reactive polymerizable groups such as olefins or oxetanes. These may find use as monomers for production of corresponding oligomers, dendrimers or polymers. The oligomerization or polymerization is preferably effected via the halogen functionality or the boronic acid functionality or via the polymerizable group. In a preferred embodiment of the present invention, the compounds of the invention, when they are used in oligomers, dendrimers or polymers, are used as end group therein.

The invention therefore further provides oligomers, polymers or dendrimers containing one or more of the above-detailed compounds of the invention, wherein one or more bonds of the compound of the invention to the polymer, oligomer or dendrimer are present. According to the linkage of the compound of the invention, it therefore forms a side chain of the oligomer or polymer or is incorporated in the main chain or constitutes an end group. The polymers, oligomers or dendrimers may be conjugated, partly conjugated or nonconjugated. The oligomers or polymers may be linear, branched or dendritic. For the repeat units of the compounds of the invention in oligomers, dendrimers and polymers, the same preferences apply as described above.

For the processing of the metal complexes of the invention from the liquid phase, for example by spin-coating or by printing methods, formulations of the metal complexes of the invention are required. These formulations may, for example, be solutions, dispersions or emulsions. For this purpose, it may be preferable to use mixtures of two or more solvents. Suitable and preferred solvents are, for example, toluene, anisole, o-, m- or p-xylene, methyl benzoate, mesitylene, tetralin, veratrole, THF, methyl-THF, THP, chlorobenzene, dioxane, phenoxytoluene, especially 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane, hexamethylindane or mixtures of these solvents.

The present invention therefore further provides a formulation comprising at least one metal complex of the invention and at least one further compound. The further compound may, for example, be a solvent, especially one of the abovementioned solvents or a mixture of these solvents. The further compound may alternatively be a further organic or inorganic compound which is likewise used in the electronic device, for example a matrix material. This further compound may also be polymeric.

The present invention therefore still further provides a composition comprising a compound of the invention and at least one further organically functional material. Functional materials are generally the organic or inorganic materials introduced between the anode and cathode. Preferably, the organically functional material is selected from the group consisting of fluorescent emitters, phosphorescent emitters, host materials, electron transport materials, electron injection materials, hole conductor materials, hole injection materials, electron blocker materials, hole blocker materials, wide band gap materials and n-dopants.

The above-described metal complex of the invention or the preferred embodiments detailed above can be used in the electronic device as active component or as oxygen sensitizers or in photocatalysis. The present invention thus further provides for the use of a compound of the invention in an electronic device or as oxygen sensitizer. In this case, the metal complex of the invention can preferably be used as a phosphorescent emitter. The present invention still further provides an electronic device comprising at least one compound of the invention.

An electronic device is understood to mean any device comprising anode, cathode and at least one layer, said layer comprising at least one organic or organometallic compound. The electronic device of the invention thus comprises anode, cathode and at least one layer containing at least one metal complex of the invention. Preferred electronic devices are selected from the group consisting of organic electroluminescent devices (OLEDs, PLEDs), organic integrated circuits (O-ICs), organic field-effect transistors (O-FETs), organic thin-film transistors (O-TFTs), organic light-emitting transistors (O-LETs), organic solar cells (O-SCs), the latter being understood to mean both purely organic solar cells and dye-sensitized solar cells (Grätzel cells), organic optical detectors, organic photoreceptors, organic field-quench devices (O-FQDs), light-emitting electrochemical cells (LECs), oxygen sensors and organic laser diodes (O-lasers), comprising at least one metal complex of the invention in at least one layer. Particular preference is given to organic electroluminescent devices. Active components are generally the organic or inorganic materials introduced between the anode and cathode, for example charge injection, charge transport or charge blocker materials, but especially emission materials and matrix materials. The compounds of the invention exhibit particularly good properties as emission material in organic electroluminescent devices. A preferred embodiment of the invention is therefore organic electroluminescent devices. In addition, the compounds of the invention can be used for production of singlet oxygen or in photocatalysis.

The organic electroluminescent device comprises cathode, anode and at least one emitting layer. Apart from these layers, it may comprise still further layers, for example in each case one or more hole injection layers, hole transport layers, hole blocker layers, electron transport layers, electron injection layers, exciton blocker layers, electron blocker layers, charge generation layers and/or organic or inorganic p/n junctions. At the same time, it is possible that one or more hole transport layers are p-doped, for example with metal oxides such as MoO₃ or WO₃ or with (per)fluorinated electron-deficient aromatic systems, and/or that one or more electron transport layers are n-doped. It is likewise possible for interlayers to be introduced between two emitting layers, these having, for example, an exciton-blocking function and/or controlling the charge balance in the electroluminescent device. However, it should be pointed out that not necessarily every one of these layers need be present.

In this case, it is possible for the organic electroluminescent device to contain an emitting layer, or for it to contain a plurality of emitting layers. If a plurality of emission layers are present, these preferably have several emission maxima between 380 nm and 750 nm overall, such that the overall result is white emission; in other words, various emitting compounds which may fluoresce or phosphoresce are used in the emitting layers. Three-layer systems are especially preferred, where the three layers exhibit blue, green and orange or red emission, or systems having more than three emitting layers. The system may also be a hybrid system wherein one or more layers fluoresce and one or more other layers phosphoresce. Preference is further given to tandem OLEDs. White-emitting organic electroluminescent devices may be used for lighting applications or else with color filters for full-color displays.

In a preferred embodiment of the invention, the organic electroluminescent device comprises the metal complex of the invention as emitting compound in one or more emitting layers.

When the metal complex of the invention is used as emitting compound in an emitting layer, it is preferably used in combination with one or more matrix materials. The mixture of the metal complex of the invention and the matrix material contains between 0.1% and 99% by weight, preferably between 1% and 90% by weight, more preferably between 3% and 40% by weight and especially between 5% and 25% by weight of the metal complex of the invention, based on the overall mixture of emitter and matrix material. Correspondingly, the mixture contains between 99.9% and 1% by weight, preferably between 99% and 10% by weight, more preferably between 97% and 60% by weight and especially between 95% and 75% by weight of the matrix material, based on the overall mixture of emitter and matrix material.

The matrix material used may generally be any materials which are known for the purpose according to the prior art. The triplet level of the matrix material is preferably higher than the triplet level of the emitter.

Suitable matrix materials for the compounds of the invention are ketones, phosphine oxides, sulfoxides and sulfones, for example according to WO 2004/013080, WO 2004/093207, WO 2006/005627 or WO 2010/006680, triarylamines, carbazole derivatives, e.g. CBP (N,N-biscarbazolylbiphenyl), m-CBP or the carbazole derivatives disclosed in WO 2005/039246, US 2005/0069729, JP 2004/288381, EP 1205527, WO 2008/086851 or US 2009/0134784, indolocarbazole derivatives, for example according to WO 2007/063754 or WO 2008/056746, indenocarbazole derivatives, for example according to WO 2010/136109 or WO 2011/000455, azacarbazoles, for example according to EP 1617710, EP 1617711, EP 1731584, JP 2005/347160, bipolar matrix materials, for example according to WO 2007/137725, silanes, for example according to WO 2005/111172, azaboroles or boronic esters, for example according to WO 2006/117052, diazasilole derivatives, for example according to WO 2010/054729, diazaphosphole derivatives, for example according to WO 2010/054730, triazine derivatives, for example according to WO 2010/015306, WO 2007/063754 or WO 2008/056746, zinc complexes, for example according to EP 652273 or WO 2009/062578, dibenzofuran derivatives, for example according to WO 2009/148015 or WO 2015/169412, or bridged carbazole derivatives, for example according to US 2009/0136779, WO 2010/050778, WO 2011/042107 or WO 2011/088877.

It may also be preferable to use a plurality of different matrix materials as a mixture, especially at least one electron-conducting matrix material and at least one hole-conducting matrix material. A preferred combination is, for example, the use of an aromatic ketone, a triazine derivative or a phosphine oxide derivative with a triarylamine derivative or a carbazole derivative as mixed matrix for the metal complex of the invention. Preference is likewise given to the use of a mixture of a charge-transporting matrix material and an electrically inert matrix material having no significant involvement, if any, in the charge transport, as described, for example, in WO 2010/108579. Preference is likewise given to the use of two electron-transporting matrix materials, for example triazine derivatives and lactam derivatives, as described, for example, in WO 2014/094964.

It is further preferable to use a mixture of two or more triplet emitters together with a matrix. In this case, the triplet emitter having the shorter-wave emission spectrum serves as co-matrix for the triplet emitter having the longer-wave emission spectrum. For example, it is possible to use the metal complexes of the invention as co-matrix for longer-wave-emitting triplet emitters, for example for green- or red-emitting triplet emitters. In this case, it may also be preferable when both the shorter-wave- and the longer-wave-emitting metal complex is a compound of the invention.

The metal complexes of the invention can also be used in other functions in the electronic device, for example as hole transport material in a hole injection or transport layer, as charge generation material, as electron blocker material, as hole blocker material or as electron transport material, for example in an electron transport layer, according to the choice of metal and the exact structure of the ligand. When the metal complex of the invention is an aluminum complex, it is preferably used in an electron transport layer. It is likewise possible to use the metal complexes of the invention as matrix material for other phosphorescent metal complexes in an emitting layer.

Preferred cathodes are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag, in which case combinations of the metals such as Mg/Ag, Ca/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). Likewise useful for this purpose are organic alkali metal complexes, e.g. Liq (lithium quinolinate). The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au. Secondly, metal/metal oxide electrodes (e.g. Al/Ni/NiOₓ, Al/PtOₓ) may also be preferred. For some applications, at least one of the electrodes has to be transparent or partly transparent in order to enable either the irradiation of the organic material (O-SC) or the emission of light (OLED/PLED, O-LASER). Preferred anode materials here are conductive mixed metal oxides. Particular preference is given to indium tin oxide (ITO) or indium zinc oxide (IZO). Preference is further given to conductive doped organic materials, especially conductive doped polymers, for example PEDOT, PANI or derivatives of these polymers. It is further preferable when a p-doped hole transport material is applied to the anode as hole injection layer, in which case suitable p-dopants are metal oxides, for example MoO₃ or WO₃, or (per)fluorinated electron-deficient aromatic systems. Further suitable p-dopants are HAT-CN (hexacyanohexaazatriphenylene) or the compound NPD9 from Novaled. Such a layer simplifies hole injection into materials having a low HOMO, i.e. a large HOMO in terms of magnitude.

In the further layers, it is generally possible to use any materials as used according to the prior art for the layers, and the person skilled in the art is able, without exercising inventive skill, to combine any of these materials with the materials of the invention in an electronic device.

The device is correspondingly (according to the application) structured, contact-connected and finally hermetically sealed, since the lifetime of such devices is severely shortened in the presence of water and/or air.

Additionally preferred is an organic electroluminescent device, characterized in that one or more layers are coated by a sublimation process. In this case, the materials are applied by vapor deposition in vacuum sublimation systems at an initial pressure of typically less than 10⁻⁵ mbar, preferably less than 10⁻⁶ mbar. It is also possible that the initial pressure is even lower or even higher, for example less than 10⁻⁷ mbar.

Preference is likewise given to an organic electroluminescent device, characterized in that one or more layers are coated by the OVPD (organic vapor phase deposition) method or with the aid of a carrier gas sublimation. In this case, the materials are applied at a pressure between 10⁻⁵ mbar and 1 bar. A special case of this method is the OVJP (organic vapor jet printing) method, in which the materials are applied directly by a nozzle and thus structured (for example M. S. Arnold et al., Appl. Phys. Lett. 2008, 92, 053301).

Preference is additionally given to an organic electroluminescent device, characterized in that one or more layers are produced from solution, for example by spin-coating, or by any printing method, for example screen printing, flexographic printing, offset printing or nozzle printing, but more preferably LITI (light-induced thermal imaging, thermal transfer printing) or inkjet printing. For this purpose, soluble compounds are needed, which are obtained, for example, through suitable substitution. In a preferred embodiment of the invention, the layer comprising the compound of the invention is applied from solution.

The organic electroluminescent device can also be produced as a hybrid system by applying one or more layers from solution and applying one or more other layers by vapor deposition. For example, it is possible to apply an emitting layer comprising a metal complex of the invention and a matrix material from solution, and to apply a hole blocker layer and/or an electron transport layer thereto by vapor deposition under reduced pressure.

These methods are known in general terms to those skilled in the art and can be applied by those skilled in the art without difficulty to organic electroluminescent devices comprising compounds of formula (1) or the above-detailed preferred embodiments.

The electronic devices of the invention, especially organic electroluminescent devices, are notable for one or more of the following surprising advantages over the prior art:
1. The metal complexes of the invention show oriented emission. This enables higher quantum efficiencies through improved outcoupling of light out of the component and hence higher efficiency of the OLED. In this way, it is also possible to increase the lifetime since the OLED can be operated at lower current.
2. The metal complexes of the invention can be synthesized in very high yield and very high purity with exceptionally short reaction times and at comparatively low reaction temperatures.
3. The metal complexes of the invention have excellent thermal stability.
4. Preferred metal complexes of the invention, especially bridged metal complexes, exhibit neither thermal nor photochemical fac/mer or mer/fac isomerization, which leads to advantages in the use of these complexes.
5. Some of the metal complexes of the invention have a very narrow emission spectrum, which leads to a high color purity in the emission, as is desirable particularly for display applications.
6. The metal complexes of the invention have very good processibility from solution and excellent solubility in many organic solvents.
7. Organic electroluminescent devices comprising the metal complexes of the invention as emitting materials have a very good lifetime.
8. Organic electroluminescent devices comprising the metal complexes of the invention as emitting materials have excellent efficiency.

These abovementioned advantages are not accompanied by a deterioration in the further electronic properties.

The invention is illustrated in more detail by the examples which follow, without any intention of restricting it thereby. The person skilled in the art will be able to use the details given, without exercising inventive skill, to produce further electronic devices of the invention and hence to execute the invention over the entire scope claimed.

### EXAMPLES

The syntheses which follow, unless stated otherwise, are conducted under a protective gas atmosphere in dried solvents. The metal complexes are additionally handled with exclusion of light or under yellow light. The solvents and reagents can be purchased, for example, from Sigma-ALDRICH or ABCR. The respective figures in square brackets or the numbers quoted for individual compounds relate to the CAS numbers of the compounds known from the literature.

### Synthesis Examples

A: Organometallic Synthons Known from Literature:

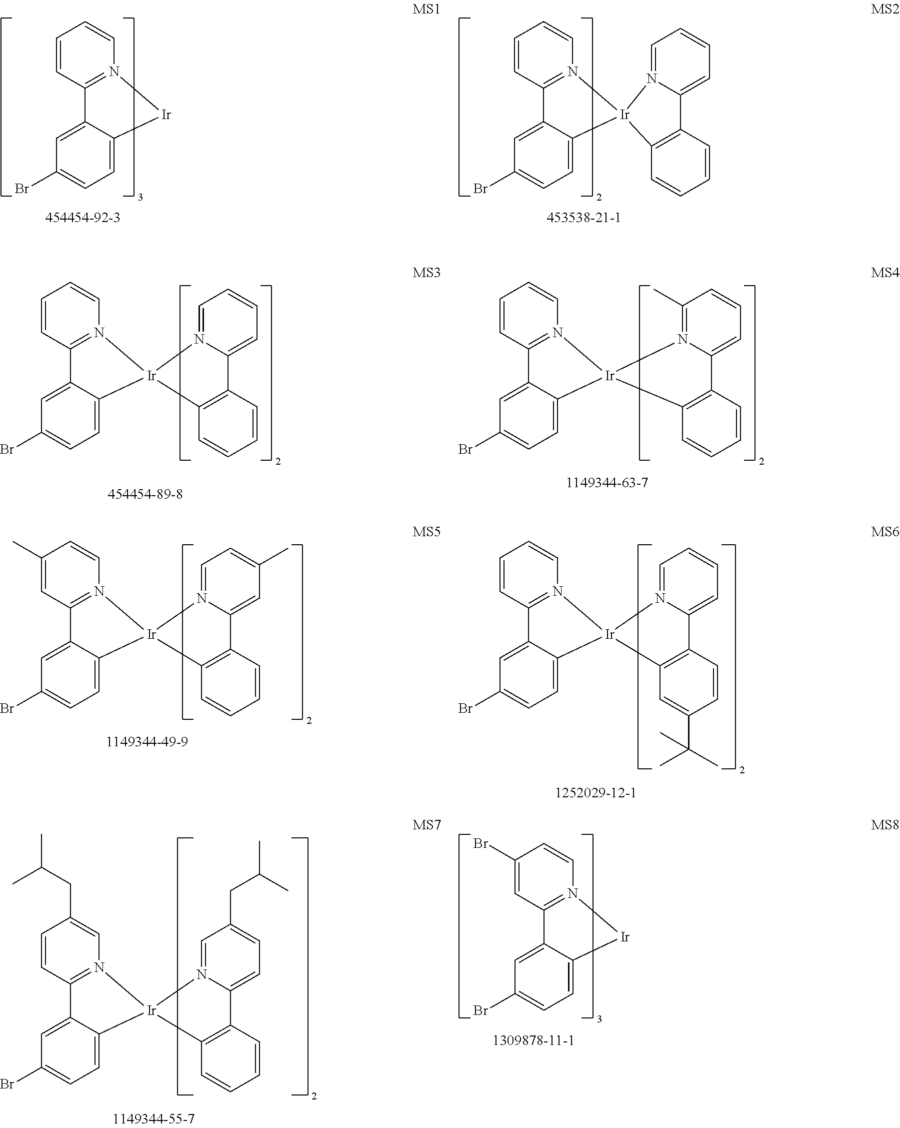

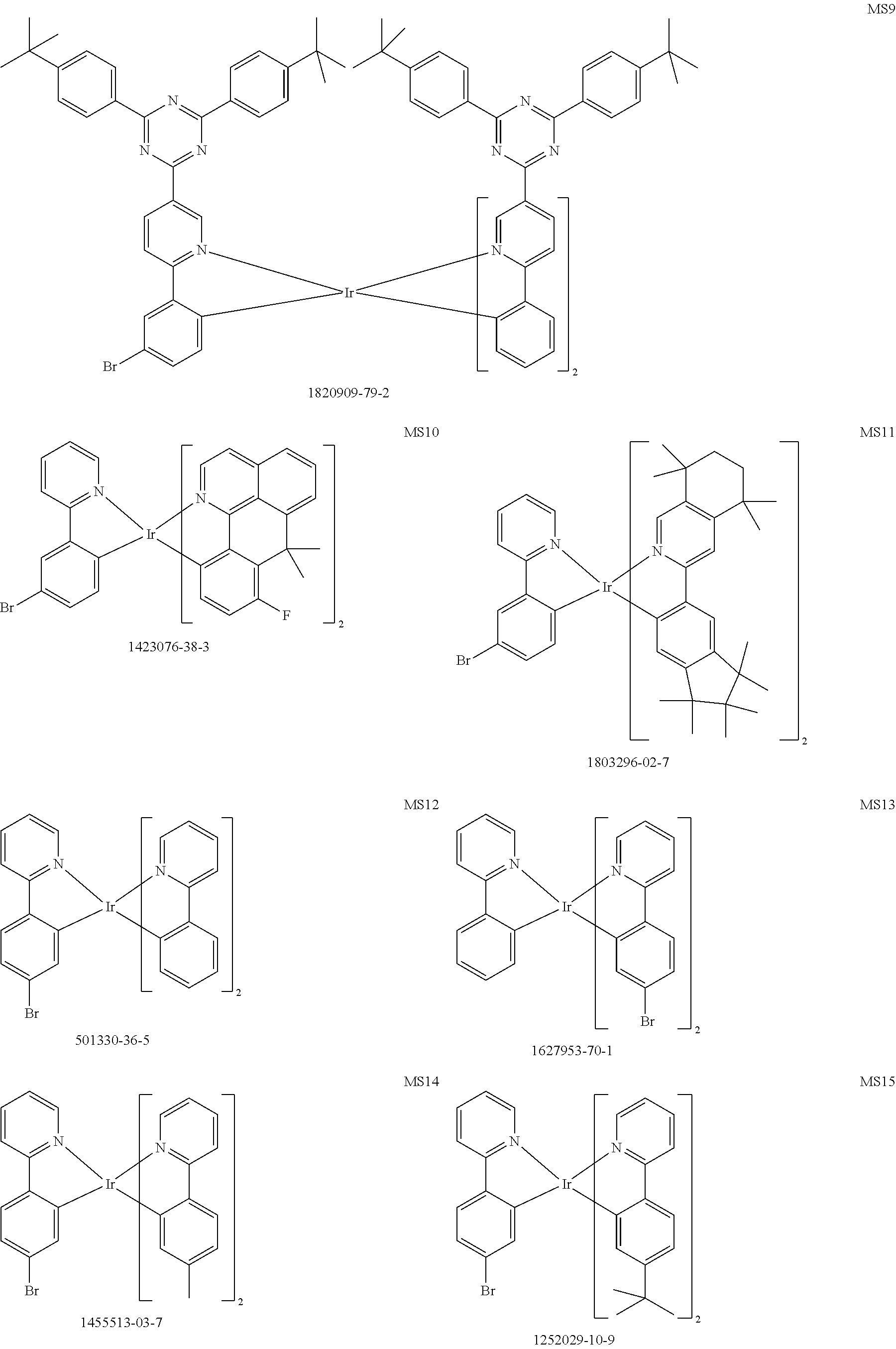

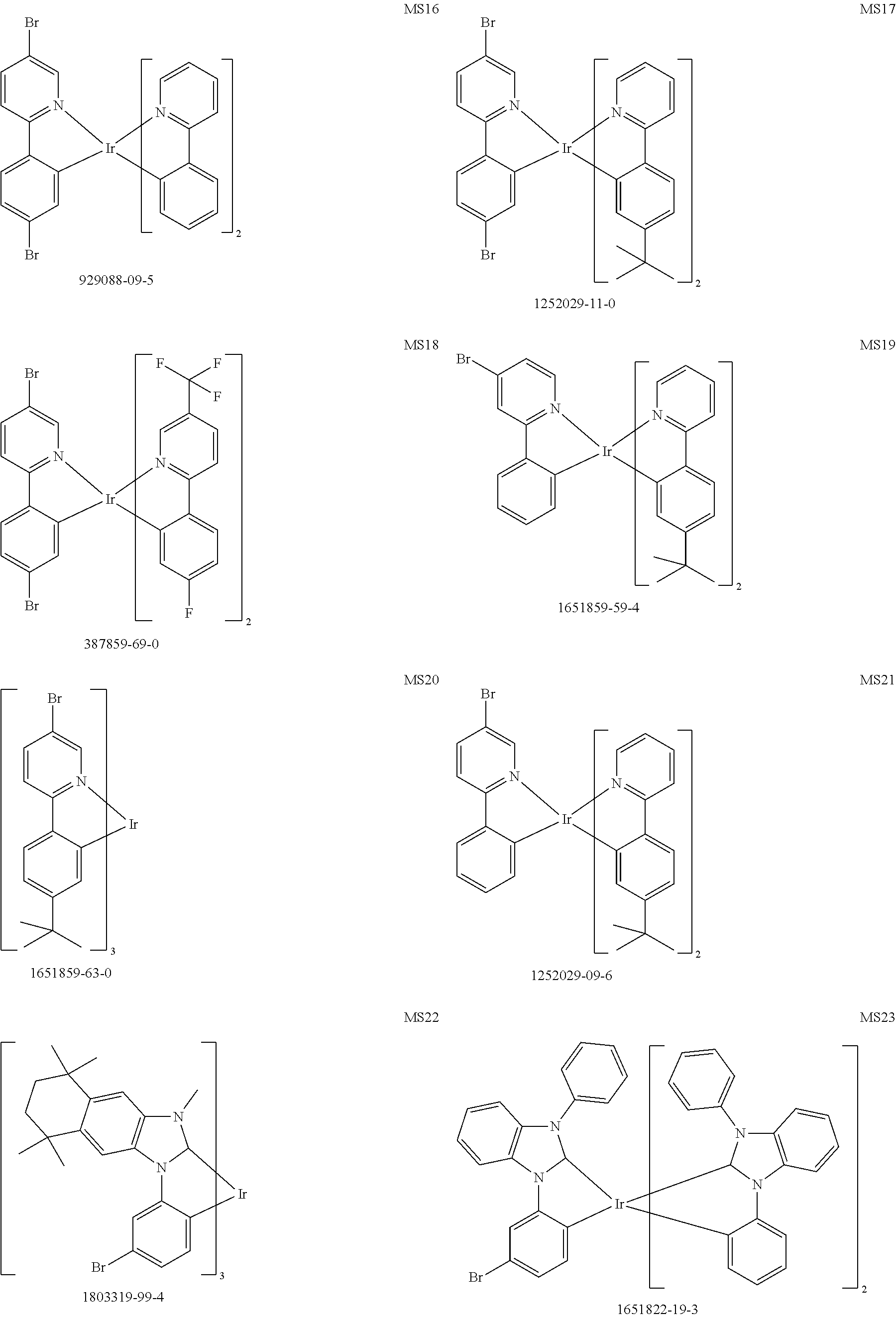

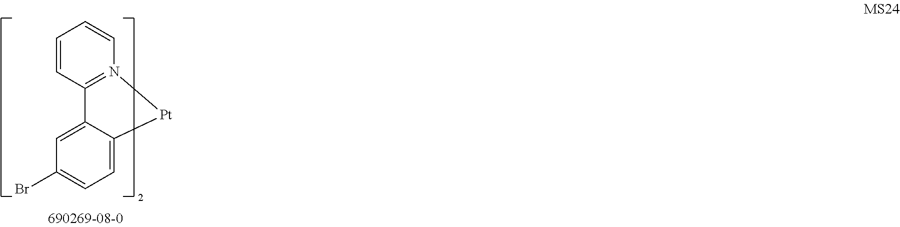

B: Synthesis of Hexadentate Ligands L:

### Example L1

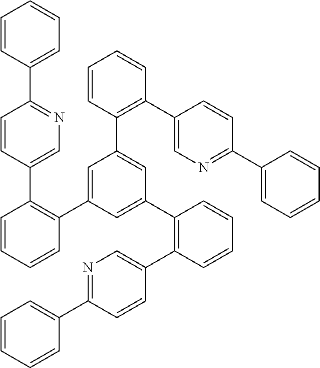 [SMILES: c1ccc(-c2ccc(-c3ccccc3-c3cc(-c4ccccc4-c4ccc(-c5ccccc5)nc4)cc(-c4ccccc4-c4ccc(-c5ccccc5)nc4)c3)cn2)cc1]

A mixture of 54.1 g (100 mmol) of 1,3,5-tris(2-bromophenyl)benzene [380626-56-2], 98.4 g (350 mmol) of 2-phenyl-5-(4,4,5,5-tetramethyl-[1,3,2]dioxaborolan-2-yl)pyridine [879291-27-7], 106.0 g (1 mol) of sodium carbonate, 5.8 g (5 mmol) of tetrakis(triphenylphosphino)palladium(0), 750 ml of toluene, 200 ml of ethanol and 500 ml of water is heated under reflux with very good stirring for 24 h. After 24 h, 300 ml of 5% by weight aqueous acetylcysteine solution are added, the mixture is stirred under reflux for a further 16 h and allowed to cool, the aqueous phase is removed and the organic phase is concentrated to dryness. After the organic phase from the Suzuki coupling has been concentrated, the brown foam is taken up in 300 ml of a mixture of dichloromethane:ethyl acetate (8:1, v/v) and filtered through a silica gel bed in the form of a dichloromethane:ethyl acetate slurry (8:1, v/v) (diameter 15 cm, length 20 cm), in order to remove brown components. After concentration, the remaining foam is recrystallized from 800 ml of ethyl acetate with addition of 400 ml of methanol at boiling and then for a second time from 1000 ml of pure ethyl acetate and then subjected to Kugelrohr sublimation under high vacuum (p about 10⁻⁵ mbar, T 280° C.). Yield: 50.6 g (66 mmol), 66%. Purity: about 99.7% by ¹H NMR.

### Example L2

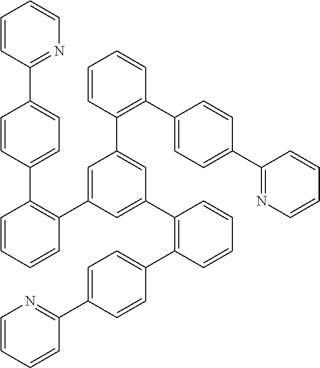 [SMILES: c1ccc(-c2ccc(-c3ccccc3-c3cc(-c4ccccc4-c4ccc(-c5ccccn5)cc4)cc(-c4ccccc4-c4ccc(-c5ccccn5)cc4)c3)cc2)nc1]

Ligand L2 can be prepared analogously. Rather than 2-phenyl-5-(4,4,5,5-tetramethyl-[1,3,2]dioxaborolan-2-yl)pyridine [879291-27-7], 2-[4-(4,4,5,5-tetramethyl-[1,3,2]dioxaborolan-2-yl)phenyl]pyridine [908350-80-1] is used. Yield: 56.0 g (73 mmol), 73%. Purity: about 99.7% by ¹H NMR.

C: Synthesis of the Metal Complexes Ir(L):

### Example Ir(L1)

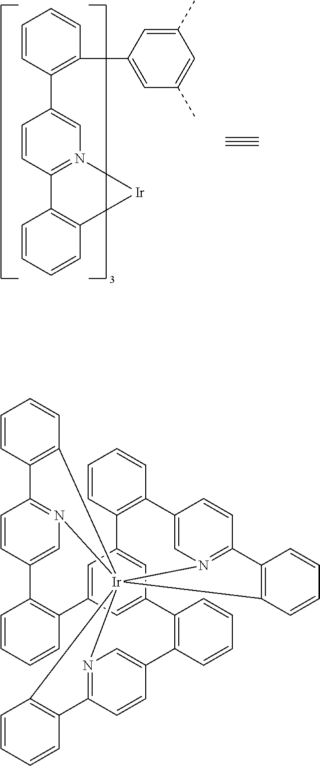

A mixture of 7.66 g (10 mmol) of ligand L1, 4.90 g (10 mmol) of trisacetylacetonatoiridium(III) [15635-87-7] and 120 g of hydroquinone [123-31-9] is initially charged in a 500 ml two-neck round-bottom flask with a glass-sheathed magnetic bar. The flask is provided with a water separator (for media of lower density than water) and an air condenser with argon blanketing. The flask is placed in a metal heating bath. The apparatus is purged with argon from the top via the argon blanketing system for 15 min, allowing the argon to flow out of the side neck of the two-neck flask. Through the side neck of the two-neck flask, a glass-sheathed Pt-100 thermocouple is introduced into the flask and the end is positioned just above the magnetic stirrer bar. Then the apparatus is thermally insulated with several loose windings of domestic aluminum foil, the insulation being run up to the middle of the riser tube of the water separator. Then the apparatus is heated rapidly with a heated laboratory stirrer system to 250-260° C., measured with the Pt-100 thermal sensor which dips into the molten stirred reaction mixture. Over the next 1.5 h, the reaction mixture is kept at 250-260° C., in the course of which a small amount of condensate is distilled off and collects in the water separator. After cooling, the melt cake is mechanically comminuted and extracted by boiling with 500 ml of methanol. The beige suspension thus obtained is filtered through a double-ended frit, and the beige solid is washed once with 50 ml of methanol and then dried under reduced pressure. Crude yield: quantitative. The solid thus obtained is dissolved in 1500 ml of dichloromethane and filtered through about 1 kg of silica gel in the form of a dichloromethane slurry (column diameter about 18 cm) with exclusion of air in the dark, leaving dark-coloured components at the start. The core fraction is cut out and substantially concentrated on a rotary evaporator, with simultaneous continuous dropwise addition of MeOH until crystallization. After removal with suction, washing with a little MeOH and drying under reduced pressure, the yellow product is purified further by continuous hot extraction three times with toluene:acetonitrile (3:1, v/v) and hot extraction five times with toluene (amount initially charged in each case about 150 ml, extraction thimble: standard Soxhlet thimbles made from cellulose from Whatman) with careful exclusion of air and light. Yield: 8.52 g (8.9 mmol), 89%. Purity: >99.9% by HPLC.

### Example Ir(L2)

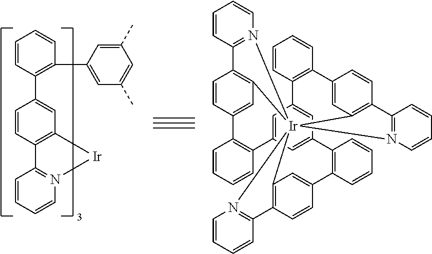

Ir(L2) can be prepared analogously using L2 rather than L1. Purification is effected by recrystallization from NMP three times with addition of methanol in the course of cooling of the solution. Yield: 8.04 g (8.4 mmol), 84%. Purity: >99.7% by HPLC.

D: Halogenation of the Metal Complex Ir(L):

General Procedure:

To a solution or suspension of 10 mmol of a complex bearing A x C—H groups in the para position to the iridium in 500 ml to 2000 ml of dichloromethane according to the solubility of the metal complexes is added, in the dark and with exclusion of air, at −30 to +30° C., A x 10.5 mmol of N-halosuccinimide (halogen: Cl, Br, I; A=1 corresponds to monohalogenation, A=2 corresponds to dihalogenation, A=3 corresponds to trihalogenation), and the mixture is stirred for 20 h. Complexes of sparing solubility in DCM may also be converted in other solvents (TCE, THF, DMF, chlorobenzene, etc.) and at elevated temperature. Subsequently, the solvent is substantially removed under reduced pressure. The residue is extracted by boiling with 100 ml of methanol, and the solids are filtered off with suction, washed three times with about 30 ml of methanol and then dried under reduced pressure. This gives the iridium complexes brominated in the para position to the iridium. Complexes having a HOMO (CV) of about −5.1 to −5.0 eV and of smaller magnitude have a tendency to oxidation (Ir(III)>Ir(IV)), the oxidizing agent being bromine released from NBS. This oxidation reaction is apparent by a distinct green hue in the otherwise yellow to red solutions/suspensions of the emitters. In such cases, a further equivalent of NBS is added. For workup, 300-500 ml of methanol and 2 ml of hydrazine hydrate as reducing agent are added, which causes the green solutions/suspensions to turn yellow (reduction of Ir(IV)>Ir(III)). Then the solvent is substantially drawn off under reduced pressure, 300 ml of methanol are added, and the solids are filtered off with suction, washed three times with 100 ml each time of methanol and dried under reduced pressure. Substoichiometric brominations, for example mono- and dibrominations, of complexes having 3 C—H groups in the para position to iridium usually proceed less selectively than the stoichiometric brominations. The crude products of these brominations can be separated by chromatography (CombiFlash Torrent from A. Semrau).

### Example Ir(L1-3Br)

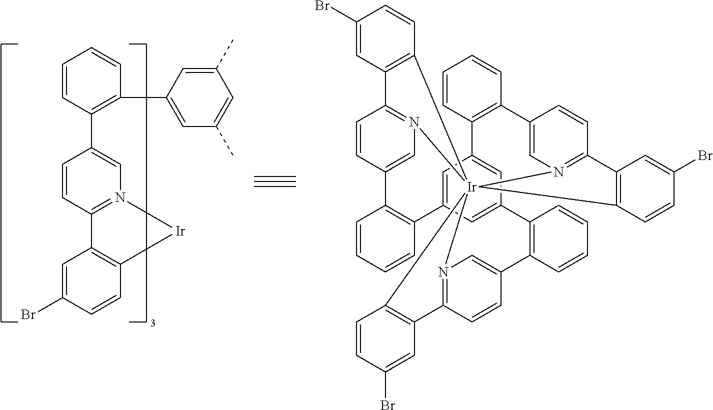

To a suspension, stirred at 0° C., of 9.6 g (10 mmol) of Ir(L1) in 2000 ml of DCM are added 5.6 g (31.5 mmol) of N-bromosuccinimide all at once and then the mixture is stirred for a further 20 h. After removing about 1900 ml of the DCM under reduced pressure, 100 ml of methanol are added to the yellow suspension, which is boiled while stirring, and the solids are filtered off with suction, washed three times with about 30 ml of methanol and then dried under reduced pressure. Yield: 11.3 g (9.5 mmol), 95%. Purity: >99.0% by NMR.

In an analogous manner, it is possible to prepare the following complexes:

| | | |
|---|---|---|
| Ex. | Reactant > brominated complex | Yield |

Tribromination

| | |
|---|---|
| Ir(L2-3Br) | 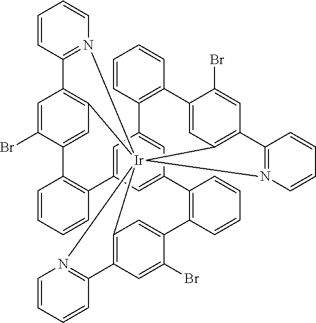 |
| | Ir(L2) + 40 mmol NBS > Ir(L2-3Br) |
| | DCM solvent |

Dibromination

| | | |
|---|---|---|
| Ir(L1-2Br) | 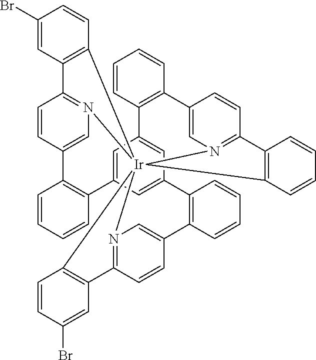 | 33% |
| | Ir(L1) + 21 mmol NBS > Ir(L1-2Br) | |
| | DMSO solvent | |
| Ir(L2-2Br) | 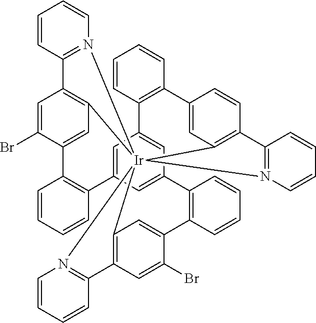 | 26% |
| | Ir(L2) + 21 mmol NBS > Ir(L2-2Br) | |
| | DMSO solvent/60° C. | |

Monobromination

| | | |
|---|---|---|
| Ir(L1-1Br) | 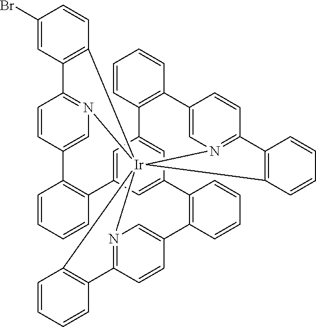 | 24% |
| | Ir(L1) + 10.5 mmol NBS > Ir(L1-1Br) | |
| | DMSO solvent | |
| Ir(L2-1Br) | 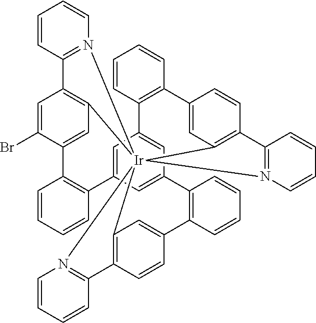 | 19% |
| | Ir(L2) + 10.5 mmol NBS > Ir(L2-1Br) | |
| | DMSO solvent/60° C. | |

E: Preparation of the Metal Complexes with an Alkyne Function

1) By Sonogashira Coupling

### Example Ir(100)

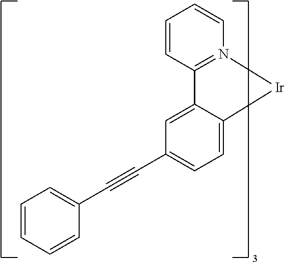

To a mixture of 26.8 g (30 mmol) of MS1, 12.2 g (120 mmol) of phenylacetylene [25038-69-1], 150 ml of dimethylacetamide (DMAC) and 50 ml of triethylamine are added 191 mg (1 mmol) of copper(I) iodide, 224 mg (1 mmol) of palladium(II) acetate and 525 mg (2 mmol) of triphenylphosphine, and then the mixture is stirred in an autoclave at 130° C. for 16 h. After cooling, the solvent is largely removed under reduced pressure, the residue is taken up in 500 ml of dichloromethane and filtered through a silica gel bed in the form of a dichloromethane slurry, and the bed is washed through with 100 ml of dichloromethane. The filtrate is washed three times with 300 ml each time of water and once with 300 ml of saturated sodium chloride solution, dried over magnesium sulfate and then concentrated to dryness. The crude product thus obtained is chromatographed with dichloromethane on silica gel. Yield: 11.5 g (12 mmol), 40%; purity: >99.0% by NMR.

Analogously, the corresponding alkynes can be used to prepare the compounds which follow, with adjustment of the reagents and catalysts in accordance with the molar amount of bromine functions.

| | Product | |
|---|---|---|
| Ex. | Reactants | Yield |
| Ir(101) | 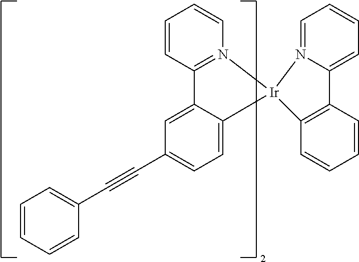 | 64% |
| | MS2/25038-69-1 | |
| Ir(102) | 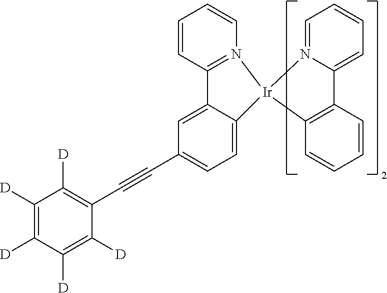 | 72% |
| | MS3/25837-46-1 | |
| Ir(103) | 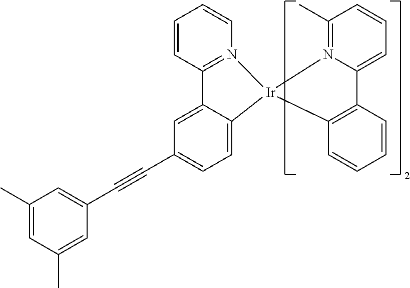 | 59% |
| | MS4/6366-06-9 | |
| Ir(104) | 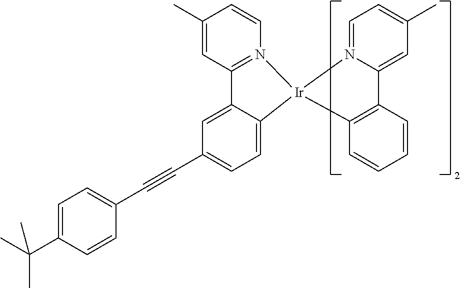 | 68% |
| | MS5/772-38-3 | |
| Ir(105) | 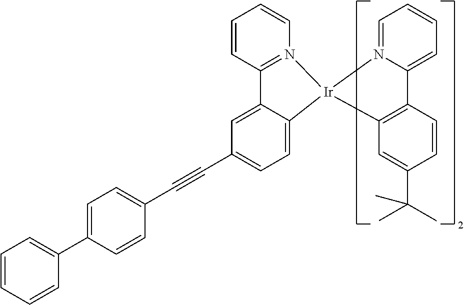 | 66% |
| | MS6/29079-00-3 | |
| Ir(106) | 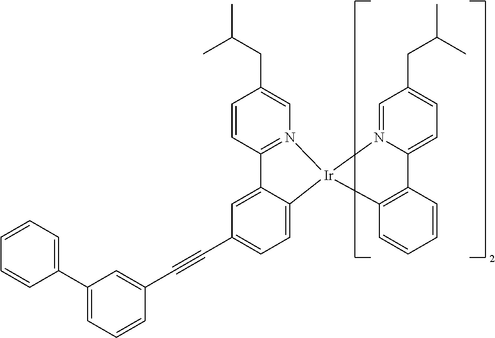 | 70% |
| | MS7/58650-11-6 | |
| Ir(107) | 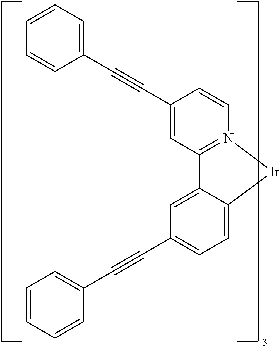 | 34% |
| | MS8/25038-69-1 | |
| Ir(108) | 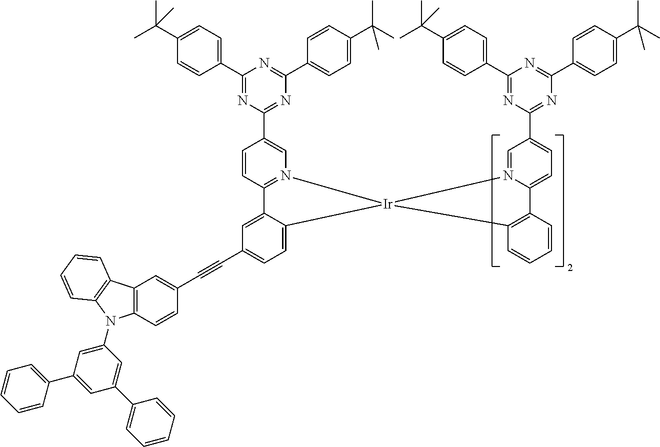 | 54% |
| | MS9/1679326-74-9 | |
| Ir(109) | 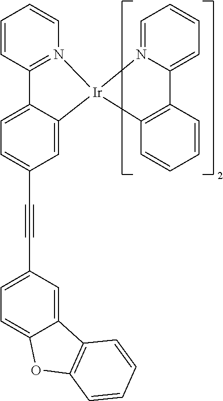 | 60% |
| | MS12/1378260-35-5 | |
| Ir(110) | 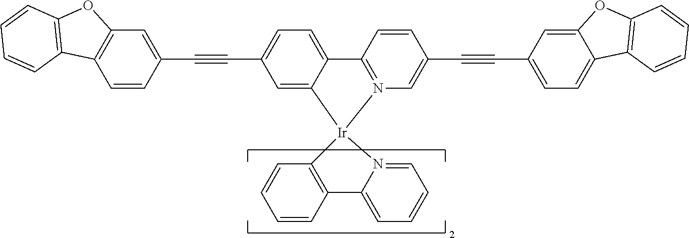 | 58% |
| | MS16/1427176-74-6 | |
| Ir(111) | 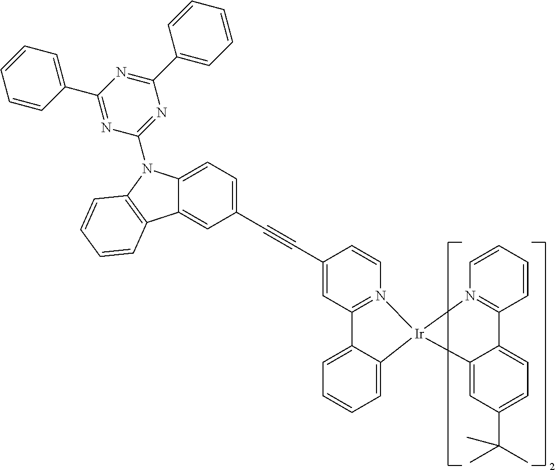 | 47% |
| | MS19/1679326-69-2 | |
| Ir(112) | 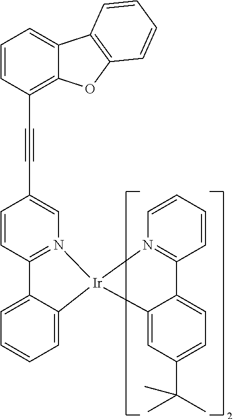 | 56% |
| | MS21/1378255-47-0 | |
| Ir(113) | 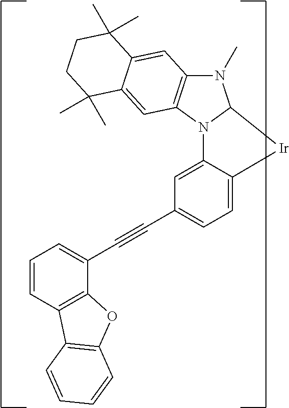 | 45% |
| | MS22/1548471-54-0 | |
| Ir(114) | 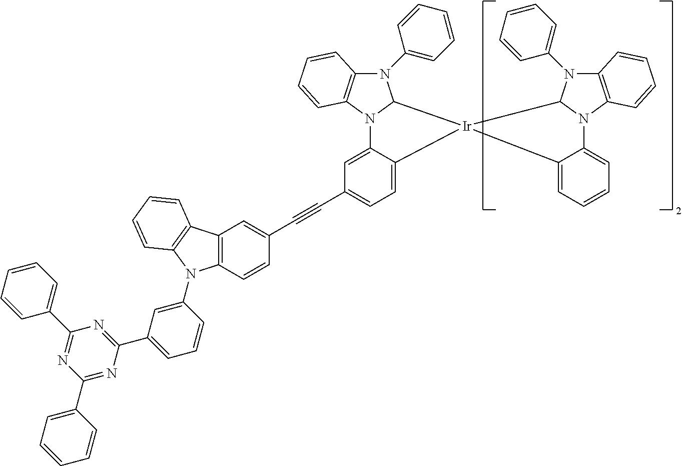 | 53% |
| | MS23/1621630-10-1 | |
| Ir(115) | 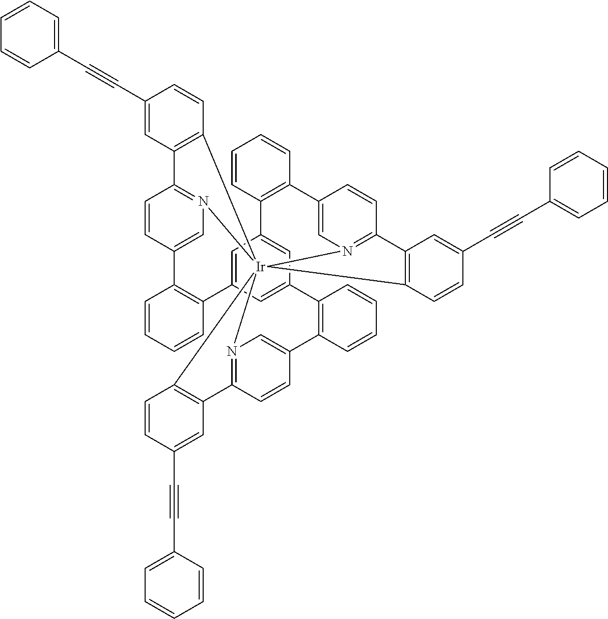 | 58% |
| | Ir(L1-3Br)25038-69-1 | |
| Ir(116) | 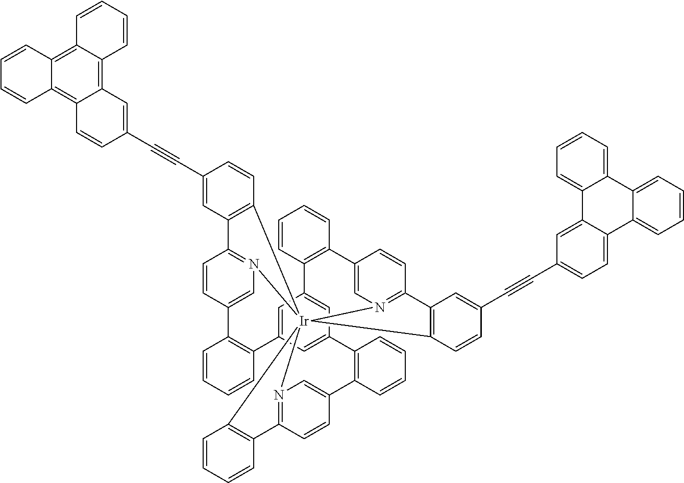 | 66% |
| | Ir(L1-2Br)/1271731-38-4 | |
| Ir(117) | 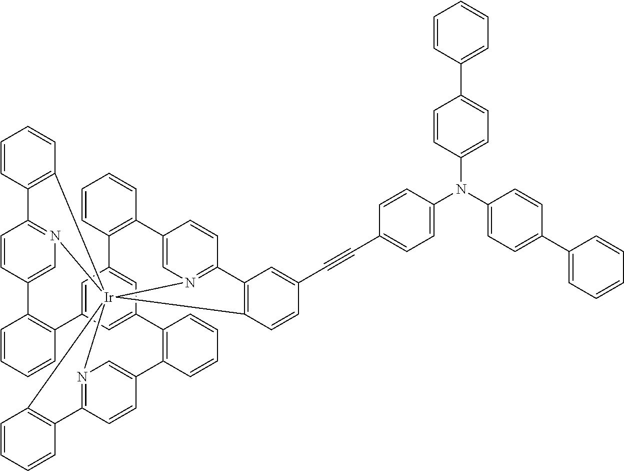 | 31% |
| | Ir(L1-1Br)/1187569-85-2 | |
| Pt(100) | 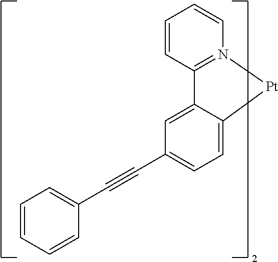 | 23% |
| | MS24/25038-69-1 | |

2) By Suzuki Coupling

### Example Ir(200)

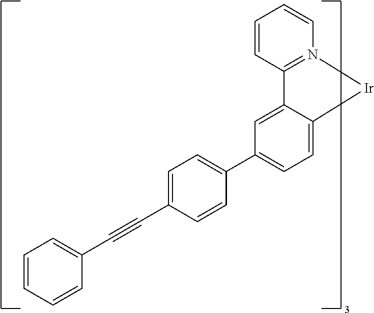

A mixture of 26.8 g (30 mmol) of MS1, 30.4 g (100 mmol) of 4,4,5,5-tetramethyl-2-[4-(2-phenylethynyl)-1,3,2-dioxaborolane [1190376-20-5], 69.1 g (300 mmol) of tripotassium phosphate monohydrate, 3.5 g (3 mmol) of tetrakis(triphenylphosphino)palladium(0), 50 g of glass beads (diameter 3 mm) and 500 ml DMSO is heated to 90° C. with good stirring for 25 h. After cooling, the solvent is largely removed under reduced pressure, the residue is taken up in 500 ml of dichloromethane and filtered through a Celite bed in the form of a dichloromethane slurry, and the bed is washed through with 100 ml of dichloromethane. The filtrate is washed three times with 300 ml each time of water and once with 300 ml of saturated sodium chloride solution, dried over magnesium sulfate and then concentrated to dryness. The crude product thus obtained is chromatographed with dichloromethane on silica gel. Yield: 25.6 g (21.6 mmol), 72%. Purity: about 99.0% by NMR.

Analogously, the corresponding alkynes can be used to prepare the compounds which follow, with adjustment of the reagents and catalysts in accordance with the molar amount of bromine functions.

| | | |
|---|---|---|
| | Product | |
| Ex. | Reactants | Yield |

Mononuclear metal complexes

| | | |
|---|---|---|
| Ir(201) | 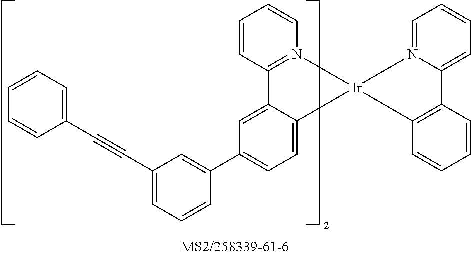 | 70% |
| Ir(202) | 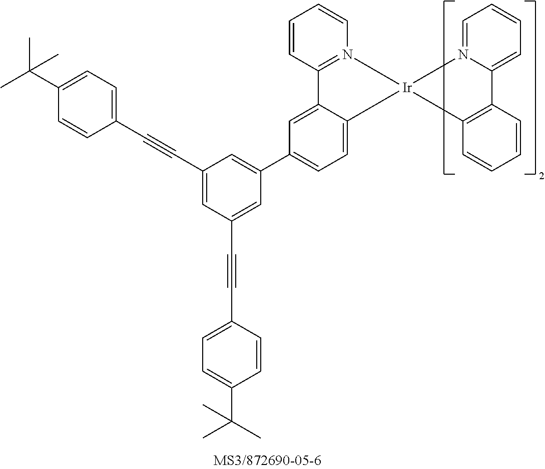 | 86% |
| Ir(203) | 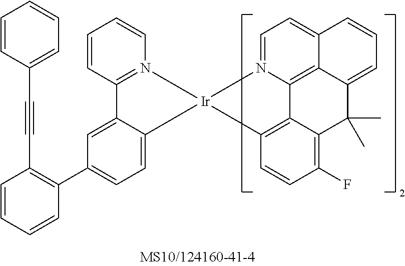 | 48% |
| Ir(204) | 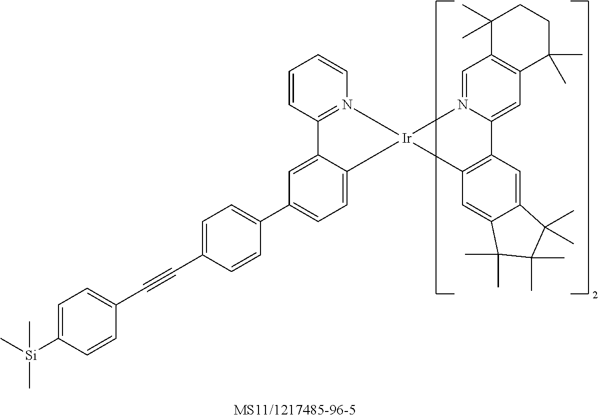 | 85% |
| Ir(205) | 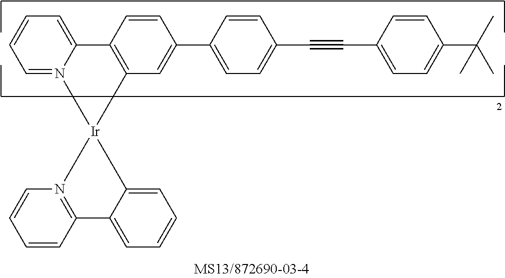 | 66% |
| Ir(206) | 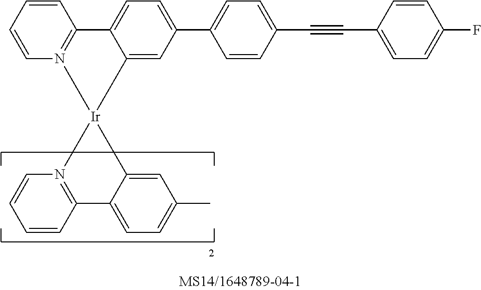 | 78% |
| Ir(207) | 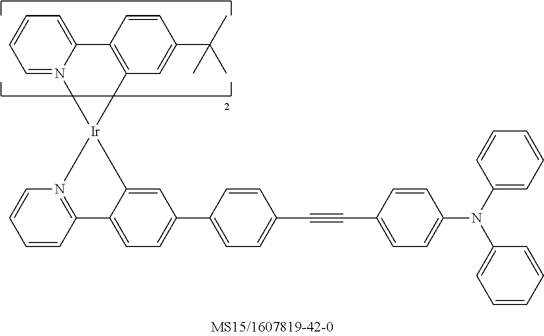 | 74% |
| Ir(208) | 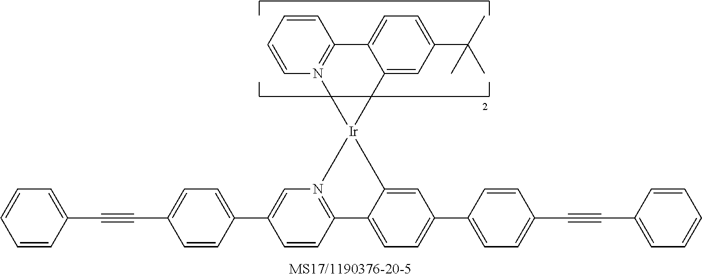 | 71% |
| Ir(209) | 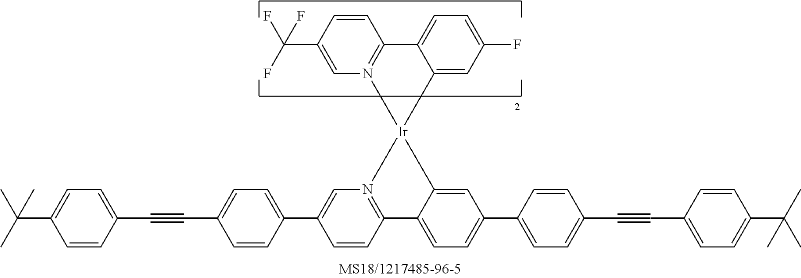 | 70% |
| Ir(210) | 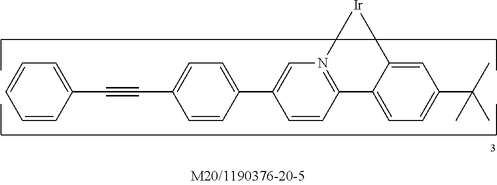 | 68% |
| Ir(211) | 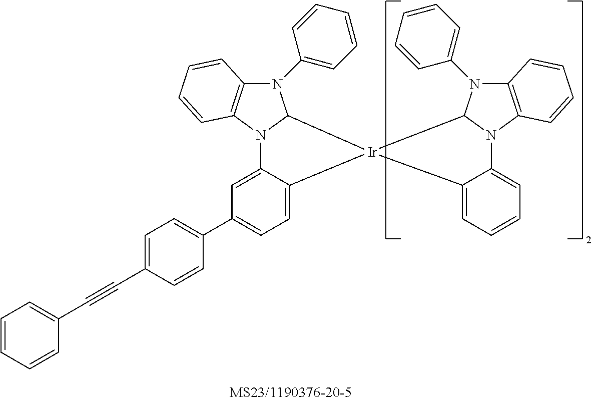 | 82% |
| Ir(212) | 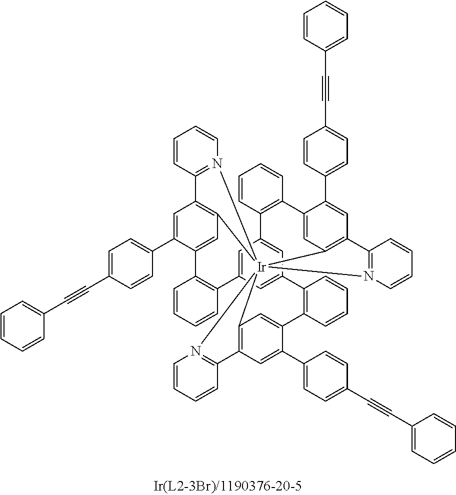 | 80% |
| Ir(213) | 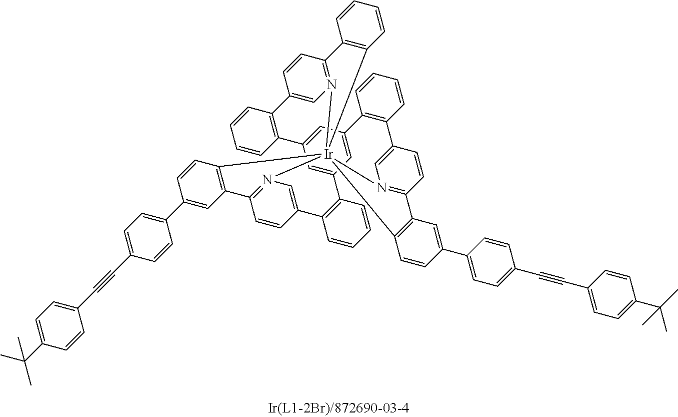 | 75% |
| Ir(214) | 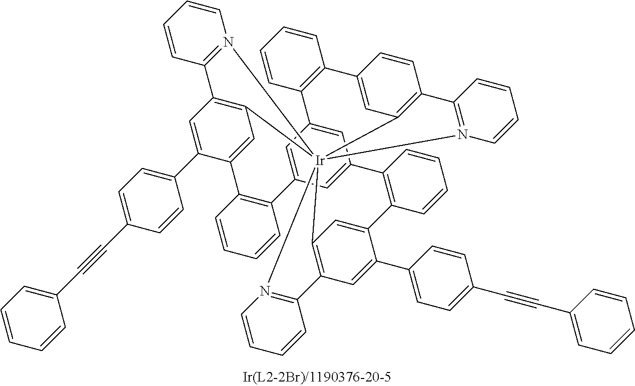 | 83% |
| Ir(215) | 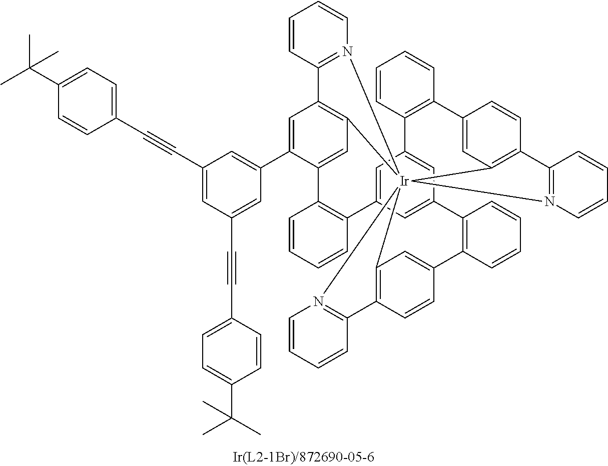 | 88% |
| Ir(216) | 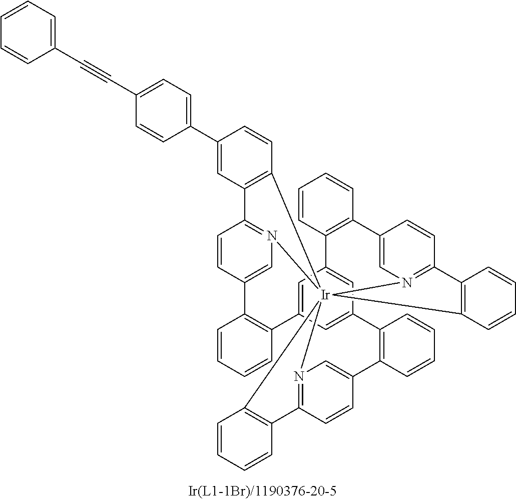 | 74% |
| Ir(217) | 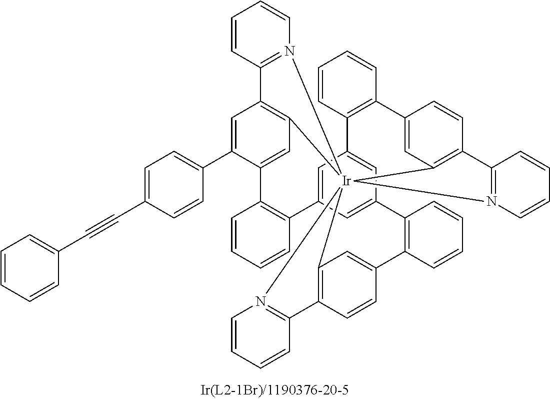 | 88% |

Dinuclear metal complexes

| | | |
|---|---|---|
| Ir(300) | 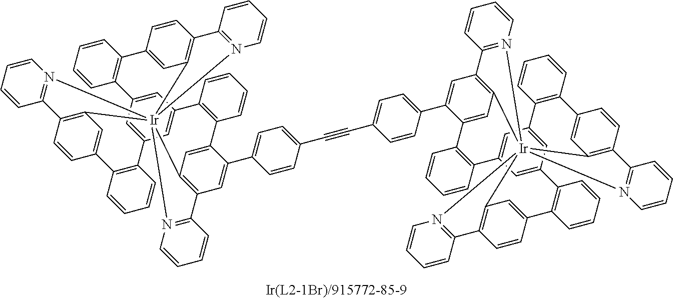 | 54% |
| Ir(301) | 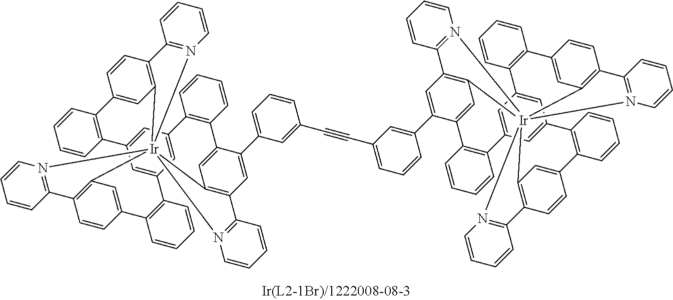 | 57% |

E: Preparation of the Metal Complexes of the Invention:

### Example Ir(500)

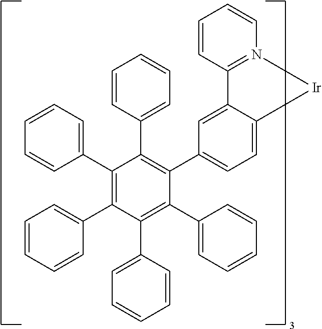

A mixture of 9.6 g (10 mmol) of Ir(100), 12.7 g (33 mmol) of 2,3,4,5-tetraphenyl-2,4-cyclopentadien-1-one [479-33-4] and 30 ml of diphenyl ether (an alternative is to use 3-phenoxytoluene) is heated to 255-260° C. for 24 h. After cooling to 60° C., the reaction mixture is added dropwise to 200 ml of methanol with good stirring and stirred for a further 1 h, and the precipitated solids are filtered off with suction, washed three times with 50 ml each time of methanol and dried under reduced pressure. The crude product thus obtained is chromatographed on silica gel (n-heptane:ethyl acetate 9:1). Subsequently, the solids are subjected to hot extraction five times with ethyl acetate/acetonitrile (1:2) (amount initially charged 250 ml) and then freed of solvent residues under high vacuum at 180° C. Yield: 10.5 g (5.2 mmol), 52%. Purity: about 99.9% by HPLC.

The compounds which follow can be prepared in an analogous manner, with appropriate variation in the stoichiometric ratio of alkyne to carbonyl component.

| | Product | |
|---|---|---|
| Ex. | Reactants | Yield |
| Ir(501) | 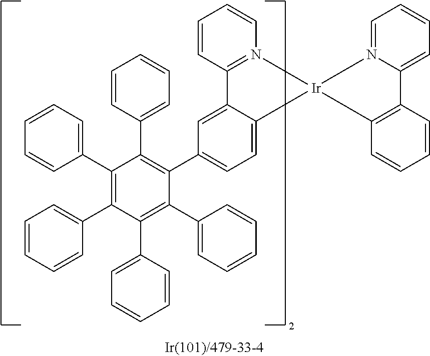 | 27% |
| Ir(502) | 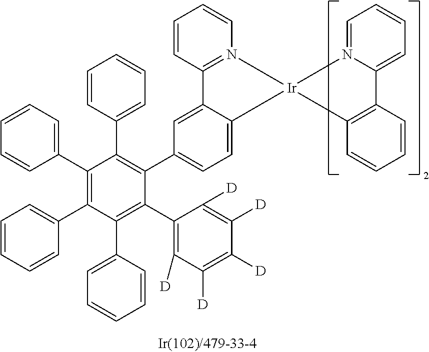 | 30% |
| Ir(503) | 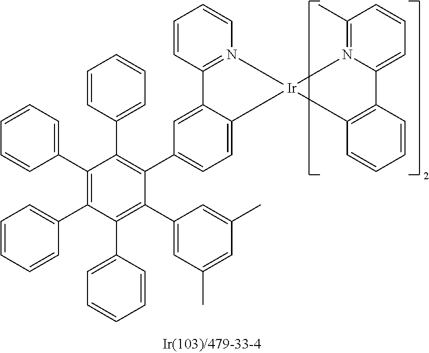 | 25% |
| Ir(504) | 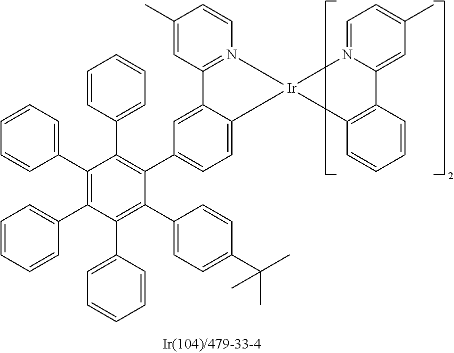 | 33% |
| Ir(505) | 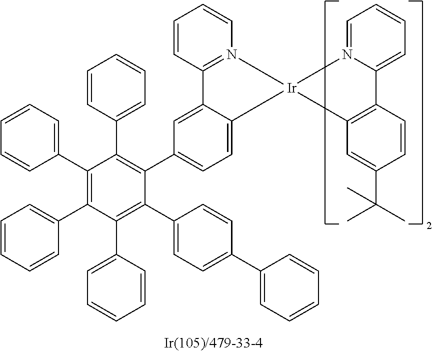 | 29% |
| Ir(506) | 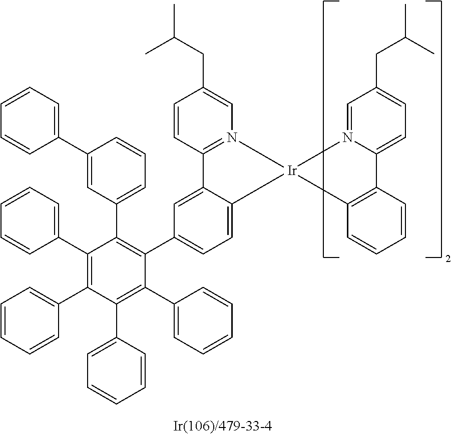 | 34% |
| Ir(507) | 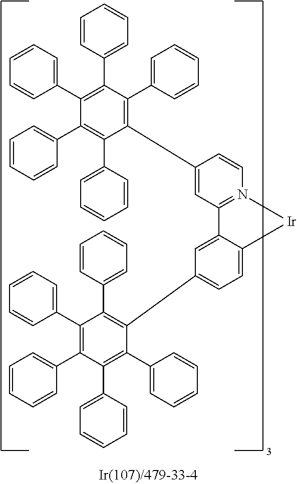 | 24% |
| Ir(508) | 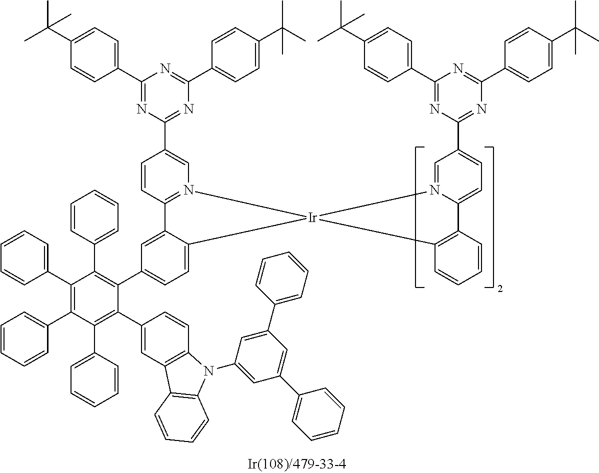 | 30% |
| Ir(509) | 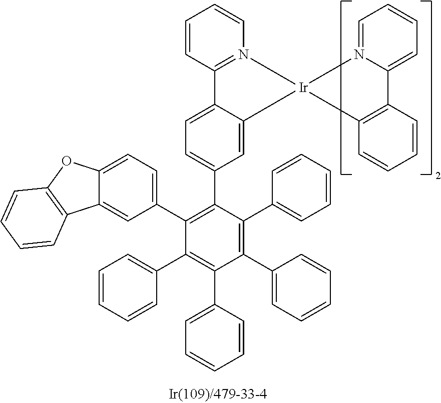 | 35% |
| Ir(510) | 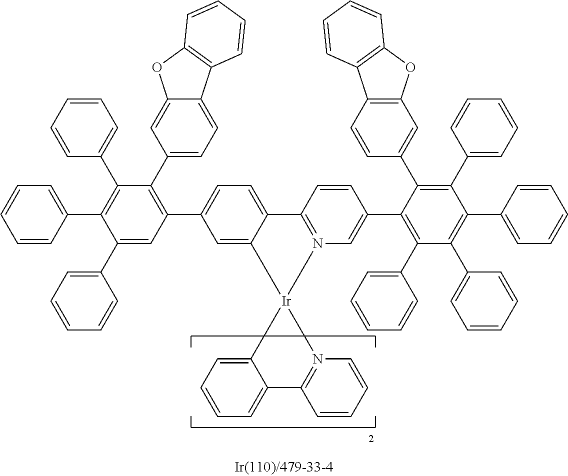 | 28% |
| Ir(511) | 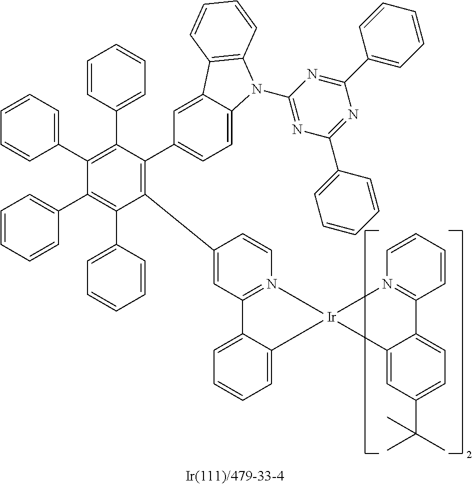 | 21% |
| Ir(512) | 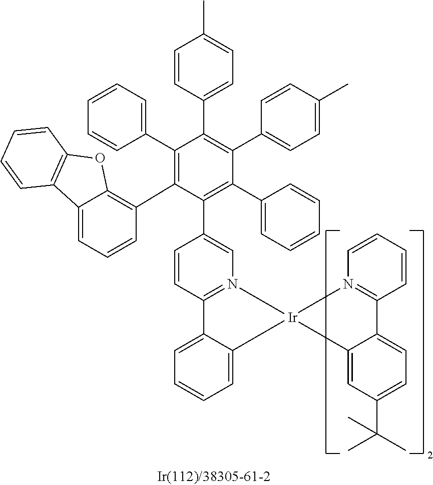 | 26% |
| Ir(513) | 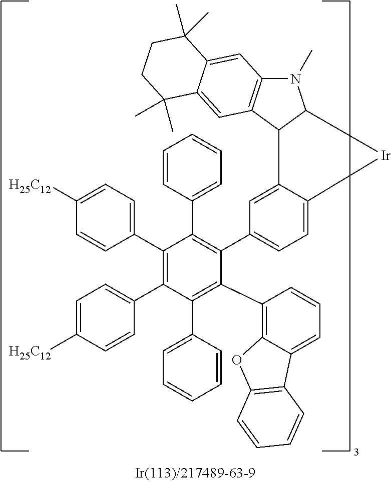 | 31% |
| Ir(514) | 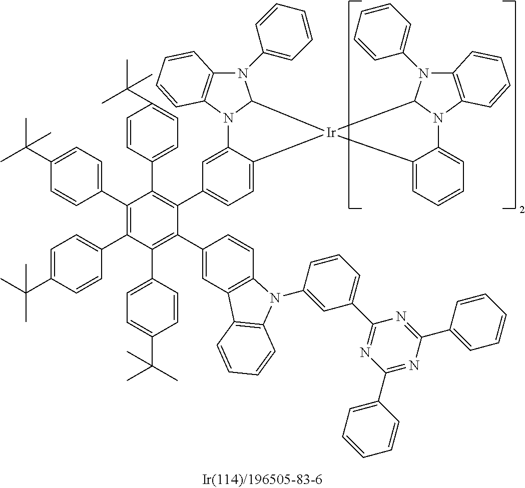 | 24% |
| Ir(515) | 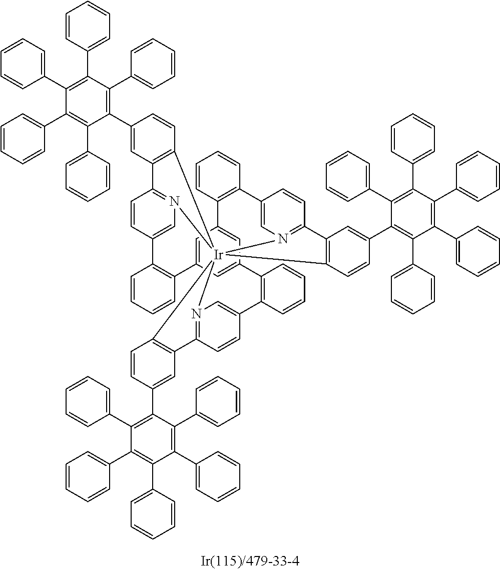 | 64% |
| Ir(516) | 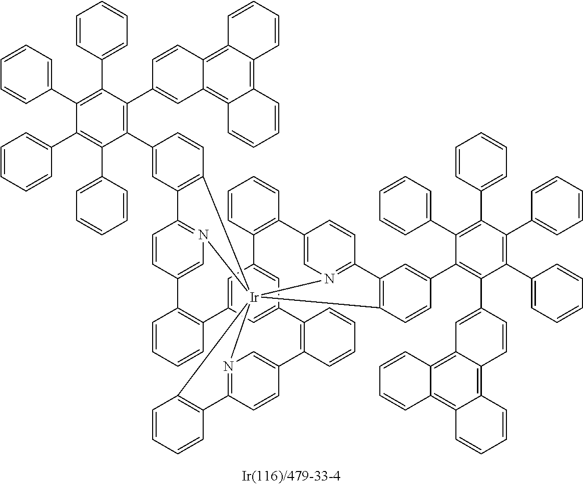 | 67% |
| Ir(517) | 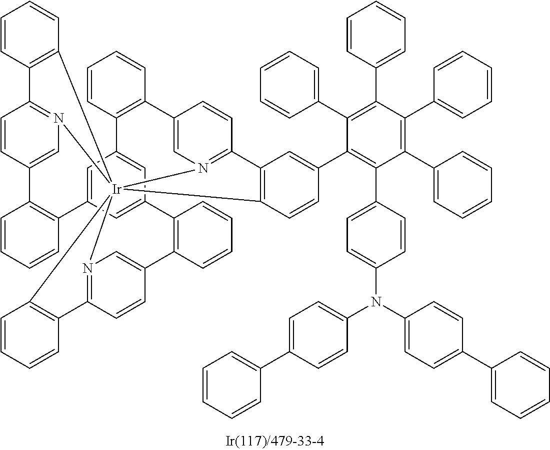 | 63% |
| Pt(500) | 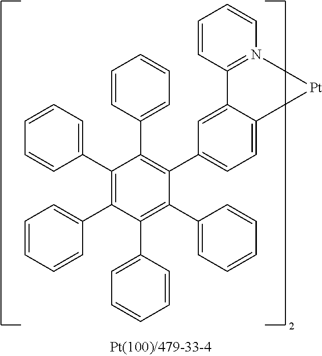 | 18% |
| Ir(518) | 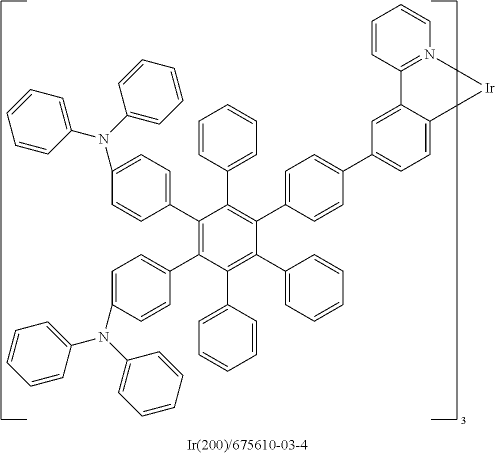 | 32% |
| Ir(519) | 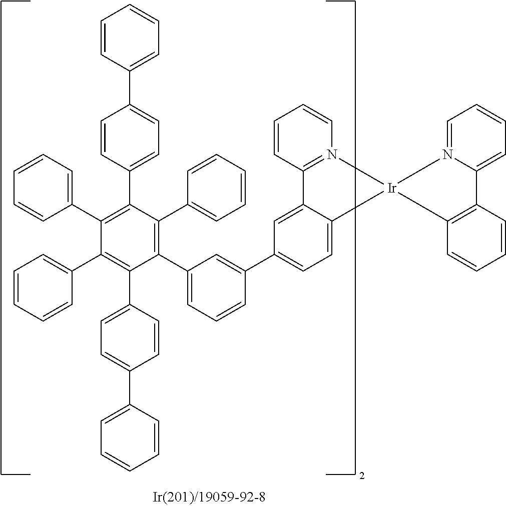 | 34% |
| Ir(520) | 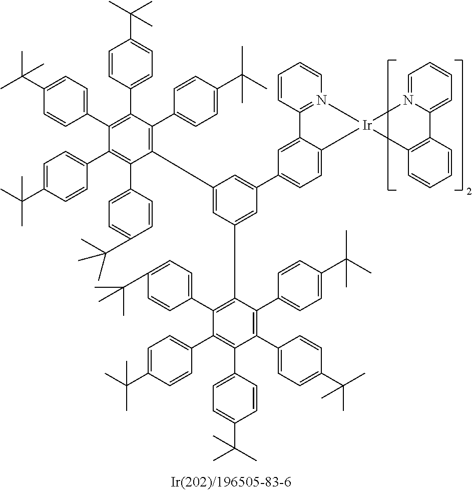 | 28% |
| Ir(521) | 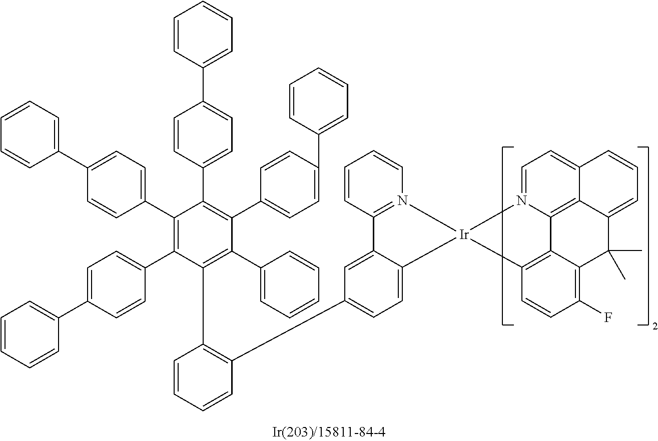 | 17% |
| Ir(522) | 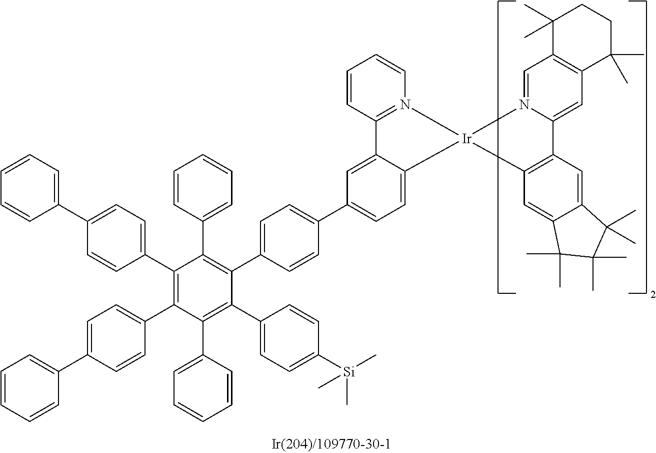 | 26% |
| Ir(523) | 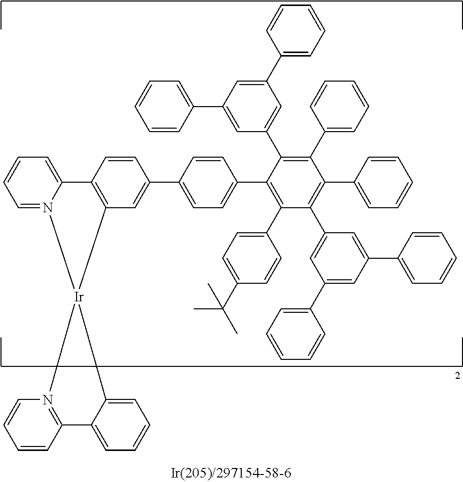 | 28% |
| Ir(524) | 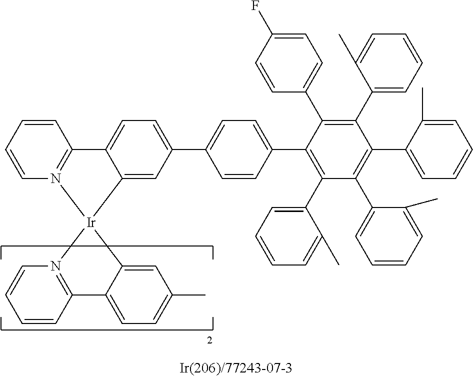 | 31% |
| Ir(525) | 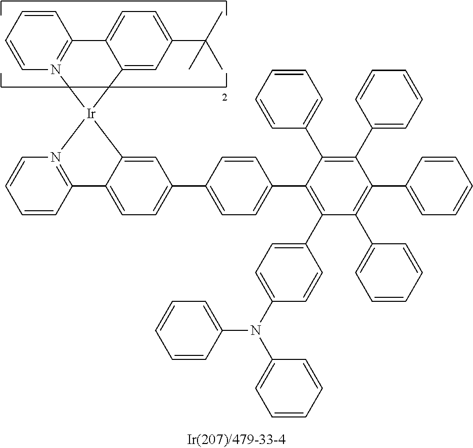 | 20% |
| Ir(526) | 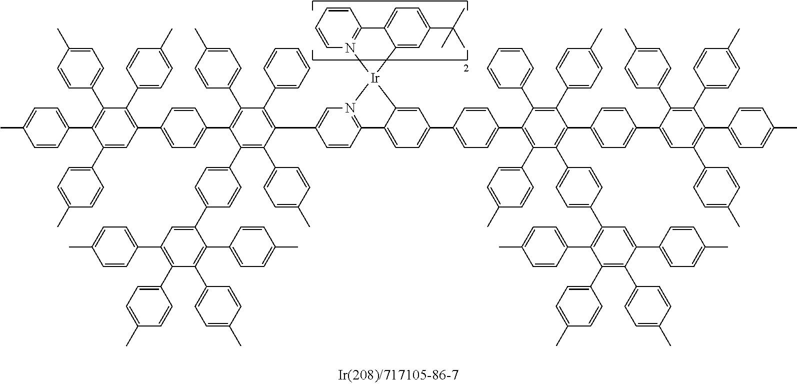 | 23% |
| Ir(527) | 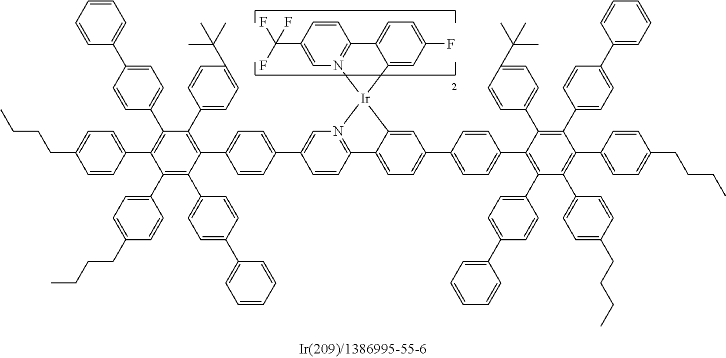 | 25% |
| Ir(528) | 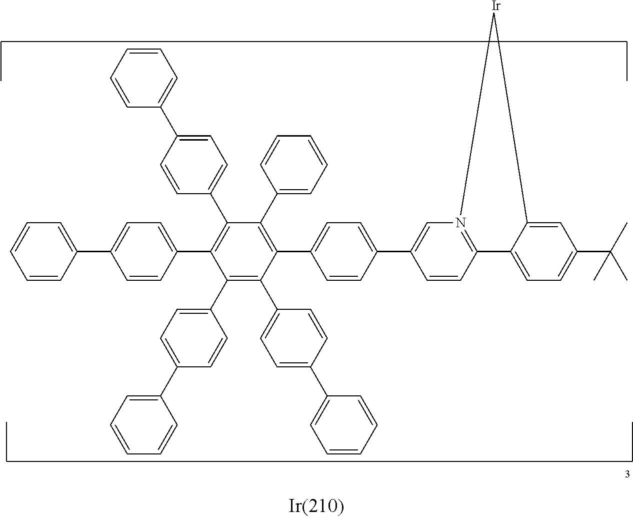 | 21% |
| Ir(529) | 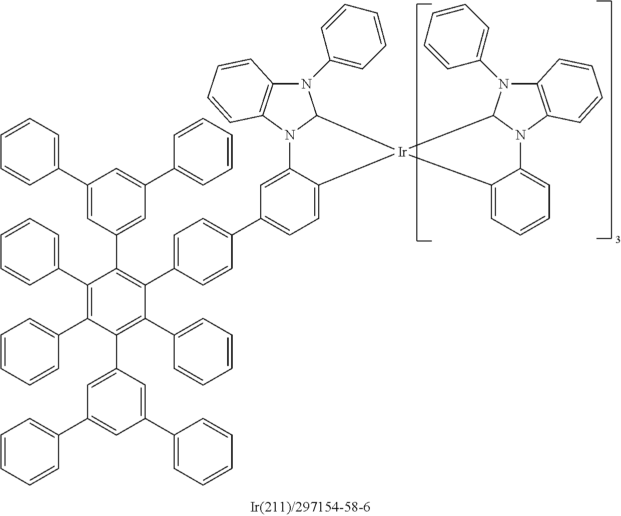 | 26% |
| Ir(530) | 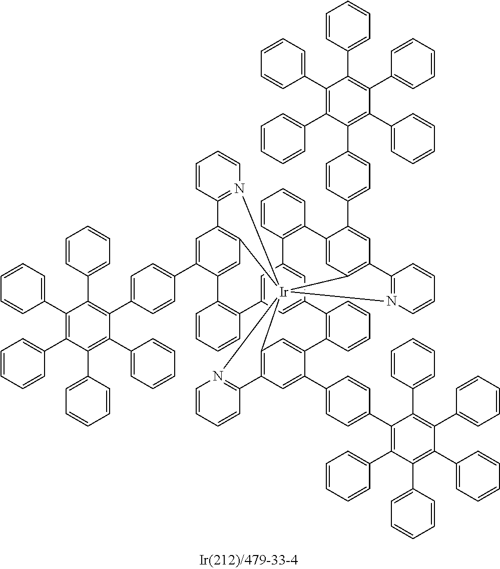 | 64% |
| Ir(531) | 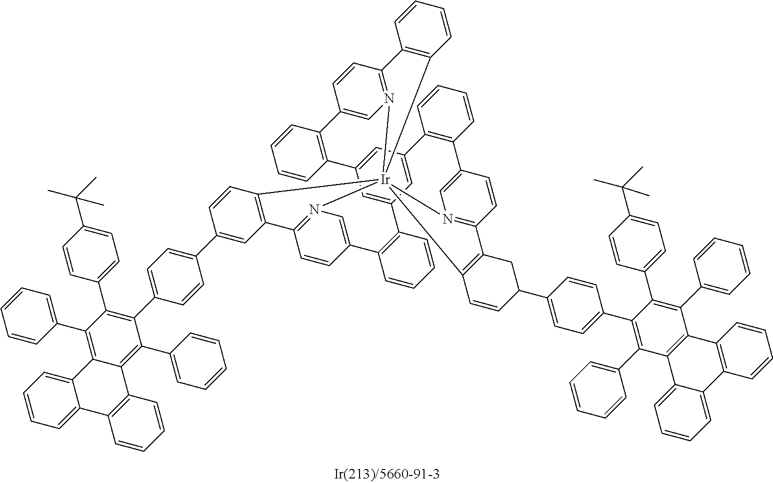 | 69% |
| Ir(532) | 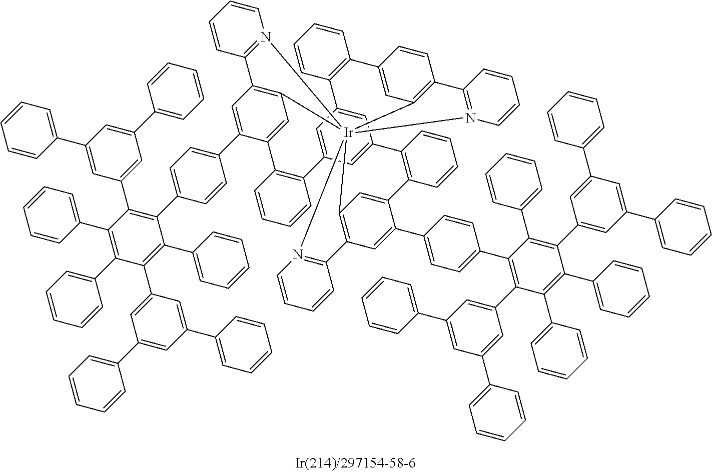 | 64% |
| Ir(533) | 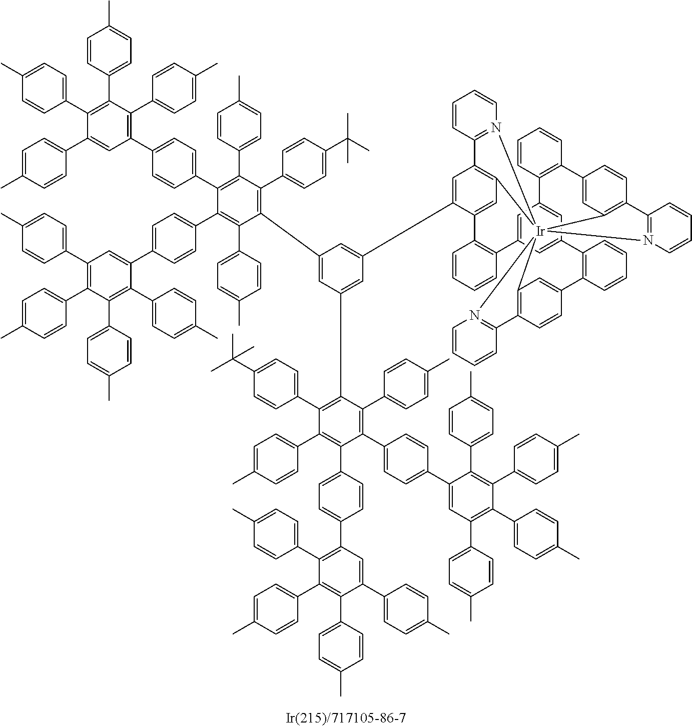 | 61% |
| Ir(534) | 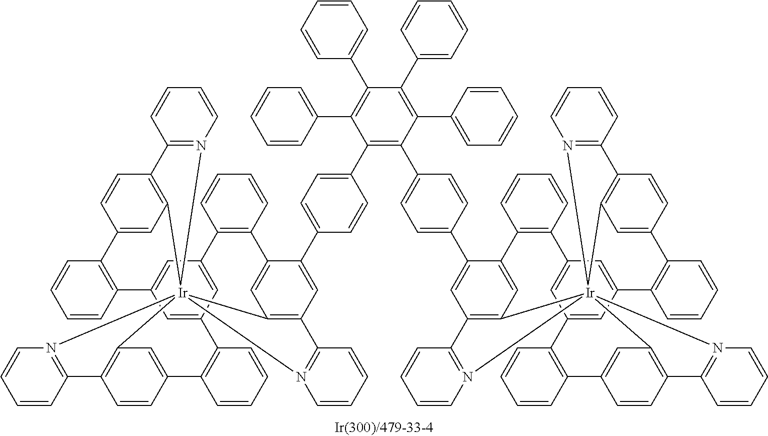 | 51% |
| Ir(535) | 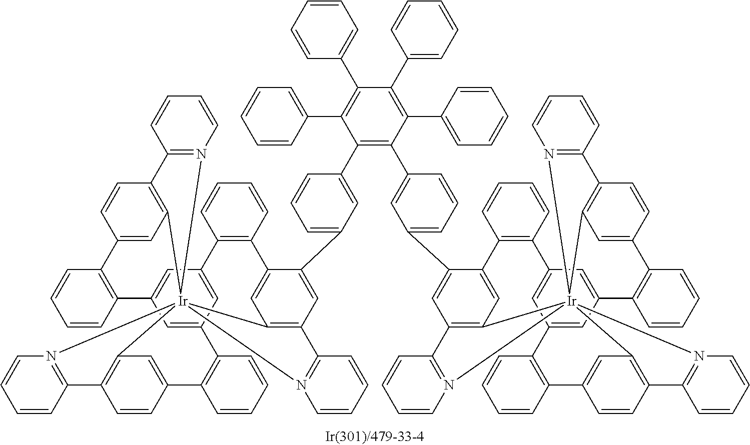 | 49% |

### Example: Solubility

The compounds of the invention have very good solubility in nonpolar solvents (aromatics, alkylaromatics, cyclohexane) and dipolar aprotic solvents (ketones, ethers, esters, amides, sulfones, sulfoxides etc., such as acetone, butanone, cyclohexanone, di-n-butyl ether, THF, dioxane, 3-phenoxytoluene, anisole, ethyl acetate, butyl acetate, hexyl acetate, methyl benzoate, DMF, DMAC, NMP, DMSO, dimethyl sulfone, sulfolane, etc.) and mixtures thereof, and form solutions that are stable for a long period of time. Preferred concentrations are 5-500 mg/ml, more preferably 20-200 mg/ml. This property is of crucial significance for processing from solution in the form of solutions alone or in combination with other materials, especially with regard to the printing of high-resolution full-color displays.

Comparison of Solubility:

| | Solubility mg/ml at room temperature | | | | |
|---|---|---|---|---|---|
| | | | 3-Phenoxy- | n-Butyl | |
| Compound | Cyclohexane | Toluene | toluene | benzoate | DMF |
| IrRef1 | <3 | ~10 | ~100 | ~20 | — |
| Ir(L2-3Ph) | <<1 | <5 | >10 | <5 | ~5 |
| Ir(500) | >5 | >100 | >150 | >80 | >70 |
| Ir(530) | >5 | >100 | >150 | >80 | >70 |

### Example: Comparison of the PL Spectra

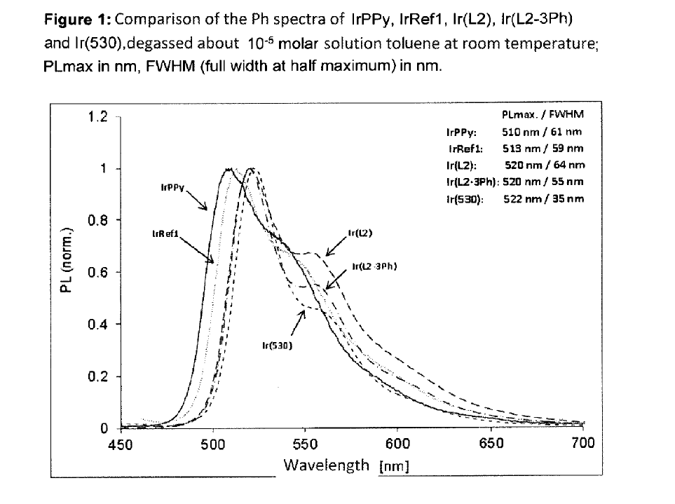

The compounds have the particular feature of narrow emission spectra (photoluminescence (PL) or electroluminescence), as apparent in FIG. 1. FIG. 1 shows a comparison of the PL spectra of IrPPy, IrRef1, Ir(L2), Ir(L2-3Ph) and Ir(530), using degassed 10⁻⁵ molar solutions in toluene at room temperature for the measurement of the spectra; PL max in nm, FWHM (full width at half maximum) in nm. Narrow emission spectra are crucial for the building of pure-color and high-efficiency OLED components, both for bottom emission and for top emission components with weak or strong cavities.

### Example: Production of the OLEDs

Solution-Processed Devices:

A: From Soluble Functional Materials of Low Molecular Weight

The iridium complexes of the invention can be processed from solution and lead therein to OLEDs which are much simpler in terms of process technology compared to the vacuum-processed OLEDs, but nevertheless have good properties. The production of such components is based on the production of polymeric light-emitting diodes (PLEDs), which has already been described many times in the literature (for example in WO 2004/037887). The structure is composed of substrate/ITO/hole injection layer (60 nm)/interlayer (20 nm)/emission layer (60 nm)/hole blocker layer (10 nm)/electron transport layer (40 nm)/cathode. For this purpose, substrates from Technoprint (soda-lime glass) are used, to which the ITO structure (indium tin oxide, a transparent conductive anode) is applied. The substrates are cleaned in a cleanroom with DI water and a detergent (Deconex 15 PF) and then activated by a UV/ozone plasma treatment. Thereafter, likewise in a cleanroom, a 20 nm hole injection layer is applied by spin-coating. The required spin rate depends on the degree of dilution and the specific spin-coater geometry. In order to remove residual water from the layer, the substrates are baked on a hotplate at 200° C. for 30 minutes. The interlayer used serves for hole transport; in this case, an HL-X from Merck is used. The interlayer may alternatively also be replaced by one or more layers which merely have to fulfill the condition of not being leached off again by the subsequent processing step of EML deposition from solution. For production of the emission layer, the triplet emitters of the invention are dissolved together with the matrix materials in toluene or chlorobenzene or 3-phenoxytoluene. The typical solids content of such solutions is between 16 and 25 g/l when, as here, the layer thickness of 60 nm which is typical of a device is to be achieved by means of spin-coating. The solution-processed devices of type 1 contain an emission layer composed of M1:M2:IrL (40%:35%:25%), and those of type 2 contain an emission layer composed of M1:M2:IrLa:IrLb (30%:35%:30%:5%); in other words, they contain two different Ir complexes. The emission layer is spun on in an inert gas atmosphere, argon in the present case, and baked at 160° C. for 10 min. Vapor-deposited above the latter are the hole blocker layer (15 nm ETM1) and the electron transport layer (35 nm ETM1 (50%)/ETM2 (50%)) (vapor deposition systems from Lesker or the like, typical vapor deposition pressure 5×10⁻⁶ mbar). Finally, a cathode of aluminum (100 nm) (high-purity metal from Aldrich) is applied by vapor deposition. In order to protect the device from air and air humidity, the device is finally encapsulated and then characterized. The OLED examples cited are yet to be optimized; Table 1 summarizes the data obtained.

TABLE 1
Results with materials processed from solution

| | | EQE (%) | Voltage (V) | | LT50 (h) |
|---|---|---|---|---|---|
| | Emitter | 1000 | 1000 | | 1000 |
| Ex. | Device | cd/m² | cd/m² | CIE x/y | cd/m² |
| Ref-Red1 | IrRef1 | 17.3 | 6.4 | 0.65/0.35 | 220000 |
| | IrRef3 | | | | |
| | Type2 | | | | |
| Red1 | Ir530 | 18.1 | 6.3 | 0.65/0.35 | 270000 |
| | IrRef3 | | | | |
| | Type2 | | | | |
| Red2 | Ir530 | 18.6 | 6.1 | 0.61/0.39 | 230000 |
| | Ir508 | | | | |
| | Type2 | | | | |
| Ref-Green1 | IrRef1 | 18.1 | 5.2 | 0.34/0.61 | 210000 |
| | Type1 | | | | |
| Ref-Green2 | IrRef2 | 20.6 | 5.2 | 0.33/0.62 | 250000 |
| | Type1 | | | | |
| Green1 | Ir(500) | 19.6 | 5.0 | 0.32/0.62 | 290000 |
| | Type1 | | | | |
| Green2 | Ir(530) | 22.3 | 5.2 | 0.30/0.65 | 360000 |
| | Type1 | | | | |
| Green3 | Ir(531) | 20.7 | 5.1 | 0.33/0.62 | 270000 |
| | Type1 | | | | |
| Green4 | Ir(534) | 22.0 | 5.1 | 0.31/0.66 | 340000 |
| | Type1 | | | | |
| Green5 | Ir(532) | 22.1 | 5.0 | 0.33/0.62 | 290000 |
| | Type1 | | | | |
| Green6 | Ir(533) | 21.9 | 4.8 | 0.32/0.63 | 320000 |
| | Type1 | | | | |
| Green7 | Ir(534) | 22.7 | 4.9 | 0.32/0.63 | 340000 |
| | Type1 | | | | |
| Green8 | Ir(509) | 20.5 | 5.1 | 0.35/0.61 | 230000 |
| | Type1 | | | | |
| Green9 | Ir(510) | 20.1 | 5.0 | 0.38/0.59 | 260000 |
| | Type1 | | | | |
| Green10 | Ir(511) | 20.9 | 5.2 | 0.44/0.55 | 330000 |
| | Type1 | | | | |
| Green11 | Ir(515) | 21.9 | 4.9 | 0.34/0.61 | 290000 |
| | Type1 | | | | |
| Green12 | Ir(516) | 22.3 | 5.0 | 0.34/0.61 | 310000 |
| | Type1 | | | | |
| Green13 | Ir(517) | 21.7 | 4.7 | 0.35/0.62 | 330000 |
| | Type1 | | | | |

TABLE 2
Structural formulae of the materials used

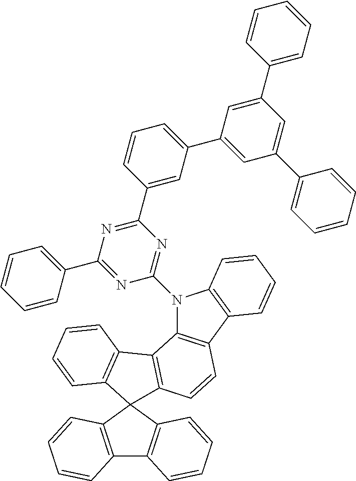 [SMILES: c1ccc(-c2cc(-c3ccccc3)cc(-c3cccc(-c4nc(-c5ccccc5)nc(-n5c6ccccc6c6ccc7c(c65)-c5ccccc5C75c6ccccc6-c6ccccc65)n4)c3)c2)cc1]

M1
1616231-60-7

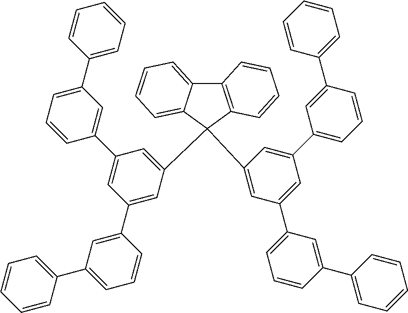 [SMILES: c1ccc(-c2cccc(-c3cc(-c4cccc(-c5ccccc5)c4)cc(C4(c5cc(-c6cccc(-c7ccccc7)c6)cc(-c6cccc(-c7ccccc7)c6)c5)c5ccccc5-c5ccccc54)c3)c2)cc1]

M2
1246496-85-4

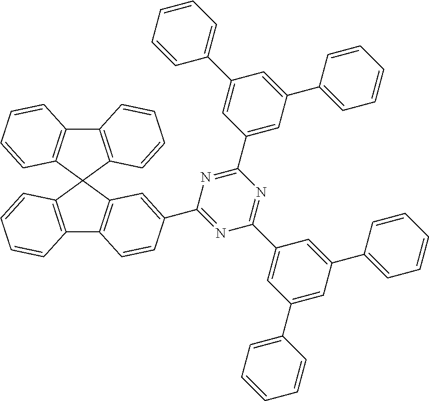 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

ETM1
1233200-52-6

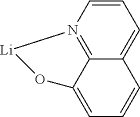

ETM2
25387-93-3

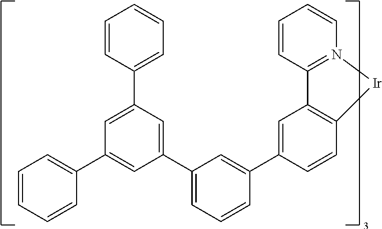

IrRef1
1269508-30-6

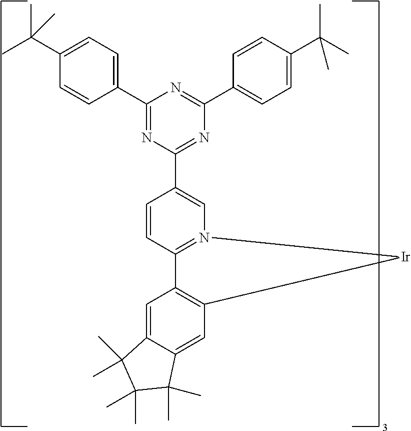

IrRef3
1870013-87-8

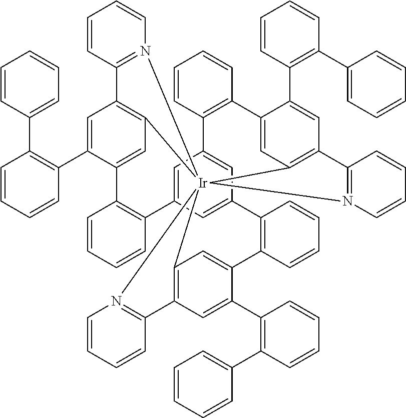

IrRef2
WO 2016/124304

1-16. (canceled)

17. A metal complex comprising at least one structure of the formula (1):
M(L)ₙ(L′)ₘ (1)
wherein
M is iridium or platinum;
L is the same or different in each instance and is a bidentate ligand;
L′ is the same or different in each instance and is a ligand;
n is 1, 2 or 3;
m is 0, 1, 2, 3, or 4;
wherein two or more ligands L are optionally joined to one another or L is optionally joined to L′ by a single bond or a bivalent or trivalent bridge so as to define a tridentate, tetradentate, pentadentate, or hexadentate ligand system;
wherein the metal complex comprises at least one substructure of formula (2): 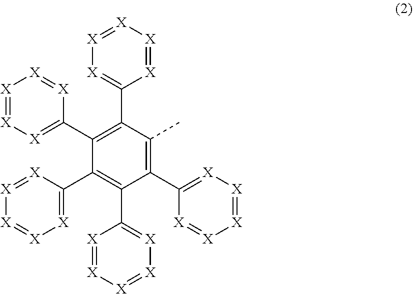
wherein
the dotted bond denotes the linkage of this group to another part of the metal complex of formula (1);
X is the same or different in each instance and is CR or N, with the proviso that not more than three X per cycle are N;
R is the same or different in each instance and is H, D, F, Cl, Br, I, N(R¹)₂, CN, NO₂, OH, COOH, C(═O)N(R¹)₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy, or thioalkoxy group having 1 to 20 carbon atoms or an alkenyl or alkynyl group having 2 to 20 carbon atoms or a branched or cyclic alkyl, alkoxy, or thioalkoxy group having 3 to 20 carbon atoms, wherein the alkyl, alkoxy, thioalkoxy, alkenyl, or alkynyl group are optionally substituted by one or more R¹ radicals, wherein one or more nonadjacent CH₂ groups are optionally replaced by R¹C═CR¹, C≡C, Si(R¹)₂, C═O, NR¹, O, S, or CONR¹, or an aromatic or heteroaromatic ring system having 5 to 40 aromatic ring atoms and optionally substituted in each case by one or more R¹ radicals, or an aryloxy or heteroaryloxy group having 5 to 40 aromatic ring atoms and optionally substituted by one or more R¹ radicals; and wherein two R radicals together optionally define a ring system;
R¹ is the same or different in each instance and is H, D, F, Cl, Br, I, N(R²)₂, CN, NO₂, Si(R²)₃, B(OR²)₂, C(═O)R², P(═O)(R²)₂, S(═O)R², S(═O)₂R², OSO₂R², a straight-chain alkyl, alkoxy, or thioalkoxy group having 1 to 20 carbon atoms or an alkenyl or alkynyl group having 2 to 20 carbon atoms or a branched or cyclic alkyl, alkoxy, or thioalkoxy group having 3 to 20 carbon atoms, wherein each alkyl, alkoxy, thioalkoxy, alkenyl, or alkynyl group is optionally substituted by one or more R² radicals, wherein one or more nonadjacent CH₂ groups are optionally replaced by R²C═CR², C≡C, Si(R²)₂, C═O, NR², O, S, or CONR², or an aromatic or heteroaromatic ring system having 5 to 40 aromatic ring atoms and is optionally substituted in each case by one or more R² radicals, or an aryloxy or heteroaryloxy group having 5 to 40 aromatic ring atoms and is optionally substituted by one or more R² radicals, or an aralkyl or heteroaralkyl group having 5 to 40 aromatic ring atoms and is optionally substituted by one or more R² radicals, or a diarylamino group, diheteroarylamino group, or arylheteroarylamino group having 10 to 40 aromatic ring atoms and is optionally substituted by one or more R² radicals; and wherein two or more R¹ radicals together optionally define a ring system;
R² is the same or different in each instance and is H, D, F, or an aliphatic, aromatic, and/or heteroaromatic organic radical having 1 to 20 carbon atoms, wherein one or more hydrogen atoms are optionally replaced by F, and wherein two or more R² radicals together optionally define a mono- or polycyclic ring system;
wherein the substructure, as well as the linkage denoted by the dotted bond, optionally have further bonds to parts of the metal complex of the formula (1);
with the proviso that if M is Ir, the part of the metal complex that binds to Ir comprises not more than one monodentate ligand L′ and the bidentate ligands L of the metal complex each have at least one Ir—C bond.

18. The metal complex of claim 17, wherein the substructure of formula (2) is a substructure of at least one of formulae (2-1), (2-2), and/or (2-3): 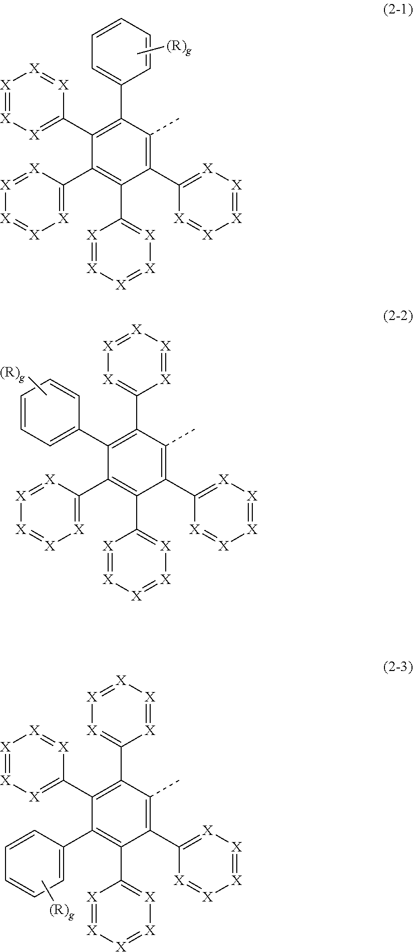
wherein
g is 0, 1, 2, 3, 4, or 5; and
wherein the substructure, as well as the linkage denoted by the dotted bond, optionally have further bonds to parts of the metal complex of formula (1).

19. The metal complex of claim 17, wherein the substructure of formula (2) is a substructure of formula (2-4): 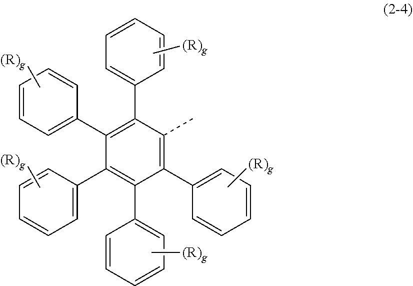
wherein
g is the same or different in each instance and is 0, 1, 2, 3, 4 or 5; and
wherein the substructure, as well as the linkage represented by a dotted bond, may have further bonds to parts of the metal complex of the formula (1).

20. The metal complex of claim 19, wherein the linkage, denoted by the dotted bond in formulae (2), (2-1), (2-2), (2-3), or (2-4), of the substructure of formulae (2), (2-1), (2-2), (2-3), and/or (2-4) is bonded to an aromatic or heteroaromatic ring system.

21. The metal complex of claim 20, wherein the linkage, denoted by the dotted bond in formulae (2), (2-1), (2-2), (2-3), or (2-4), of the substructure of formulae (2), (2-1), (2-2), (2-3), and/or (2-4) is bonded to an aryl or heteroaryl radical of formula (Ar-1): 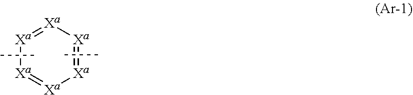
wherein
the dotted bonds denote the linkages of this group to other parts of the metal complex of the formula (1);
X^{a} is N, CR, or C if X^{a} denotes a bond to the substructure of formulae (2), (2-1), (2-2), (2-3), or (2-4) or to another part of the metal complex of formula (1); and
wherein the substructure, as well as the linkage denoted by the dotted bond, optionally has further bonds to parts of the metal complex of formula (1).

22. The metal complex of claim 20, wherein the aromatic or heteroaromatic ring system bonded to the substructure of formula (2), (2-1), (2-2), (2-3), and/or (2-4) is bonded directly to the metal atom M.

23. The metal complex of claim 17, wherein the metal is Ir(III) and the metal complex has three bidentate ligands, wherein the bidentate ligands coordinate to the iridium via one carbon atom and one nitrogen atom or via two carbon atoms.

24. The metal complex of claim 17, wherein the metal is Pt and coordinates to two bidentate ligands.

25. The metal complex of claim 17, wherein the metal complex comprises at least one bidentate ligand of formula (L-1), (L-2), and/or (L-3): 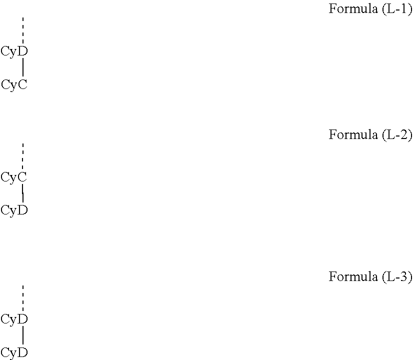
wherein
CyC is the same or different in each instance and is a substituted or unsubstituted aryl or heteroaryl group having 5 to 14 aromatic ring atoms and coordinates in each case to the metal via a carbon atom and which is bonded to CyD via a covalent bond in each case;
CyD is the same or different in each instance and is a substituted or unsubstituted heteroaryl group having 5 to 14 aromatic ring atoms and coordinates to the metal via a nitrogen atom or via a carbene carbon atom and which is bonded to CyC via a covalent bond;
wherein two or more ligands (L-1), (L-2), and/or (L-3) are optionally joined to one another via a single bond or a bivalent or trivalent bridge so as to define a tridentate, tetradentate, pentadentate, or hexadentate ligand system, wherein these optional bonds to a bridge are denoted by the dotted bond; and
wherein a substituent may also optionally coordinate to M.

26. The metal complex of claim 17, wherein at least one bidentate ligand is selected from the group consisting of structures of formulae (L-1-1), (L-1-2), and (L-2-1) through (L-2-4): 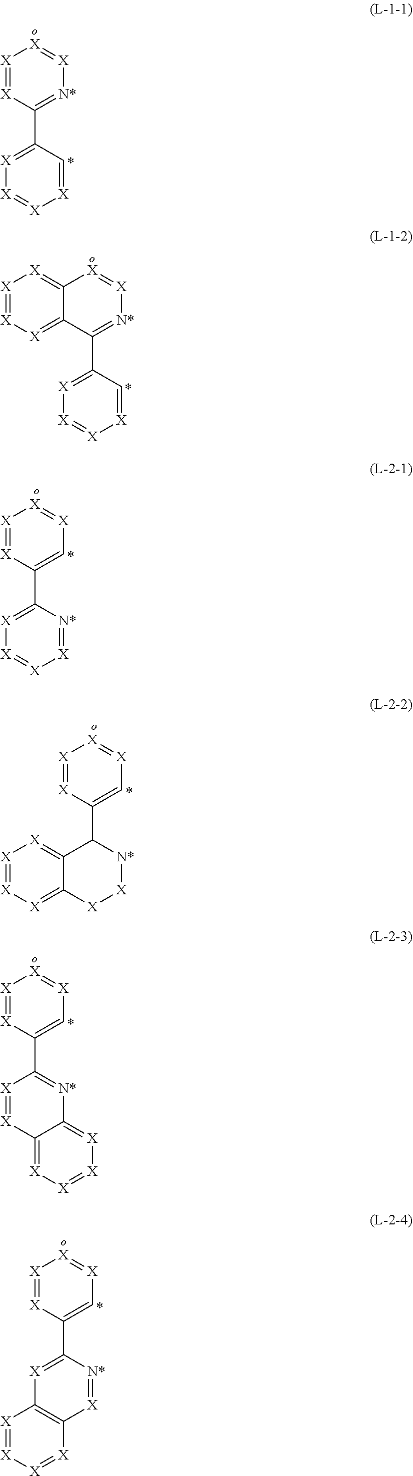
wherein the at least one bidentate ligand coordinates to the metal at the position denoted by * and wherein the ligands are optionally bonded via a bridge, wherein the bond to the bridge is optionally via the position denoted by “o”;
and/or wherein at least one bidentate ligand is selected from the group consisting of structures of formulae (L-5) through (L-32): 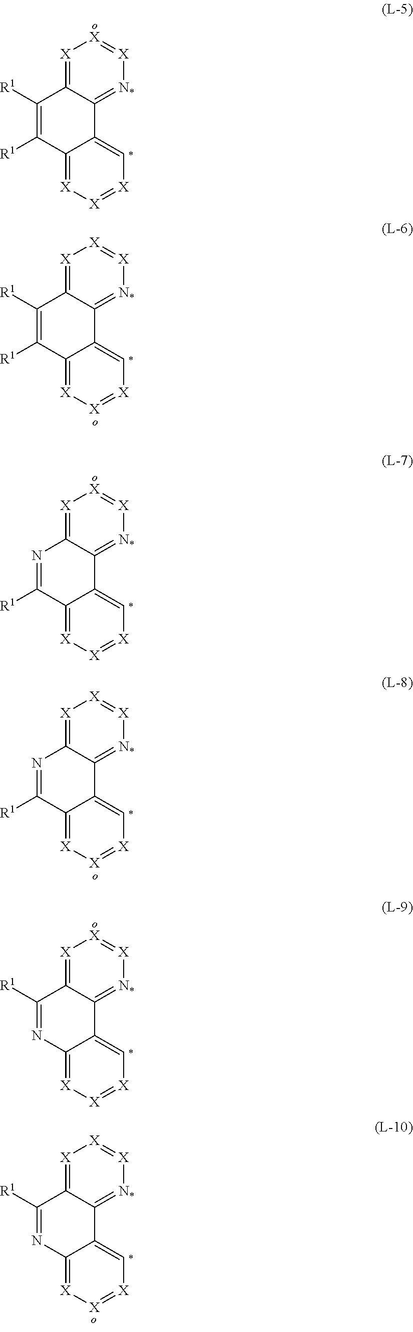 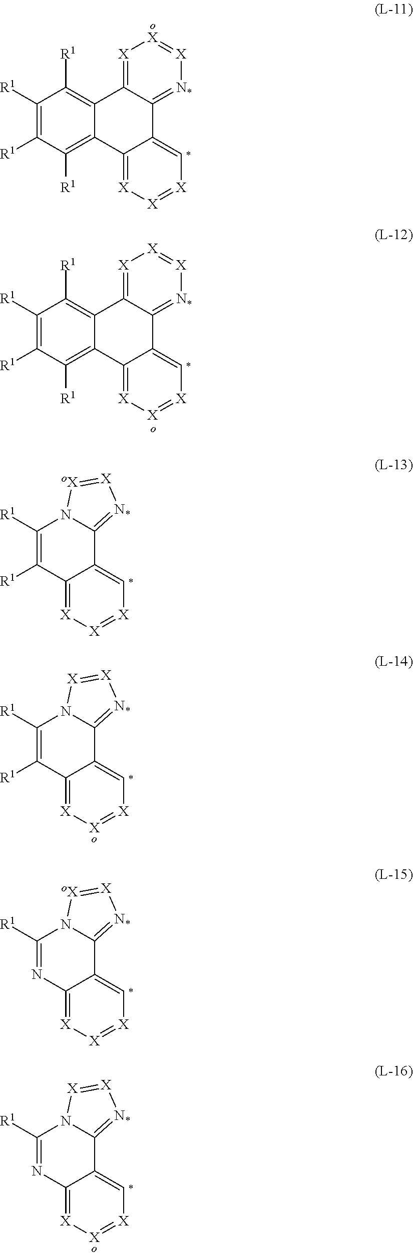 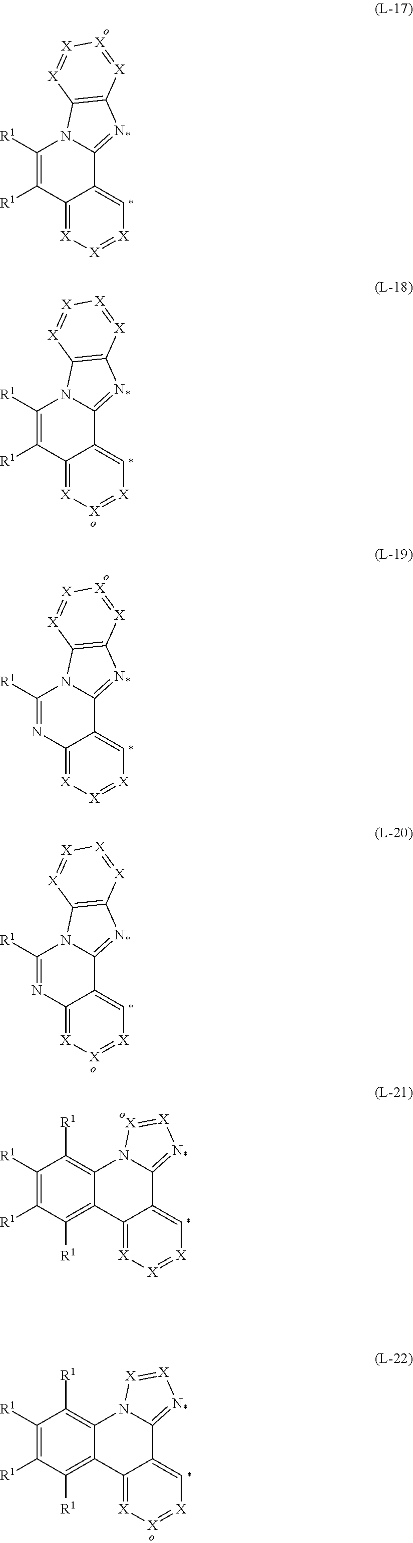 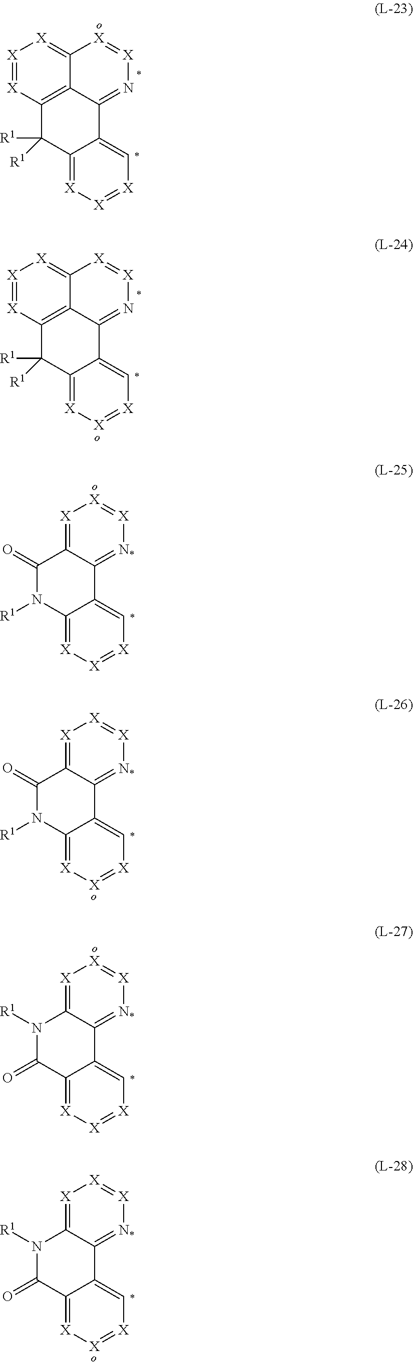 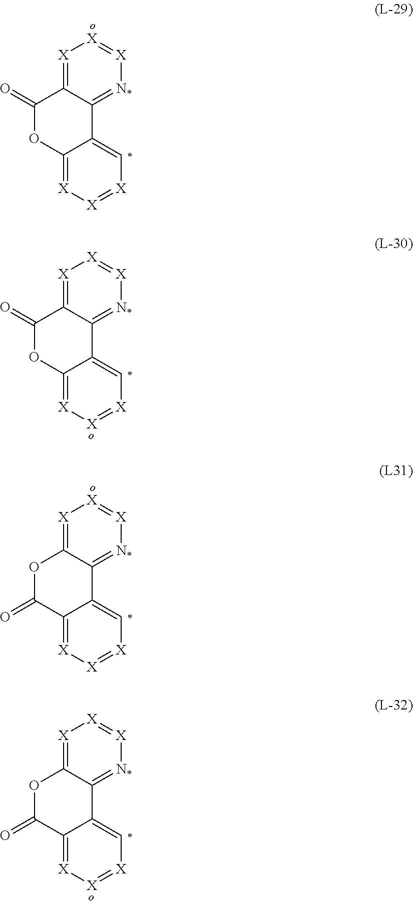
wherein the at least one bidentate ligand coordinates to the metal at the position denoted by * and wherein the ligands are optionally bonded via a bridge, wherein the bond to the bridge is optionally via the position denoted by “o”, and wherein the position denoted by “o” denotes a carbon atom if it constitutes a bridgehead site;
and/or wherein at least one bidentate ligand is selected from the group consisting of structures of formulae (L-35) through (L-40): 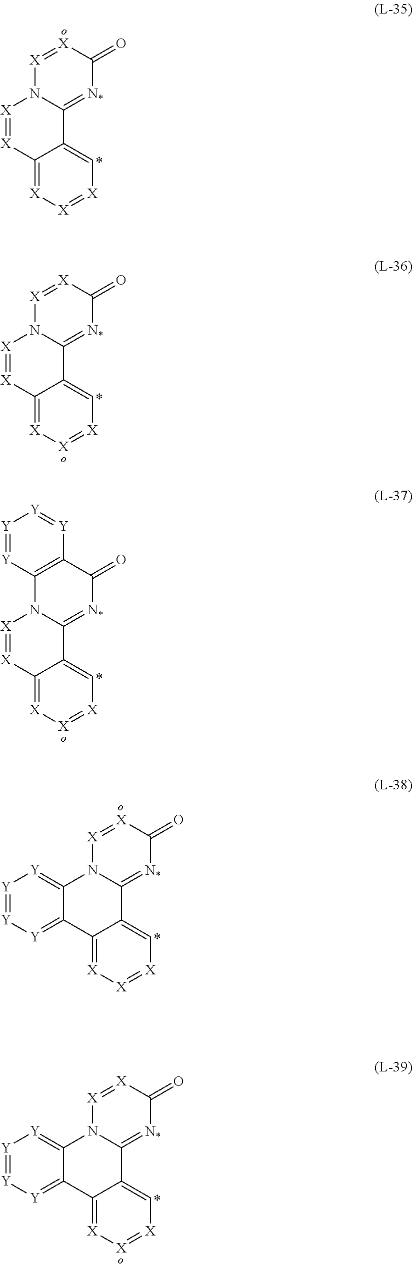 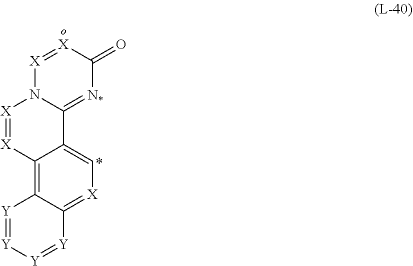
wherein * denotes the position of coordination to the metal, and wherein the ligands are optionally bonded via a bridge, wherein the bond to the bridge is optionally via the position denoted by “o”; and
X is the same or different in each instance and is CR or N, with the proviso that not more than one X per cycle is N, wherein X is C if the ligand at this position is bonded to a bridge;
Y is the same or different in each instance and is CR¹ or N;
and/or wherein at least one bidentate ligand is selected from the group consisting of structures of formulae (L-41) through (L-45): 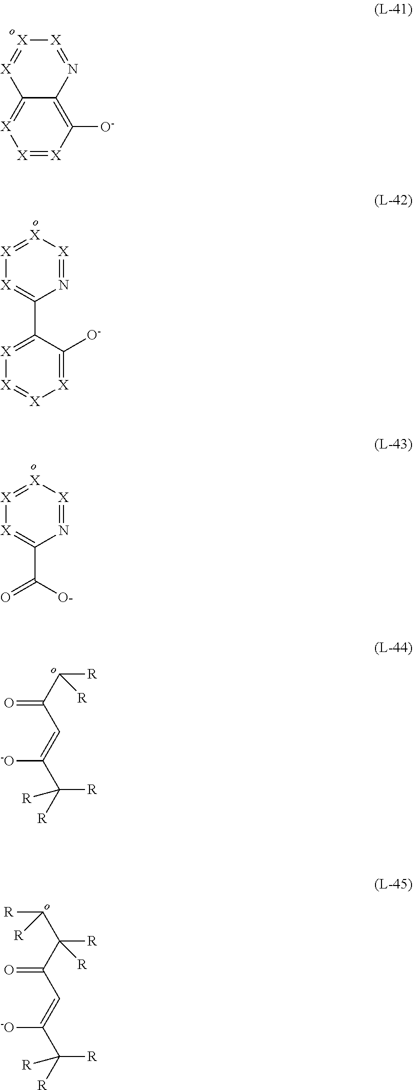
wherein the ligands (L-41) through (L-43) each coordinate to the metal via the nitrogen atom shown explicitly and the negatively charged oxygen atom and, for ligands (L-44) and (L-45), via the two oxygen atoms, and wherein the ligands are optionally bonded via a bridge, wherein the bond to the bridge is optionally via the position denoted by “o”, wherein X is C if the ligand is bonded to a bridge at this position, or, in formulae (L-44) or (L-45), the carbon atom optionally has a substituent R if the ligand is not bonded to a bridge at this position;
and/or wherein at least one bidentate ligand is selected from the group consisting of structures of formulae (L-46): 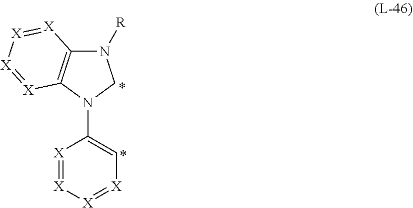
wherein * denotes the position of coordination to the metal, wherein the ligands are optionally bonded via a bridge.

27. The metal complex of claim 17, wherein the metal complex is a metal complex of formula:
Ir(L)ₙ(L′)ₘ (1a)
wherein the ligands L and L′ are bidentate ligands and are joined via a bridge so as to define a hexadentate tripodal ligand system, wherein the bridge via which the ligands are joined is a bridge of formula (3) or formula (4): 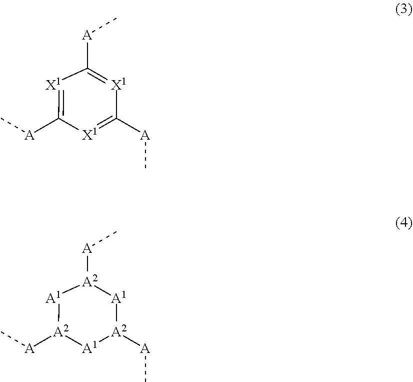
wherein
the dotted bond denotes the bond of the ligands to this structure;
X¹ is the same or different in each instance and is CR or N;
A¹ is the same or different in each instance and is C(R)₂ or O;
A² is the same or different in each instance and is CR, P(═O), B, or SiR, with the proviso that, when A²=P(═O), B, or SiR, A¹ is O and the A bonded to this A² is not —C(═O)—NR′— or —C(═O)—O—;
A is the same or different in each instance and is —CR═CR—, —C(═O)—NR′—, —C(═O)—O—, or a group of formula (5): 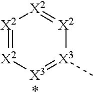
wherein the dotted bond denotes the position of the bond of the ligands to this structure and * denotes the position of the linkage of the unit of formula (5) to the central cyclic group;
X² is the same or different in each instance and is CR or N or two adjacent X² together are NR, O, or S, so as to define a five-membered ring, and the remaining X² are the same or different in each instance and are CR or N; or two adjacent X² together are CR or N when one X³ in the cycle is N, so as to define a five-membered ring; with the proviso that not more than two adjacent X² are N;
X³ is C in each instance or one X³ is N and the other X³ in the same cycle is C; with the proviso that two adjacent X² together are CR or N when one X³ in the cycle is N;
R′ is the same or different in each instance and is H, D, a straight-chain alkyl group having 1 to 20 carbon atoms or a branched or cyclic alkyl group having 3 to 20 carbon atoms, wherein the alkyl group in each case is optionally substituted by one or more R¹ radicals and wherein one or more nonadjacent CH₂ groups are optionally replaced by Si(R¹)₂, or an aromatic or heteroaromatic ring system having 5 to 40 aromatic ring atoms and is optionally substituted in each case by one or more R¹ radicals; and
wherein the three bidentate ligands L and/or L′, apart from via the bridge of the formula (3) or (4), are optionally also ring-closed via a further bridge to form a cryptate.

28. An oligomer, polymer, or dendrimer comprising one or more metal complexes of claim 17, wherein one or more bonds of the one or more metal complexes to the polymer, oligomer, or dendrimer are present.

29. A formulation comprising at least one metal complex of claim 17 and at least one further compound selected from the group consisting of solvents, fluorescent emitters, phosphorescent emitters, host materials, matrix materials, electron transport materials, electron injection materials, hole conductor materials, hole injection materials, electron blocker materials, and hole blocker materials.

30. A formulation comprising at least one oligomer, polymer, or dendrimer of claim 28 and at least one further compound selected from the group consisting of solvents, fluorescent emitters, phosphorescent emitters, host materials, matrix materials, electron transport materials, electron injection materials, hole conductor materials, hole injection materials, electron blocker materials, and hole blocker materials.

31. A process for preparing the metal complex of claim 17 comprising reacting a metal complex with an aromatic or heteroaromatic compound.

32. A process for preparing the oligomer, polymer, or dendrimer of claim 28 comprising reacting a metal complex with an aromatic or heteroaromatic compound.

33. An electronic device comprising at least one metal complex of claim 17.

34. The electronic device of claim 33, wherein the electronic device is selected from the group consisting of organic electroluminescent devices, organic integrated circuits, organic field-effect transistors, organic thin-film transistors, organic light-emitting transistors, organic solar cells, organic optical detectors, organic photoreceptors, organic field quench devices, light-emitting electrochemical cells, oxygen sensors, oxygen sensitizers, and organic laser diodes.

35. An electronic device comprising at least one the oligomer, polymer, or dendrimer of claim 28.

36. The electronic device of claim 35, wherein the electronic device is selected from the group consisting of organic electroluminescent devices, organic integrated circuits, organic field-effect transistors, organic thin-film transistors, organic light-emitting transistors, organic solar cells, organic optical detectors, organic photoreceptors, organic field quench devices, light-emitting electrochemical cells, oxygen sensors, oxygen sensitizers, and organic laser diodes.
